(19) United States
(12) Patent Application Publication
(10) Pub. No.: US 2026/0186185 A1
(43) Pub. Date: Jul. 2, 2026

(54) OPTICAL FILM, POLARIZING PLATE, AND IMAGE DISPLAY DEVICE

(71) Applicant: FUJIFILM Corporation, Tokyo (JP)

(72) Inventor: Yuki NAKAMURA, Minamiashigara-shi (JP)

(73) Assignee: FUJIFILM Corporation, Tokyo (JP)

(21) Appl. No.: 19/541,439

(22) Filed: Feb. 17, 2026

Related U.S. Application Data
(63) Continuation of application No. PCT/JP2024/030381, filed on Aug. 27, 2024.

(30) Foreign Application Priority Data
Sep. 15, 2023 (JP) 2023-150111

(51) Int. Cl. G02B 5/30; G02F 1/1335; H10K 59/50; H10K 59/80

(52) U.S. Cl. CPC G02B 5/3016; H10K 59/50; H10K 59/8793; G02F 1/133528

(57) ABSTRACT

An optical film, polarizing plate, and image display device are provided, each including an optically anisotropic layer in which both precipitate formation and cohesive failure are suppressed. The optically anisotropic layer is a liquid crystal cured layer formed from a liquid crystal composition containing a liquid crystal compound and a surfactant, the liquid crystal compound being immobilized in a vertically aligned state and exhibiting reverse wavelength dispersibility. The surfactant includes a repeating unit H having a fluorinated alkyl group or a silicon-containing group. At least one surfactant further includes repeating unit K having a functional group capable of crosslinking with the liquid crystal compound and repeating unit M having a mesogen group. A content of repeating unit X in the surfactant, having an I/O value difference of 0.9 or more relative to the liquid crystal compound, is 8 mol % or less.

### CROSS-REFERENCE TO RELATED APPLICATIONS

This application is a Continuation of PCT International Application No. PCT/JP2024/030381 filed on Aug. 27, 2024, which claims priority under 35 U.S.C. § 119(a) to Japanese Patent Application No. 2023-150111 filed on Sep. 15, 2023. The above applications are hereby expressly incorporated by reference, in their entirety, into the present application.

### BACKGROUND OF THE INVENTION

### 1. Field of the Invention

The present invention relates to an optical film, a polarizing plate, and an image display device.

### 2. Description of the Related Art

Optical films such as an optical compensation sheet and a retardation film have been used in various image display devices in order to eliminate image coloration or widen a viewing angle.

A stretched birefringent film has been used as the optical film, but in recent years, it has been proposed to use an optical film having a liquid crystal cured layer instead of the stretched birefringent film.

As such an optical film, for example, JP2021-193825A discloses an optical film including an optically anisotropic layer obtained by curing a polymerizable liquid crystal composition which contains a rod-like liquid crystal compound and a monofunctional compound, and immobilizing an alignment state of the rod-like liquid crystal compound (see, for example, Claim 1 and Claim 13).

### SUMMARY OF THE INVENTION

The present inventor has found that, in the optical film disclosed in JP2021-193825A, in a case where a polymerizable liquid crystal composition is applied (particularly continuously applied) and an alignment state is fixed to form an optically anisotropic layer, precipitates (streaky unevenness) may occur, and the optically anisotropic layer may undergo cohesive failure during peeling.

Therefore, an object of the present invention is to provide an optical film, a polarizing plate, and an image display device, each of which includes an optically anisotropic layer in which both occurrence of precipitates and cohesive failure are suppressed.

As a result of intensive studies to achieve the above-described object, the present inventor has found that, in a case where a content of a repeating unit having a difference in I/O value with a liquid crystal compound of 0.9 or more is set to 8 mol % or less in a surfactant contained in the liquid crystal composition, both the occurrence of precipitates and cohesive failure can be suppressed in a liquid crystal cured layer (optically anisotropic layer) obtained by immobilizing the liquid crystal compound in a vertically aligned state, and have completed the present invention.

That is, the present inventor has found that the above-described object can be achieved by employing the following configurations.
[1] An optical film comprising:
an optically anisotropic layer,
in which the optically anisotropic layer is a liquid crystal cured layer formed by using a liquid crystal composition which contains a liquid crystal compound and a surfactant, and immobilizing the liquid crystal compound in a vertically aligned state,
the liquid crystal compound is a liquid crystal compound exhibiting reverse wavelength dispersibility,
the surfactant is a surfactant having a repeating unit H including a fluorinated alkyl group or a silicon-containing group,
at least one surfactant has the repeating unit H, a repeating unit K including a functional group capable of being crosslinked with the liquid crystal compound, and a repeating unit M including a mesogen group, and
a content of a repeating unit X in the surfactant, in which a difference in I/O value with the liquid crystal compound is 0.9 or more, is 8 mol % or less,
provided that, in a case where the liquid crystal composition contains two or more kinds of liquid crystal compounds, each of requirements regarding the liquid crystal compound is a requirement regarding a liquid crystal compound having a highest content, and
in a case where the liquid crystal composition contains two or more kinds of surfactants, a requirement regarding the content of the repeating unit X in the surfactant is a requirement which is satisfied independently by all kinds of the surfactants.
[2] The optical film according to [1],
in which the repeating unit X includes a carboxy group.
[3] The optical film according to [1] or [2],
in which the content of the repeating unit X is 5 mol % or less.
[4] The optical film according to any one of [1] to [3],
in which a content of the surfactant is 0.05% by mass or more with respect to a total mass of solid contents of the liquid crystal composition.
[5] The optical film according to any one of [1] to [4],
in which a content of the repeating unit K is 10 mol % or more.
[6] The optical film according to any one of [1] to [5],
in which, in a case where a value of a content (unit: mol %) of the repeating unit M is denoted by m and a value of a content (unit: mol %) of the repeating unit K is denoted by k, the following expressions (1) and (2) are satisfied,

$$m / k \leq 1 , and \qquad ( 1 )$$

$$m \leq 50. \qquad ( 2 )$$

[7] The optical film according to any one of [1] to [6],
in which the liquid crystal composition further contains a compound including a mesogen group having the same structure as the mesogen group included in the repeating unit M in an amount of 0.5% by mass or more with respect to a total mass of solid contents of the liquid crystal composition.
[8] The optical film according to any one of [1] to [7],
in which the repeating unit M further includes a boronic acid group in addition to the mesogen group.
[9] The optical film according to any one of [1] to [8], further comprising:
a substrate.
[10] The optical film according to [9],
in which the substrate is a positive A-plate.
[11] The optical film according to [9] or [10],
in which the substrate is a liquid crystal cured layer formed by fixing an alignment state of a liquid crystal compound, the liquid crystal cured layer being different from the optically anisotropic layer.
[12]A polarizing plate comprising:
the optical film according to any one of [1] to [11]; and
a polarizer.
[13] An image display device comprising:
the optical film according to any one of [1] to [11].
[14] An image display device comprising:
the polarizing plate according to [12].
[15] The image display device according to [13] or [14],
in which the image display device is a liquid crystal display device.
[16] The image display device according to [13] or [14],
in which the image display device is an organic electroluminescence (hereinafter, abbreviated as “EL”) display device.

According to the present invention, it is possible to provide an optical film, a polarizing plate, and an image display device, each of which includes an optically anisotropic layer in which both occurrence of precipitates and cohesive failure are suppressed.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

Any numerical range expressed using “to” in the present specification refers to a range including the numerical values before and after the “to” as a lower limit value and an upper limit value, respectively.

In addition, in a range of numerical values described in stages in the present specification, the upper limit value or the lower limit value described in a certain range of numerical values may be replaced with an upper limit value or a lower limit value of the range of numerical values described in other stages. In addition, regarding the numerical range described in the present specification, an upper limit value or a lower limit value described in a numerical value may be replaced with a value described in Examples.

In addition, in the present specification, substances corresponding to respective components may be used alone or in combination of two or more kinds thereof. Here, in a case where two or more kinds of substances are used in combination for each component, the content of the component indicates the total content of the substances used in combination, unless otherwise specified.

In addition, in this specification, “(meth)acrylic” is a notation representing “acrylic” or “methacrylic”.

In addition, in the present specification, a bonding direction of a divalent group as noted (for example, —CO—O—) is not particularly limited unless the bonding position is specified; and for example, in a case where D¹ in Formula (5) described later is —CO—NR—, D¹ may be *1-CO—NR—*2 or *1-NR—CO—*2, in which *1 represents a bonding position to the G¹ side and *2 represents a bonding position to the Ar side.

In the present specification, Re(λ) and Rth(λ) respectively represent an in-plane retardation at a wavelength λ and a thickness-direction retardation at a wavelength λ. Unless otherwise specified, the wavelength λ refers to 550 nm.

In addition, in the present specification, Re(λ) and Rth(λ) are values measured at a wavelength λ using AxoScan OPMF-1 (manufactured by Optoscience. Inc.).

Specifically, by inputting an average refractive index ((nx+ny+nz)/3) and a film thickness (d(μm)) to AxoScan OPMF-1, it is possible to calculate:
a slow axis direction (°);

$$Re ( λ ) = R 0 ( λ ) ; and$$

$$Rth ( λ ) = ( ( n x + ny ) / 2 - nz ) \times d$$

are calculated.

In addition, RO(λ) is expressed in a numerical value calculated with AxoScan OPMF-1, and means Re(λ).

In the present specification, examples of a substituent (monovalent substituent) include substituents described in the following substituent group A.

In the present specification, “may have a substituent” includes not only an aspect of not having a substituent but also an aspect of having one or more substituents.

### <Substituent Group A>

Examples of the substituent include:
a halogen atom (for example, a fluorine atom, a chlorine atom, or a bromine atom, preferably a chlorine atom or a fluorine atom, and more preferably a fluorine atom);
an alkyl group (a linear, branched, or cyclic alkyl group having preferably 1 to 48 carbon atoms, more preferably 1 to 24 carbon atoms, and particularly preferably 1 to 8 carbon atoms, such as a linear alkyl group having 1 to 6 carbon atoms (for example, a methyl group, an ethyl group, a n-propyl group, a n-butyl group, a n-pentyl group, and a n-hexyl group), a branched alkyl group having 3 to 6 carbon atoms (for example, an isopropyl group, an isobutyl group, a tert-butyl group, a sec-butyl group, a neopentyl group, an isohexyl group, and a 3-methylpentyl group), and a cyclic alkyl group having 3 to 12 carbon atoms (for example, a cyclopropyl group, a cyclopentyl group, a cyclohexyl group, a 1-norbornyl group, and a 1-adamantyl group));
an alkenyl group (an alkenyl group having preferably 2 to 48 carbon atoms and more preferably 2 to 18 carbon atoms, such as a vinyl group, an allyl group, a 1-butenyl group, and a 2-butenyl group);
an alkynyl group (an alkynyl group having preferably 2 to 6 carbon atoms and more preferably 2 to 4 carbon atoms, such as an ethynyl group, a 1-propynyl group, a propargyl group, a 1-butynyl group, and a 2-butynyl group);
an aryl group (an aryl group having preferably 6 to 48 carbon atoms and more preferably 6 to 24 carbon atoms, such as a phenyl group, an oligoaryl group (a naphthyl group or an anthryl group), a phenanthrenyl group, a fluorenyl group, a pyrenyl group, a triphenylenyl group, and a biphenyl group);
a heteroaryl group (a heterocyclic group having preferably 1 to 32 carbon atoms and more preferably 1 to 18 carbon atoms, such as a 2-thienyl group, a 4-pyridyl group, a 2-furyl group, a 2-pyrimidinyl group, a 1-pyridyl group, a 2-benzothiazolyl group, a 1-imidazolyl group, a 1-pyrazolyl group, and a benzotriazol-1-yl group);
an arylalkyl group (an arylalkyl group having preferably 7 to 15 carbon atoms, such as a benzyl group, a phenethyl group, a methylbenzyl group, a phenylpropyl group, a 1-methylphenylethyl group, a phenylbutyl group, a 2-methylphenylpropyl group, a tetrahydronaphthyl group, a naphthylmethyl group, a naphthylethyl group, an indenyl group, a fluorenyl group, an anthracenylmethyl group (an anthrylmethyl group), and a phenanthrenylmethyl group (a phenanthrylmethyl group));
a silyl group (a silyl group having preferably 3 to 38 carbon atoms and more preferably 3 to 18 carbon atoms, such as a trimethylsilyl group, a triethylsilyl group, a tributylsilyl group, a t-butyldimethylsilyl group, and a t-hexyldimethylsilyl group);
a hydroxy group; a cyano group; a nitro group; a morpholino group;
an alkoxy group (an alkoxy group having preferably 1 to 48 carbon atoms and more preferably 1 to 24 carbon atoms, such as a methoxy group, an ethoxy group, a 1-butoxy group, a 2-butoxy group, an isopropoxy group, a t-butoxy group, a dodecyloxy group, and a cycloalkyloxy group (for example, a cyclopentyloxy group or a cyclohexyloxy group));
an aryloxy group (an aryloxy group having preferably 6 to 48 carbon atoms and more preferably 6 to 24 carbon atoms, such as a phenoxy group and a 1-naphthoxy group);
an alkenyloxy group (an alkenyloxy group having preferably 2 to 6 carbon atoms, such as a vinyloxy group, a 1-propenyloxy group, a 2-n-propenyloxy group (an allyloxy group), a 1-n-butenyloxy group, and a prenyloxy group);
a heterocyclic oxy group (a heterocyclic oxy group having preferably 1 to 32 carbon atoms and more preferably 1 to 18 carbon atoms, such as a 1-phenyltetrazol-5-yloxy group and a 2-tetrahydropyranyloxy group);
a silyloxy group (a silyloxy group having preferably 1 to 32 carbon atoms and more preferably 1 to 18 carbon atoms, such as a trimethylsilyloxy group, a t-butyldimethylsilyloxy group, and a diphenylmethylsilyloxy group);
an acyloxy group (an acyloxy group having preferably 2 to 48 carbon atoms and more preferably 2 to 24 carbon atoms, such as an acetoxy group, a pivaloyloxy group, a benzoyloxy group, a dodecanoyloxy group, an acryloyloxy group, and a methacryloyloxy group);
a hydroxyalkyleneoxy group (a hydroxyalkyleneoxy group having preferably 2 to 10 carbon atoms, such as a hydroxyethyleneoxy group);
an alkoxycarbonyloxy group (an alkoxycarbonyloxy group having preferably 2 to 48 carbon atoms and more preferably 2 to 24 carbon atoms, such as an ethoxycarbonyloxy group, a t-butoxycarbonyloxy group, and a cycloalkyloxycarbonyloxy group (for example, a cyclohexyloxycarbonyloxy group));
an aryloxycarbonyloxy group (an aryloxycarbonyloxy group having preferably 7 to 32 carbon atoms and more preferably 7 to 24 carbon atoms, such as a phenoxycarbonyloxy group);
a carbamoyloxy group (a carbamoyloxy group having preferably 1 to 48 carbon atoms and more preferably 1 to 24 carbon atoms, such as an N,N-dimethylcarbamoyloxy group, an N-butylcarbamoyloxy group, an N-phenylcarbamoyloxy group, and an N-ethyl-N-phenylcarbamoyloxy group);
a sulfamoyloxy group (a sulfamoyloxy group having preferably 1 to 32 carbon atoms and more preferably 1 to 24 carbon atoms, such as an N,N-diethylsulfamoyloxy group and an N-propylsulfamoyloxy group);
an alkylsulfonyloxy group (an alkylsulfonyloxy group having preferably 1 to 38 carbon atoms and more preferably 1 to 24 carbon atoms, such as a methylsulfonyloxy group, a hexadecylsulfonyloxy group, and a cyclohexylsulfonyloxy group);
an arylsulfonyloxy group (an arylsulfonyloxy group having preferably 6 to 32 carbon atoms and more preferably 6 to 24 carbon atoms, such as a phenylsulfonyloxy group);
an acyl group (an acyl group having preferably 1 to 48 carbon atoms and more preferably 1 to 24 carbon atoms, such as a formyl group, an acetyl group, an acryloyl group, a methacryloyl group, a pivaloyl group, a benzoyl group, a tetradecanoyl group, and a cyclohexanoyl group);
an alkoxycarbonyl group (an alkoxycarbonyl group having preferably 2 to 48 carbon atoms and more preferably 2 to 24 carbon atoms, such as a methoxycarbonyl group, an ethoxycarbonyl group, an octadecyloxycarbonyl group, a cyclohexyloxycarbonyl group, and a 2,6-di-tert-butyl-4-methylcyclohexyloxycarbonyl group);
an aryloxycarbonyl group (an aryloxycarbonyl group having preferably 7 to 32 carbon atoms and more preferably 7 to 24 carbon atoms, such as a phenoxycarbonyl group);
a carbamoyl group (a carbamoyl group having preferably 1 to 48 carbon atoms and more preferably 1 to 24 carbon atoms, such as a carbamoyl group, an N,N-diethylcarbamoyl group, an N-ethyl-N-octylcarbamoyl group, an N,N-dibutylcarbamoyl group, an N-propylcarbamoyl group, an N-phenylcarbamoyl group, an N-methyl-N-phenylcarbamoyl group, and an N,N-dicyclohexylcarbamoyl group);
an amino group (an amino group having preferably 32 or less carbon atoms and more preferably 24 or less carbon atoms, such as an amino group, a methylamino group, an N,N-dimethylamino group, an N,N-dibutylamino group, a tetradecylamino group, a 2-ethylhexylamino group, and a cyclohexylamino group);
an anilino group (an anilino group having preferably 6 to 32 carbon atoms and more preferably 6 to 24 carbon atoms, such as an anilino group and an N-methylanilino group);
a heterocyclic amino group (a heterocyclic amino group having preferably 1 to 32 carbon atoms and more preferably 1 to 18 carbon atoms, such as a 4-pyridylamino group);
a carboxamide group (a carboxamide group having preferably 2 to 48 carbon atoms and more preferably 2 to 24 carbon atoms, such as an acetamide group, a benzamide group, a tetradecaneamide group, a pivaloylamide group, and a cyclohexaneamide group);
a ureido group (a ureido group having preferably 1 to 32 carbon atoms and more preferably 1 to 24 carbon atoms, such as a ureido group, an N,N-dimethylureido group, and an N-phenylureido group);
an imide group (an imide group having preferably 36 or less carbon atoms and more preferably 24 or less carbon atoms, such as an N-succinimide group and an N-phthalimide group);
an alkoxycarbonylamino group (an alkoxycarbonylamino group having preferably 2 to 48 carbon atoms and more preferably 2 to 24 carbon atoms, such as a methoxycarbonylamino group, an ethoxycarbonylamino group, a t-butoxycarbonylamino group, an octadecyloxycarbonylamino group, and a cyclohexyloxycarbonylamino group);
an aryloxycarbonylamino group (an aryloxycarbonylamino group having preferably 7 to 32 carbon atoms and more preferably 7 to 24 carbon atoms, such as a phenoxycarbonylamino group);
a sulfonamide group (a sulfonamide group having preferably 1 to 48 carbon atoms and more preferably 1 to 24 carbon atoms, such as a methanesulfonamide group, a butanesulfonamide group, a benzenesulfonamide group, a hexadecanesulfonamide group, and a cyclohexanesulfonamide group);
a sulfamoylamino group (a sulfamoylamino group having preferably 1 to 48 carbon atoms and more preferably 1 to 24 carbon atoms, such as an N,N-dipropylsulfamoylamino group and an N-ethyl-N-dodecylsulfamoylamino group);
an azo group (an azo group having preferably 1 to 32 carbon atoms and more preferably 1 to 24 carbon atoms, such as a phenylazo group and a 3-pyrazolylazo group);
an alkylthio group (an alkylthio group having preferably 1 to 48 carbon atoms and more preferably 1 to 24 carbon atoms, such as a methylthio group, an ethylthio group, an octylthio group, and a cyclohexylthio group);
an arylthio group (an arylthio group having preferably 6 to 48 carbon atoms and more preferably 6 to 24 carbon atoms, such as a phenylthio group);
a heterocyclic thio group (a heterocyclic thio group having preferably 1 to 32 carbon atoms and more preferably 1 to 18 carbon atoms, such as a 2-benzothiazolylthio group, a 2-pyridylthio group, and a 1-phenyltetrazolylthio group);
an alkylsulfinyl group (an alkylsulfinyl group having preferably 1 to 32 carbon atoms and more preferably 1 to 24 carbon atoms, such as a dodecanesulfinyl group);
an arylsulfinyl group (an arylsulfinyl group having preferably 6 to 32 carbon atoms and more preferably 6 to 24 carbon atoms, such as a phenylsulfinyl group);
an alkylsulfonyl group (an alkylsulfonyl group having preferably 1 to 48 carbon atoms and more preferably 1 to 24 carbon atoms, such as a methylsulfonyl group, an ethylsulfonyl group, a propylsulfonyl group, a butylsulfonyl group, an isopropylsulfonyl group, a 2-ethylhexylsulfonyl group, a hexadecylsulfonyl group, an octylsulfonyl group, and a cyclohexylsulfonyl group);
an arylsulfonyl group (an arylsulfonyl group having preferably 6 to 48 carbon atoms and more preferably 6 to 24 carbon atoms, such as a phenylsulfonyl group and a 1-naphthylsulfonyl group);
a sulfamoyl group (a sulfamoyl group having preferably 32 or less carbon atoms and more preferably 24 or less carbon atoms, such as a sulfamoyl group, an N,N-dipropylsulfamoyl group, an N-ethyl-N-dodecylsulfamoyl group, an N-ethyl-N-phenylsulfamoyl group, an N-cyclohexylsulfamoyl group, and an N-(2-ethylhexyl)sulfamoyl group);
a phosphonyl group (a phosphonyl group having preferably 1 to 32 carbon atoms and more preferably 1 to 24 carbon atoms, such as a phenoxyphosphonyl group, an octyloxyphosphonyl group, and a phenylphosphonyl group);
a phosphinoylamino group (a phosphinoylamino group having preferably 1 to 32 carbon atoms and more preferably 1 to 24 carbon atoms, such as a diethoxyphosphinoylamino group and a dioctyloxyphosphinoylamino group);
an epoxy group; —NHCOCH₃; —SO₂NHC₂H₄OCH₃; and —NHSO₂CH₃,
in which two or more thereof may be combined.

These substituents may be further substituted with these substituents. In addition, in a case of having two or more of the substituents, the substituents may be the same or different from each other. Furthermore, if possible, these substituents may be bonded to each other to form a ring.

### [Optical Film]

The optical film according to the embodiment of the present invention is an optical film including an optically anisotropic layer.

The optically anisotropic layer of the optical film according to the embodiment of the present invention is a liquid crystal cured layer formed by using a liquid crystal composition which contains a liquid crystal compound and a surfactant, and immobilizing the liquid crystal compound in a vertically aligned state.

In addition, the above-described liquid crystal compound is a liquid crystal compound exhibiting reverse wavelength dispersibility (hereinafter, also abbreviated as “reverse dispersion liquid crystal compound”).

In addition, the above-described surfactant is a surfactant having a repeating unit H including a fluorinated alkyl group or a silicon-containing group.

In addition, at least one surfactant has the above-described repeating unit H, a repeating unit K including a functional group capable of being crosslinked with the liquid crystal compound, and a repeating unit M including a mesogen group.

In addition, a content of a repeating unit X in the above-described surfactant, in which a difference in I/O value with the above-described liquid crystal compound (hereinafter, also abbreviated as “ΔI/O value”) is 0.9 or more, is 8 mol % or less. In the following, a surfactant having the repeating unit H, the repeating unit K, and the repeating unit M, and having the content of the repeating unit X of 8 mol % or less is also abbreviated as “specific surfactant”.

In a case where the above-described liquid crystal composition contains two or more kinds of liquid crystal compounds, each of requirements regarding the above-described liquid crystal compound is a requirement regarding a liquid crystal compound having the highest content (hereinafter, also abbreviated as “main liquid crystal”).

In addition, in a case where the above-described liquid crystal composition contains two or more kinds of surfactants, a requirement regarding the above-described content of the repeating unit X in the above-described surfactant is a requirement which is satisfied independently by all kinds of the surfactants. The repeating unit X is a repeating unit defined from different viewpoint from the repeating unit H, the repeating unit K, and the repeating unit M described above, so that, for example, even a repeating unit corresponding to the repeating unit H may fall within the definition of the repeating unit X, and needless to say, another repeating unit which does not fall under the repeating unit H, the repeating unit K, and the repeating unit M described above may also fall within the definition of the repeating unit X.

In the present invention, as described above, in a case where the content of the repeating unit having a difference in I/O value with the liquid crystal compound of 0.9 or more is set to 8 mol % or less in the surfactant contained in the liquid crystal composition, both the occurrence of precipitates and cohesive failure can be suppressed in a liquid crystal cured layer (optically anisotropic layer) obtained by immobilizing the liquid crystal compound in a vertically aligned state.

The reason why the effect is exhibited is not clear in detail, but the present inventor has presumed as follows.

That is, it is considered that, in a case where the content of the repeating unit having a ΔI/O value with the liquid crystal compound of 0.9 or more is set to 8 mol % or less in the surfactant contained in the liquid crystal composition, when applying the liquid crystal composition, a surface of a coating liquid is covered with a material having high compatibility with the liquid crystal compound, so that the liquid crystal compound is suppressed from precipitating in a drying process. In addition, it is considered that, since the compatibility between the surfactant and the liquid crystal compound is high, adhesiveness of these compounds is improved, so that the cohesive failure is suppressed.

### [Optically Anisotropic Layer]

As described above, the optically anisotropic layer of the optical film according to the embodiment of the present invention is a liquid crystal cured layer formed by using the liquid crystal composition which contains the reverse dispersion liquid crystal compound and the specific surfactant, and immobilizing the reverse dispersion liquid crystal compound in a vertically aligned state.

Here, the vertical alignment in a case where the liquid crystal compound is a rod-like liquid crystal compound is also referred to as a homeotropic alignment, and means an alignment in which an angle between a surface (main surface) of the optically anisotropic layer and a director of the rod-like liquid crystal compound is within a range of 70° to 90°. An alignment in which the above-described angle is within a range of 80° to 90° is preferable, and an alignment in which the above-described angle is within a range of 85° to 90° is more preferable.

In addition, the vertical alignment in a case where the liquid crystal compound is a disk-like liquid crystal compound means an alignment in which an angle between a surface (main surface) of the optically anisotropic layer and a disc plane of the disk-like liquid crystal compound is within a range of 70° to 90°. An alignment in which the above-described angle is within a range of 80° to 90° is preferable, and an alignment in which the above-described angle is within a range of 85° to 90° is more preferable.

As described above, the liquid crystal composition used for forming the optically anisotropic layer (liquid crystal cured layer) is a composition containing the reverse dispersion liquid crystal compound and the specific surfactant, and may be a composition containing a solvent, a polymerization initiator, and the like, which will be described later.

In the liquid crystal composition of the present invention, a content of a dichroic substance (that is, a coloring agent having different absorbance depending on a direction) is preferably less than 1% by mass with respect to the total mass of solid contents of the liquid crystal composition, and it is more preferable that the liquid crystal composition does not contain the dichroic substance.

### <Reverse Dispersion Liquid Crystal Compound>

As described above, the reverse dispersion liquid crystal compound contained in the liquid crystal composition is a liquid crystal compound exhibiting reverse wavelength dispersibility.

Here, the “liquid crystal compound exhibiting reverse wavelength dispersibility” refers to a liquid crystal compound in which, in a case where an in-plane retardation (Re) value or a thickness direction retardation (Rth) value of a retardation film produced using the liquid crystal compound is measured at a specific wavelength (visible light range), the Re value or the Rth value increases as a measurement wavelength increases.

The reverse dispersion liquid crystal compound is not particularly limited, and a known liquid crystal compound exhibiting reverse wavelength dispersibility in the related art can be used.

In general, the liquid crystal compound can be classified into a rod-like type and a disk-like type according to the shape thereof. Each of the types can further be classified into a low-molecular-weight type and a high-molecular-weight type. The “high-molecular-weight” generally refers to a compound having a degree of polymerization of 100 or more (Polymer Physics-Phase Transition Dynamics, written by Masao Doi, p. 2, published by Iwanami Shoten, 1992).

In the present invention, any liquid crystal compound can be used, and it is preferable to use a rod-like liquid crystal compound or a discotic liquid crystal compound (disk-like liquid crystal compound). A mixture of two or more kinds of the rod-like liquid crystal compounds, a mixture of two or more kinds of the disk-like liquid crystal compounds, or a mixture of the rod-like liquid crystal compound and the disk-like liquid crystal compound may be used.

As the rod-like liquid crystal compound, for example, rod-like liquid crystal compounds described in Claim 1 of JP1999-513019A (JP-H11-513019A) or paragraphs [0026] to [0098] of JP2005-289980A can be preferably used; and as the discotic liquid crystal compounds, for example, discotic liquid crystal compounds described in paragraphs [0020] to [0067] of JP2007-108732A or paragraphs [0013] to [0108] of JP2010-244038A can be preferably used, but the liquid crystal compounds are not limited thereto.

In the present invention, from the viewpoint of improving durability of the optically anisotropic layer, it is preferable that the reverse dispersion liquid crystal compound has a polymerizable group, and it is more preferable that the reverse dispersion liquid crystal compound has two or more polymerizable groups.

Here, the polymerizable group is not particularly limited, but is preferably a radically polymerizable group or a cationically polymerizable group.

A known radically polymerizable group can be used as the radically polymerizable group, and suitable examples thereof include an acryloyloxy group or a methacryloyloxy group. In this case, it is known that the acryloyloxy group generally has a high polymerization rate, and from the viewpoint of improving productivity, the acryloyloxy group is preferable. However, the methacryloyloxy group can also be used as the polymerizable group.

A known cationically polymerizable group can be used as the cationically polymerizable group, and specific examples thereof include an alicyclic ether group, a cyclic acetal group, a cyclic lactone group, a cyclic thioether group, a spiro orthoester group, and a vinyloxy group. Among these, an alicyclic ether group or a vinyloxy group is suitable, and an epoxy group, an oxetanyl group, or a vinyloxy group is particularly preferable.

Examples of a particularly preferred polymerizable group include a polymerizable group represented by any one of Formulae (P-1) to (P-20).

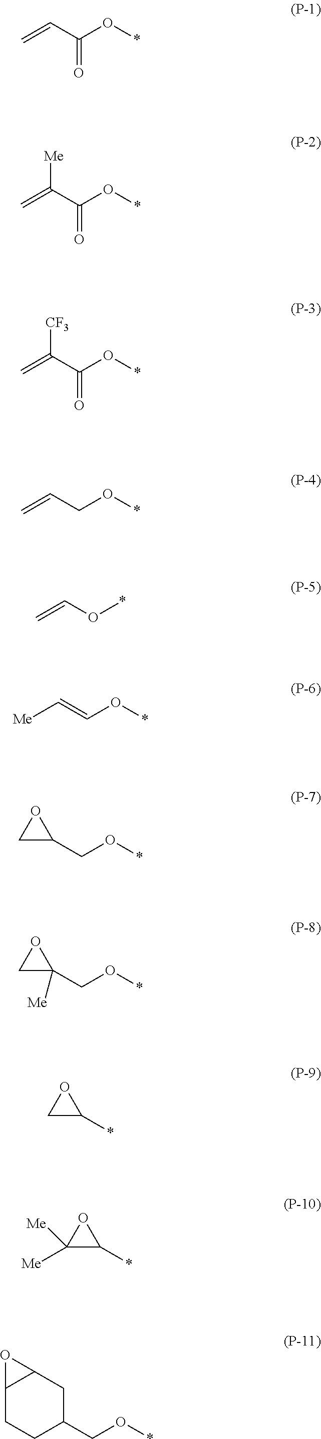

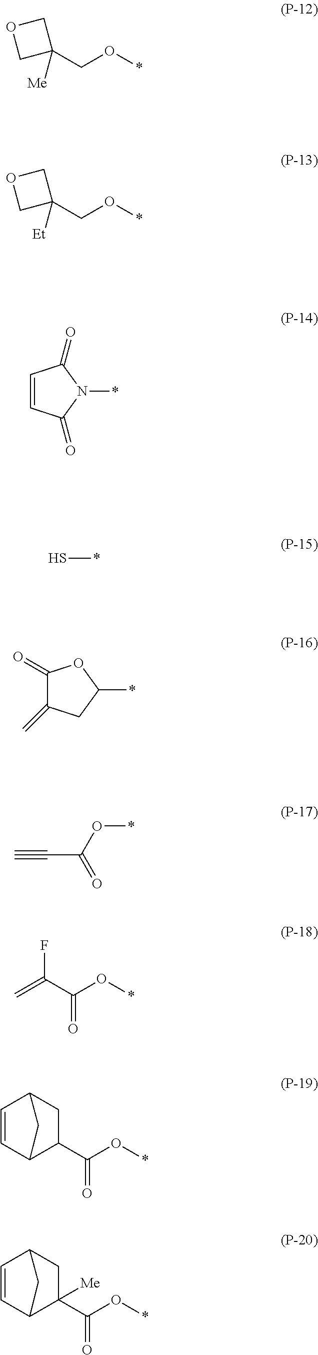

In the present invention, for the reason that the aligning properties are improved, it is more preferable that the reverse dispersion liquid crystal compound is a compound represented by Formula (A).

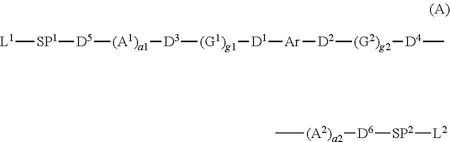

In Formula (A), a1, a2, g1, and g2 each independently represent 0 or 1. Here, at least one of a1 or g1 represents 1 and at least one of a2 or g2 represents 1.

In addition, D¹, D², D³, D⁴, D⁵, and D⁶ each independently represent a single bond, —CO—, —O—, —S—, —C(═S)—, —CR¹R²—, —CR³=CR⁴—, —NR¹—, or a divalent linking group consisting of a combination of two or more of these groups, where R¹ to R⁵ each independently represent a hydrogen atom, a fluorine atom, or an alkyl group having 1 to 12 carbon atoms.

In addition, G¹ and G² each independently represent an aromatic ring having 6 to 20 carbon atoms, which may have a substituent, or a divalent alicyclic hydrocarbon group having 5 to 20 carbon atoms, which may have a substituent, where one or more of —CH₂—'s constituting the alicyclic hydrocarbon group may be substituted with —O—, —S—, or —NH—.

In addition, A¹ and A² each independently represent an aromatic ring having 6 to 20 carbon atoms, which may have a substituent, or a divalent alicyclic hydrocarbon group having 5 to 20 carbon atoms, which may have a substituent, where one or more of —CH₂—'s constituting the alicyclic hydrocarbon group may be substituted with —O—, —S—, or —NH—.

In addition, SP¹ and SP² each independently represent a single bond or a divalent aliphatic hydrocarbon group having 1 to 20 carbon atoms. Here, one or more of —CH₂—'s constituting the aliphatic hydrocarbon group may be substituted with —O—, —S—, —NH—, —N(Q)-, or —CO—. Q represents a substituent.

In addition, L¹ and L² each independently represent a monovalent organic group, where at least one of L¹ or L² represents a polymerizable group. Here, in a case where Ar is an aromatic ring represented by Formula (Ar-3), at least one of L¹, L², or L³ or L⁴ in Formula (Ar-3) represents a polymerizable group.

In addition, Ar represents any aromatic ring selected from the group consisting of groups represented by Formulae (Ar-1) to (Ar-7) described later.

In Formula (A), it is preferable that all of a1, a2, g1, and g2 are 1 for the reason that the liquid crystal composition easily exhibits a liquid crystalline state of a smectic phase.

In addition, it is preferable that both a1 and a2 are 0 and both g1 and g2 are 1 for the reason that durability of the optically anisotropic layer is improved.

In Formula (A), examples of the divalent linking group represented by one aspect of D¹, D², D³, D⁴, D⁵, and D⁶ include —CO—, —O—, —S—, —C(═S)—, —CR¹R²—, —CR³=CR⁴—, —NR⁵—, or a divalent linking group consisting of a combination of two or more of these groups. R¹ to R⁵ each independently represent a hydrogen atom, a fluorine atom, or an alkyl group having 1 to 12 carbon atoms.

Specific examples of the divalent linking group include —CO—, —O—, —CO—O—, —C(═S)O—, —CR¹R²—, —CR¹R²—CR¹R²—, —O—CR¹R²—, —CR¹R²—O—CR¹R²—, —CO—O—CR¹R²—, —O—CO—CR¹R²—CR¹R²—O—CO—CR¹R²—, —CR¹R²—CO—O—CR¹R²—, —NR⁵—CR¹R²—, and —CO—NR⁵—. R¹, R², and R⁵ each independently represent a hydrogen atom, a fluorine atom, or an alkyl group having 1 to 12 carbon atoms.

Among these, any of —CO—, —O—, or —CO—O— is preferable.

In Formula (A), examples of the aromatic ring having 6 to 20 carbon atoms, represented by one aspect of G¹ and G², include aromatic hydrocarbon rings such as a benzene ring, a naphthalene ring, an anthracene ring, and a phenanthroline ring; and aromatic heterocyclic rings such as a furan ring, a pyrrole ring, a thiophene ring, a pyridine ring, a thiazole ring, and a benzothiazole ring. Among these, a benzene ring (for example, a 1,4-phenyl group) is preferable.

In Formula (A), the divalent alicyclic hydrocarbon group having 5 to 20 carbon atoms, represented by one aspect of G¹ and G², is preferably a 5-membered ring or a 6-membered ring. In addition, the alicyclic hydrocarbon group may be saturated or unsaturated, but a saturated alicyclic hydrocarbon group is preferable. As the divalent alicyclic hydrocarbon group represented by G¹ and G², for example, the description of paragraph [0078] of JP2012-21068A can be referred to, the contents of which are incorporated herein by reference.

In the present invention, G¹ and G² in Formula (A) are each preferably a cycloalkane ring for the reason that durability of the optically anisotropic layer is improved.

Specific examples of the cycloalkane ring include a cyclohexane ring, a cycloheptane ring, a cyclooctane ring, a cyclododecane ring, and a cyclodocosane ring.

Among these, a cyclohexane ring is preferable, a 1,4-cyclohexylene group is more preferable, and a trans-1,4-cyclohexylene group is still more preferable.

In addition, with regard to G¹ and G² in Formula (A), examples of the substituent which may be included in the aromatic ring having 6 to 20 carbon atoms and the divalent alicyclic hydrocarbon group having 5 to 20 carbon atoms include the substituents described in the above substituent group A; and among these, an alkyl group, an alkoxy group, an alkoxycarbonyl group, an alkylcarbonyloxy group, or a halogen atom is preferable.

In Formula (A), examples of the aromatic ring having 6 to 20 carbon atoms, represented by one aspect of A¹ and A², include the same aromatic rings as those described for G¹ and G² in Formula (A).

In addition, in Formula (A), examples of the divalent alicyclic hydrocarbon group having 5 to 20 carbon atoms, represented by one aspect of A¹ and A², include the same groups as those described for G¹ and G² in Formula (A).

In A¹ and A², examples of the substituent which may be included in the aromatic ring having 6 to 20 carbon atoms or the divalent alicyclic hydrocarbon group having 5 to 20 carbon atoms include the same as those described for the substituent which may be included in each of G¹ and G² in Formula (A).

Examples of the divalent aliphatic hydrocarbon group having 1 to 20 carbon atoms, represented by one aspect of SP¹ and SP² in Formula (A), include a linear or branched alkylene group having 1 to 20 carbon atoms, a linear or branched alkenylene group having 1 to 20 carbon atoms, and a linear or branched alkynylene group having 1 to 20 carbon atoms.

As the linear or branched alkylene group having 1 to 20 carbon atoms, an alkylene group having 1 to 12 carbon atoms is preferable and an alkylene group having 1 to 10 carbon atoms is more preferable; and suitable examples thereof include a methylene group, an ethylene group, a propylene group, a butylene group, a pentylene group, and a hexylene group.

As the linear or branched alkenylene group having 1 to 20 carbon atoms, an alkenylene group having 2 to 10 carbon atoms is preferable and an alkenylene group having 2 to 4 carbon atoms is more preferable; and suitable examples thereof include an ethenylene group.

As the linear or branched alkynylene group having 1 to 20 carbon atoms, an alkynylene group having 2 to 10 carbon atoms is preferable and an alkynylene group having 2 to 4 carbon atoms is more preferable; and suitable examples thereof include an ethynylene group.

As described above, one or more of —CH₂—'s constituting the aliphatic hydrocarbon group may be substituted with —O—, —S—, —NH—, —N(Q)-, or —CO—; and examples of the substituent represented by Q include the substituents described in the above substituent group A. Among these, an alkyl group, an alkoxy group, an alkoxycarbonyl group, an alkylcarbonyloxy group, or a halogen atom is preferable.

In Formula (A), examples of the monovalent organic group represented by L¹ and L² include the substituents described in the above substituent group A; and among these, suitable examples thereof include an alkyl group, an aryl group, a heteroaryl group, an alkoxy group, a cyano group, and a carboxy group.

The alkyl group may be linear, branched, or cyclic, but is preferably linear. The number of carbon atoms in the alkyl group is preferably 1 to 30, more preferably 1 to 20, and still more preferably 1 to 10.

In addition, the aryl group may be monocyclic or polycyclic, but is preferably monocyclic. The number of carbon atoms in the aryl group is preferably 6 to 25 and more preferably 6 to 10.

In addition, the heteroaryl group may be monocyclic or polycyclic. The number of heteroatoms constituting the heteroaryl group is preferably 1 to 3. The heteroatom constituting the heteroaryl group is preferably a nitrogen atom, a sulfur atom, or an oxygen atom. The number of carbon atoms in the heteroaryl group is preferably 6 to 18 and more preferably 6 to 12.

In addition, the alkyl group, the aryl group, and the heteroaryl group may be unsubstituted or may have a substituent. Examples of the substituent include the substituents described in the above substituent group A; and among these, an alkyl group, an alkoxy group, an alkoxycarbonyl group, an alkylcarbonyloxy group, or a halogen atom is preferable.

In addition, suitable examples of the polymerizable group represented by at least one of L¹ or L² include the polymerizable group represented by any of Formulae (P-1) to (P-20) described above.

In Formula (A), as described above, Ar represents any aromatic ring selected from the group consisting of groups represented by Formulae (Ar-1) to (Ar-7). In Formulae (Ar-1) to (Ar-7), * represents a bonding position to D¹ or D² in Formula (A).

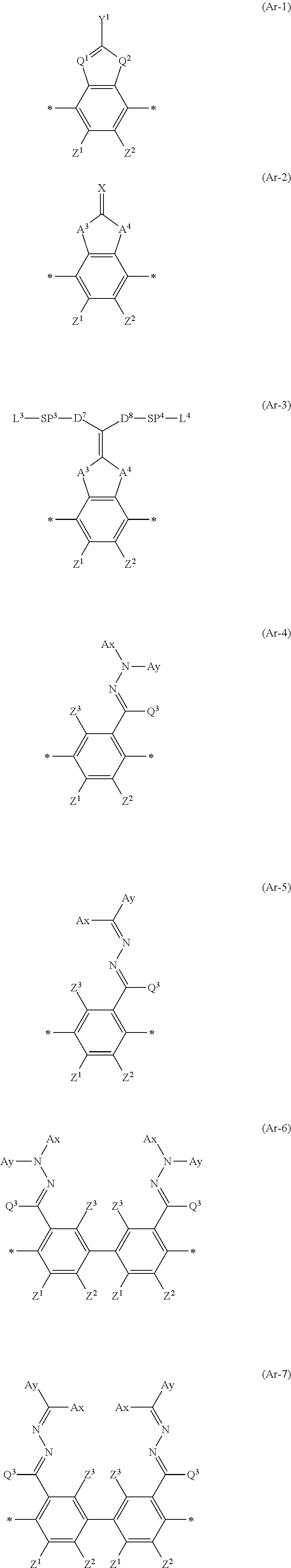

In Formula (Ar-1), Q¹ represents N or CH, Q² represents —S—, —O—, or —N(R⁶)—, where R⁶ represents a hydrogen atom or an alkyl group having 1 to 6 carbon atoms, Yⁱ represents an aromatic hydrocarbon group having 6 to 12 carbon atoms, which may have a substituent, an aromatic heterocyclic group having 3 to 12 carbon atoms, which may have a substituent, or an alicyclic hydrocarbon group having 6 to 20 carbon atoms, which may have a substituent, and one or more of —CH₂—'s constituting the alicyclic hydrocarbon group may be substituted with —O—, —S—, or —NH—.

Here, specific examples of the alkyl group having 1 to 6 carbon atoms, represented by one aspect of R⁶, include a methyl group, an ethyl group, a propyl group, an isopropyl group, a n-butyl group, an isobutyl group, a sec-butyl group, a tert-butyl group, a n-pentyl group, and a n-hexyl group.

Examples of the aromatic hydrocarbon group having 6 to 12 carbon atoms, represented by one aspect of Y¹, include aryl groups such as a phenyl group, a 2,6-diethylphenyl group, and a naphthyl group.

Examples of the aromatic heterocyclic group having 3 to 12 carbon atoms, represented by one aspect of Y¹, include a heteroaryl group such as a thienyl group, a thiazolyl group, a furyl group, a pyridyl group, a benzofuryl group, and a benzothiazolyl group; and a group obtained by removing one hydrogen atom from any of an indole ring, a benzofuran ring, a benzothiophene ring, a benzimidazole ring, a benzothiazole ring, or a benzoxazole ring. Among these, as the aromatic heterocyclic group having 3 to 12 carbon atoms, represented by Y¹, a group obtained by removing one hydrogen atom from a benzofuran ring or a benzothiazole ring is preferable.

Examples of the alicyclic hydrocarbon group having 6 to 20 carbon atoms, represented by one aspect of Y¹, include a cyclohexylene group, a cyclopentylene group, a norbornylene group, and an adamantylene group.

In addition, examples of the substituent which may be included in Y¹ include the substituents described in the above substituent group A; and among these, an alkyl group, an alkoxy group, an alkoxycarbonyl group, an alkylcarbonyloxy group, a nitro group, a cyano group, or a halogen atom is preferable.

In addition, in Formulae (Ar-1) to (Ar-7), Z¹, Z², and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a monovalent aromatic heterocyclic group having 6 to 20 carbon atoms, a halogen atom, a cyano group, a nitro group, —OR⁷, —NR⁸R⁹, —SR¹⁰, —COOR¹¹, or —COR¹², where R⁷ to R¹² each independently represent a hydrogen atom or an alkyl group having 1 to 6 carbon atoms and Z¹ and Z² may be bonded to each other to form an aromatic ring.

As the monovalent aliphatic hydrocarbon group having 1 to 20 carbon atoms, an alkyl group having 1 to 15 carbon atoms is preferable, an alkyl group having 1 to 8 carbon atoms is more preferable; and specifically, a methyl group, an ethyl group, an isopropyl group, a tert-pentyl group (1,1-dimethylpropyl group), a tert-butyl group, or 1,1-dimethyl-3,3-dimethyl-butyl group is still more preferable, and a methyl group, an ethyl group, or a tert-butyl group is particularly preferable.

Examples of the monovalent alicyclic hydrocarbon group having 3 to 20 carbon atoms include monocyclic saturated hydrocarbon groups such as a cyclopropyl group, a cyclobutyl group, a cyclopentyl group, a cyclohexyl group, a cycloheptyl group, a cyclooctyl group, a cyclodecyl group, a methylcyclohexyl group, and an ethylcyclohexyl group; monocyclic unsaturated hydrocarbon groups such as a cyclobutenyl group, a cyclopentenyl group, a cyclohexenyl group, a cycloheptenyl group, a cyclooctenyl group, a cyclodecenyl group, a cyclopentadienyl group, a cyclohexadienyl group, a cyclooctadienyl group, and a cyclodecadiene group; and polycyclic saturated hydrocarbon groups such as a bicyclo[2.2.1]heptyl group, a bicyclo[2.2.2]octyl group, a tricyclo[5.2.1.0^{2,6}]decyl group, a tricyclo[3.3.1.1^{3,7}]decyl group, a tetracyclo[6.2.1.1^{3,6}.0^{2,7}]dodecyl group, and an adamantyl group.

Specific examples of the monovalent aromatic hydrocarbon group having 6 to 20 carbon atoms include a phenyl group, a 2,6-diethylphenyl group, a naphthyl group, and a biphenyl group, and an aryl group having 6 to 12 carbon atoms (particularly, a phenyl group) is preferable.

Specific examples of the monovalent aromatic heterocyclic group having 6 to 20 carbon atoms include a 4-pyridyl group, a 2-furyl group, a 2-thienyl group, a 2-pyrimidinyl group, and a 2-benzothiazolyl group.

Examples of the halogen atom include a fluorine atom, a chlorine atom, a bromine atom, and an iodine atom, and among these, a fluorine atom, a chlorine atom, or a bromine atom is preferable.

On the other hand, specific examples of the alkyl group having 1 to 6 carbon atoms represented by one aspect of R⁷ to R¹⁰ include a methyl group, an ethyl group, a propyl group, an isopropyl group, a n-butyl group, an isobutyl group, a sec-butyl group, a tert-butyl group, a n-pentyl group, and a n-hexyl group.

As described above, Z¹ and Z² may be bonded to each other to form an aromatic ring, and examples of a structure in a case where Z¹ and Z² in Formula (Ar-1) are bonded to each other to form an aromatic ring include a group represented by Formula (Ar-1a). In Formula (Ar-1a), * represents a bonding position to D¹ or D² in Formula (A) described above.

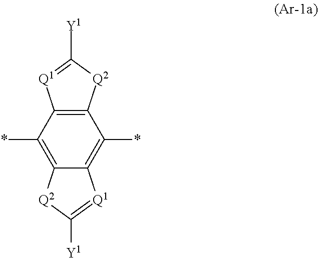

Here, in Formula (Ar-1a), examples of Q¹, Q², and Y¹ include the same as those described in Formula (Ar-1) above.

In addition, in Formulae (Ar-2) and (Ar-3), A³ and A⁴ each independently represent a group selected from the group consisting of —O—, —N(R¹³)—, —S—, and —CO—, and R¹³ represents a hydrogen atom or a substituent.

Examples of the substituent represented by one aspect of R¹³ include the substituents described in the above substituent group A; and among these, an alkyl group, an alkoxy group, an alkoxycarbonyl group, an alkylcarbonyloxy group, or a halogen atom is preferable.

In addition, in Formula (Ar-2), X represents a non-metal atom of Group 14 to Group 16. Here, a hydrogen atom or a substituent may be bonded to the non-metal atom. In addition, examples of the non-metal atom of Groups 14 to 16, represented by X, include an oxygen atom, a sulfur atom, a nitrogen atom to which a hydrogen atom or a substituent is bonded [=N—R^{N1}, R^{N1} represents a hydrogen atom or a substituent], and a carbon atom to which a hydrogen atom or a substituent is bonded [=C—(R^{C1})₂, R^{C1} represents a hydrogen atom or a substituent].

Suitable examples of the substituent include the substituents described in the above substituent group A; and among these, examples thereof include an alkyl group, an alkoxy group, an alkyl-substituted alkoxy group, a cyclic alkyl group, an aryl group (for example, a phenyl group, a naphthyl group, or the like), a cyano group, an amino group, a nitro group, an alkylcarbonyl group, a sulfo group, and a hydroxyl group.

In addition, in Formula (Ar-3), D⁷ and D⁸ each independently represent a single bond, —CO—, —O—, —S—, —C(═S)—, —CR¹R²—, —CR³=CR⁴—, —NR⁵—, or a divalent linking group consisting of a combination of two or more of these groups, where R¹ to R⁵ each independently represent a hydrogen atom, a fluorine atom, or an alkyl group having 1 to 12 carbon atoms.

Here, specific examples of the divalent linking group include the same groups as those described for D¹, D², D³, D⁴, D⁵, and D⁶ in Formula (A) above.

In addition, in Formula (Ar-3), SP³ and SP⁴ each independently represent a single bond or a divalent aliphatic hydrocarbon group having 1 to 20 carbon atoms. Here, one or more of —CH₂—'s constituting the aliphatic hydrocarbon group may be substituted with —O—, —S—, —NH—, —N(Q)-, or —CO—. Q represents a substituent. Examples of the substituent represented by Q include the substituents described in the above substituent group A; and among these, an alkyl group, an alkoxy group, an alkoxycarbonyl group, an alkylcarbonyloxy group, or a halogen atom is preferable.

Here, examples of the divalent aliphatic hydrocarbon group include the same groups as those described for SP¹ and SP² in Formula (A) above.

In addition, in Formula (Ar-3), L³ and L⁴ each independently represent a monovalent organic group.

Here, examples of the monovalent organic group include the same as those described for L¹ and L² in Formula (A) above.

In addition, in Formulae (Ar-4) to (Ar-7), Ax represents an organic group having 2 to 30 carbon atoms, which has at least one aromatic ring selected from the group consisting of an aromatic hydrocarbon ring and an aromatic heterocyclic ring.

In addition, in Formulae (Ar-4) to (Ar-7), Ay represents a hydrogen atom, an alkyl group having 1 to 12 carbon atoms, which may have a substituent, or an organic group having 2 to 30 carbon atoms which has at least one aromatic ring selected from the group consisting of an aromatic hydrocarbon ring and an aromatic heterocyclic ring.

Here, the aromatic rings in Ax and Ay may have a substituent, and Ax and Ay may be bonded to each other to form a ring.

In addition, Q³ represents a hydrogen atom or an alkyl group having 1 to 6 carbon atoms, which may have a substituent.

Examples of Ax and Ay include those described in paragraphs [0039] to [0095] of WO2014/010325A.

In addition, specific examples of the alkyl group having 1 to 6 carbon atoms, represented by Q³, include a methyl group, an ethyl group, a propyl group, an isopropyl group, a n-butyl group, an isobutyl group, a sec-butyl group, a tert-butyl group, a n-pentyl group, and a n-hexyl group; and examples of the substituent include the substituents described in the above substituent group A. Among these, an alkyl group, an alkoxy group, an alkoxycarbonyl group, an alkylcarbonyloxy group, or a halogen atom is preferable.

Examples of the reverse dispersion liquid crystal compound include a compound represented by General Formula (1) described in JP2010-084032A (particularly, a compound described in paragraphs [0067] to [0073]), a compound represented by General Formula (II) described in JP2016-053709A (particularly, a compound described in paragraphs [0036] to [0043]), a compound represented by General Formula (1) described in JP2016-081035A (particularly, a compound described in paragraphs [0043] to [0055]), and a compound described in paragraphs [0025] to [0056] of WO2021/060427A.

In addition, a content of the reverse dispersion liquid crystal compound is preferably 40% to 99% by mass, more preferably 50% to 99% by mass, and still more preferably more than 50% by mass and 99% by mass or less with respect to the total mass of solid contents of the liquid crystal composition.

### <Specific Surfactant>

As described above, the specific surfactant contained in the liquid crystal composition is a surfactant having the repeating unit H including a fluorinated alkyl group or a silicon-containing group, the repeating unit K including a functional group capable of being crosslinked with the reverse dispersion liquid crystal compound, and the repeating unit M including a mesogen group, in which the content of the repeating unit X in the surfactant, in which the ΔI/O value with the reverse dispersion liquid crystal compound is 0.9 or more, is 8 mol % or less.

Here, the “I/O value” is used as one unit for predicting various physicochemical properties of an organic compound. The magnitude of organicity is obtained by performing a comparison on the number of carbon atoms, and the magnitude of inorganicity is obtained by performing a comparison between the boiling points of hydrocarbons with the same number of carbon atoms. For example, the organicity value of one (—CH₂—) (actually, C) is determined as 20, and the inorganicity value thereof is determined as 100 from an influence of a hydroxyl group (—OH) on the boiling point. Based on the inorganicity value of (—OH) of 100, values of other substituents (inorganic groups) are obtained, which are shown as “inorganic group table”. The ratio I/O of inorganicity value (I) to organicity value (0) obtained for each molecule according to the inorganic group table is defined as “I/O value”. It is shown that the larger the I/O value, the higher the hydrophilicity; and the smaller the I/O value, the higher the hydrophobicity.

In the present invention, the “1/O value” is a value of “inorganicity (I)/organicity (O)” obtained by a method described in “YOSHIO KOUDA et al., “New edition Organic Conceptual Diagram Foundation and Application”, November 2008, SANKYO PUBLISHING”.

### (Repeating Unit H: Repeating Unit Including Fluorinated Alkyl Group)

Examples of the repeating unit including a fluorinated alkyl group in the repeating unit H include a repeating unit represented by Formula (H-1).

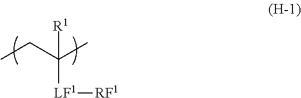

In Formula (H-1), R¹ represents a hydrogen atom or an alkyl group having 1 to 20 carbon atoms.

In addition, LF¹ represents a single bond or a divalent linking group.

In addition, RF¹ represents a group containing a fluorine atom.

In Formula (H-1), as described above, R¹ represents a hydrogen atom or an alkyl group having 1 to 20 carbon atoms; and among these, a hydrogen atom or an alkyl group having 1 to 10 carbon atoms is preferable, a hydrogen atom or an alkyl group having 1 to 4 carbon atoms is more preferable, and a hydrogen atom or a methyl group is still more preferable.

In addition, in Formula (H-1), as described above, LF¹ represents a single bond or a divalent linking group; and among these, a divalent linking group selected from the group consisting of —O—, —COO—, —OCO—, a divalent aliphatic group, and a combination thereof is preferable. —COO— represents that a carbon to which R¹ is bonded is bonded to C═O and RF¹ is bonded to O; and —OCO— represents that a carbon to which R¹ is bonded is bonded to O and RF¹ is bonded to C═O.

Here, examples of the divalent aliphatic group include a divalent aliphatic chain group and a divalent aliphatic cyclic group. As the divalent aliphatic chain group, an alkylene group having 1 to 20 carbon atoms is preferable, and an alkylene group having 1 to 10 carbon atoms is more preferable. As the divalent aliphatic cyclic group, a cycloalkylene group having 3 to 20 carbon atoms is preferable, and a cycloalkylene group having 3 to 15 carbon atoms is more preferable.

Among these, as LF¹, —COO— or —OCO— is preferable, and —COO— is more preferable.

In addition, in Formula (H-1), as described above, RF¹ represents a group containing a fluorine atom; and among these, an alkyl group in which at least one hydrogen atom (hereinafter, also referred to as “fluoroalkyl group”) is substituted with a fluorine atom, having 1 to 20 carbon atoms, is preferable, a fluoroalkyl group having 1 to 18 carbon atoms is more preferable, and a fluoroalkyl group having 2 to 15 carbon atoms is still more preferable.

In addition, the above-described fluoroalkyl group preferably includes at least one —CF₃ group.

In addition, the number of fluorine atoms is preferably 1 to 25, more preferably 3 to 21, and most preferably 5 to 21.

In the present invention, the repeating unit represented by Formula (H-1) is preferably a repeating unit represented by Formula (H-1-1).

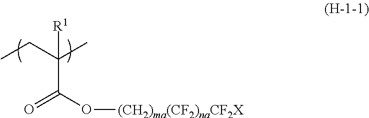

In Formula (H-1-1), R¹ represents a hydrogen atom or an alkyl group having 1 to 20 carbon atoms, as in R¹ in Formula (H-1), and a suitable aspect thereof is also the same.

In addition, in Formula (H-1-1), ma and na each independently represent an integer of 0 to 19. Among these, from the viewpoint of availability of raw materials, ma is preferably an integer of 1 to 8 and more preferably an integer of 1 to 5. In addition, na is preferably an integer of 1 to 15, more preferably an integer of 1 to 12, still more preferably an integer of 2 to 10, and most preferably an integer of 3 to 7. Here, the sum of ma and na is an integer of 0 to 19.

In addition, in Formula (H-1-1), X represents a hydrogen atom or a fluorine atom.

Specific examples of a monomer forming the repeating unit represented by Formula (H-1) or (H-1-1) include 2,2,2-trifluoroethyl(meth)acrylate, 2,2,3,3,3-pentafluoropropyl (meth)acrylate, 2-(perfluorobutyl)ethyl (meth)acrylate, 2-(perfluorohexyl)ethyl (meth)acrylate, 2-(perfluorooctyl)ethyl (meth)acrylate, 2-(perfluorodecyl)ethyl (meth)acrylate, 2-(perfluoro-3-methylbutyl)ethyl (meth)acrylate, 2-(perfluoro-5-methylhexyl)ethyl (meth)acrylate, 2-(perfluoro-7-methyloctyl)ethyl (meth)acrylate, 3-perfluorobutyl-2-hydroxypropyl (meth)acrylate, 3-perfluorohexyl-2-hydroxypropyl (meth)acrylate, 3-perfluorooctyl-2-hydroxypropyl (meth)acrylate, 3-(perfluoro-3-methylbutyl)-2-hydroxypropyl (meth)acrylate, 3-(perfluoro-5-methylhexyl)-2-hydroxypropyl (meth)acrylate, and 3-(perfluoro-7-methyloctyl)-2-hydroxypropyl (meth)acrylate.

### (Repeating Unit H: Repeating Unit Including Silicon-Containing Group)

Examples of the repeating unit including a silicon-containing group in the repeating unit H include a repeating unit represented by Formula (H-2).

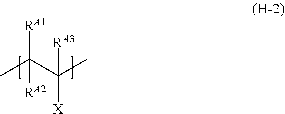

In Formula (H-2), R^{A1} and R^{A2} each independently represent a hydrogen atom or an alkyl group.

Examples of the alkyl group in R^{A1} and R^{A2} include a linear alkyl group having 1 to 18 carbon atoms (preferably having 1 to 6 carbon atoms and more preferably having 1 to 4 carbon atoms), and a branched or cyclic alkyl group having 3 to 18 carbon atoms (preferably having 3 to 9 carbon atoms and more preferably having 3 to 6 carbon atoms). Specific examples thereof include a methyl group, an ethyl group, a propyl group, a butyl group, an isopropyl group, a tert-butyl group, and a cyclohexyl group.

It is preferable that both R^{A1} and R^{A2} are hydrogen atoms.

In Formula (H-2), R^{A3} represents a hydrogen atom, a halogen atom, or a substituent.

Examples of the substituent in R^{A3} include an alkyl group, an alkenyl group, an aryl group, and a substituent having a linking group and having a structure of Formula (a) described later at a terminal.

Specific examples of the substituent having a linking group and having a structure of Formula (a) described later at a terminal include —CH₂—CO-L^{A1}-L^{A2}-(Si(R^{a1})(R^{a2})(R^{a3}))ₘ. The definition of -L^{A1}-L^{A2}-(Si(R^{a1})(R^{a2})(R^{a3}))ₘ is the same as the definition of -L^{A1}-L^{A2}-(Si(R^{a1})(R^{a2})(R^{a3}))ₘ in Formula (H-2-1) described later, and suitable aspects thereof are also the same.

The substituent in R^{A3} is preferably an alkyl group, more preferably a linear alkyl group having 1 to 4 carbon atoms, and still more preferably a methyl group or an ethyl group.

It is preferable that R^{A3} is a hydrogen atom or a methyl group.

In Formula (H-2), X represents a substituent (hereinafter, also referred to as “substituent X”) including one or more structures represented by Formula (a) described later (hereinafter, also referred to as “group a”).

As the substituent X, a monovalent hydrocarbon group having one or more groups a is preferable. The monovalent hydrocarbon group in the substituent X may be linear, branched, or cyclic, and is preferably linear or branched.

Examples of the monovalent hydrocarbon group in the substituent X include a monovalent aliphatic hydrocarbon group and a monovalent aromatic hydrocarbon group. The monovalent hydrocarbon group is preferably a monovalent aliphatic hydrocarbon group, and more preferably an alkyl group. The alkyl group may be linear, branched, or cyclic, and is preferably linear or branched. The number of carbon atoms in the alkyl group is preferably 1 to 30, more preferably 2 to 25, and still more preferably 2 to 20.

Here, one or more of —CH₂—'s constituting a part of the monovalent hydrocarbon group in the substituent X may be each independently substituted with a divalent group such as —O—, —CO—, —C(O)—O—, —C(O)—N(R^{X10})—, —[O—Si(R^{X11})₂]ₙₓ—, and —Si(R^{X12})₂—; and it is preferable that these —CH₂—'s are substituted with these divalent groups.

R^{X10} represents a hydrogen atom or an alkyl group having 1 to 6 carbon atoms, and is preferably a hydrogen atom. The alkyl group may be linear, branched, or cyclic, and is preferably linear or branched.

R^{X11} and R^{X12} each independently represent a hydrogen atom, a hydroxy group, the group a (that is, the group represented by Formula (a) described later), or an alkyl group having 1 to 6 carbon atoms; and an alkyl group having 1 to 6 carbon atoms or the group a is preferable. The alkyl group may be linear, branched, or cyclic, and is preferably linear or branched. Two R^{X11}'s may be the same or different from each other. Two R^{X12}'s may be the same or different from each other.

nx is a number of 1 or more, and is preferably a number of 1 to 100 and more preferably a number of 1 to 11. In a case where nx is a number of 2 or more, a plurality of [O—Si(R^{X11})₂]'s may be the same or different from each other.

Examples of one suitable aspect of the substituent X include a group represented by Formula (X1).

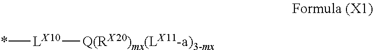

In Formula (X1), * represents a bonding position.

In Formula (X1), L^{X10} represents a divalent hydrocarbon group, and L^{X11} represents —O— or a divalent hydrocarbon group. Here, one or more of —CH₂—'s constituting a part of the divalent hydrocarbon group may be each independently substituted with a divalent group such as —O—, —CO—, —C(O)—O—, —C(O)—N(R^{X10})—, —[O—Si(R^{X11})₂]ₙₓ—, and —Si(R^{X12})₂—. The definitions of R^{X10}, R^{X10}, R^{X12}, and nx are as described above. Two R^{X11}'s may be the same or different from each other. Two R^{X12}'s may be the same or different from each other. In a case where nx is a number of 2 or more, a plurality of [O—Si(R^{X11})₂]'s may be the same or different from each other.

Examples of the divalent hydrocarbon group in L^{X10} and L^{X11} include a divalent aliphatic hydrocarbon group and a divalent aromatic hydrocarbon group. The divalent hydrocarbon group is preferably a divalent aliphatic hydrocarbon group, and more preferably an alkylene group. The alkylene group may be linear, branched, or cyclic, and is preferably linear or branched and more preferably linear. The number of carbon atoms in the alkylene group is preferably 1 to 30, more preferably 2 to 25, and still more preferably 2 to 20.

In Formula (X1), R^{X20} represents a hydrogen atom or a monovalent hydrocarbon group. The definition of the monovalent hydrocarbon group in R^{X20} is the same as the monovalent hydrocarbon group described in the substituent X above.

In Formula (X1), Q represents a carbon atom or a silicon atom.

In Formula (X1), a represents the structure (group) represented by Formula (a) described later.

In Formula (X1), mx represents an integer of 0 to 2. In a case where mx is an integer of 0 or 1, a plurality of (L^{X11}-a)'s may be the same or different from each other. In a case where mx is 2, two R^{X20}'s may be the same or different from each other.

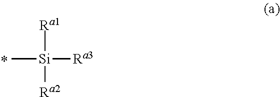

In Formula (a), * represents a bonding position.

In addition, R^{a1}, R^{a2}, and R^{a3} each independently represent an alkyl group, an alkenyl group, an aryl group, or an alkylene-aryl group, which may have a substituent. Specific examples of the substituent include the above-described substituent W; and among the above, a halogen atom, an alkyl group, an alkylcarbonyl group, an alkoxycarbonyl group, an alkylcarbonyloxy group, or an alkoxy group is preferable.

Examples of the alkyl group include a linear alkyl group having 1 to 18 carbon atoms and a branched or cyclic alkyl group having 3 to 18 carbon atoms. Specific examples thereof include a methyl group, an ethyl group, a propyl group, a butyl group, an isopropyl group, a tert-butyl group, and a cyclohexyl group.

Examples of the alkenyl group include an alkenyl group having 2 to 12 carbon atoms. Specific examples thereof include a vinyl group, a 1-propenyl group, a 1-butenyl group, a 1-methyl-1-propenyl group, a 1-cyclopentenyl group, and a 1-cyclohexenyl group.

Examples of the aryl group include an aryl group having 6 to 12 carbon atoms. Specific examples thereof include a phenyl group, an α-methylphenyl group, and a naphthyl group.

Examples of the alkylene-aryl group include an alkylene-aryl group having 7 to 30 carbon atoms.

The number of groups a included in the substituent X is 1 or more; and from the viewpoint of further improving the alignment degree of the optically anisotropic layer, it is preferably 2 or more, and more preferably 3 or more, and from the viewpoint of further suppressing alignment defects, it is preferably 18 or less, more preferably 12 or less, still more preferably 9 or less, and particularly preferably 6 or less.

From the viewpoint of further improving the effect of the present invention and further improving the alignment degree of the optically anisotropic layer, the repeating unit H is preferably a repeating unit represented by Formula (H-2-1).

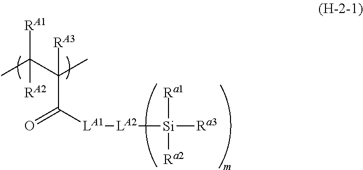

In Formula (H-2-1), R^{A1}, R^{A2}, and R^{A3} are the same as those described in Formula (A) above, and R^{a1}, R^{a2}, and R^{a3} are the same as those described in Formula (a) above. In a case where m in Formula (H-2-1) is an integer of 2 or more, a plurality of R^{a1}'s may be the same or different from each other, a plurality of R^{a2}'s may be the same or different from each other, and a plurality of R^{a3}'s may be the same or different from each other.

In Formula (H-2-1), L^{A1} represents a single bond, —O—, or —NR^{Z}—. Here, Rz represents a hydrogen atom or a substituent.

Regarding —NR^{Z}— in L^{A1}, the substituent in Rz is preferably an alkyl group, more preferably a linear alkyl group having 1 to 4 carbon atoms, and still more preferably a methyl group or an ethyl group.

As L^{A1}, —O— or NH— is preferable, and —O— is more preferable.

In Formula (H-2-1), L^{A2} represents a single bond or an (m+1)-valent linking group. Suitable examples of the (m+1)-valent linking group in L^{A2} include an (m+1)-valent hydrocarbon group having 1 to 10 carbon atoms, which may have a substituent, in which a part of carbon atoms constituting the hydrocarbon group may be substituted with a heteroatom. Specific examples thereof include —(CH₂)ₚ—Si(—O—*)₃ in which a part of carbon atoms is substituted with a heteroatom, as a tetravalent linking group. p represents an integer of 1 to 6, and * represents a bonding position to Si in Formula (H-2-1).

Here, as the substituent which may be included in the hydrocarbon group, an alkyl group is preferable, a linear alkyl group having 1 to 4 carbon atoms is more preferable, and a methyl group or an ethyl group is still more preferable.

In addition, examples of the heteroatom include a silicon atom, an oxygen atom, and a nitrogen atom.

In Formula (H-2-1), m represents an integer of 1 or more; and from the viewpoint of further improving the alignment degree of the optically anisotropic layer, it is preferably an integer of 2 or more, and more preferably an integer of 3 or more, and from the viewpoint of further suppressing alignment defects, it is preferably an integer of 18 or less, more preferably an integer of 12 or less, still more preferably an integer of 9 or less, and particularly preferably an integer of 6 or less.

Specific examples of the repeating unit H include repeating units corresponding to monomers represented by Formulae K-1 to K-33.

The monomer represented by Formula K-29 is a mixture of monomers having different numbers of —(O—Si(CH₃)₂)—, and thus the average value thereof is represented as n≈11. The same applies to the monomer represented by Formula K-30.

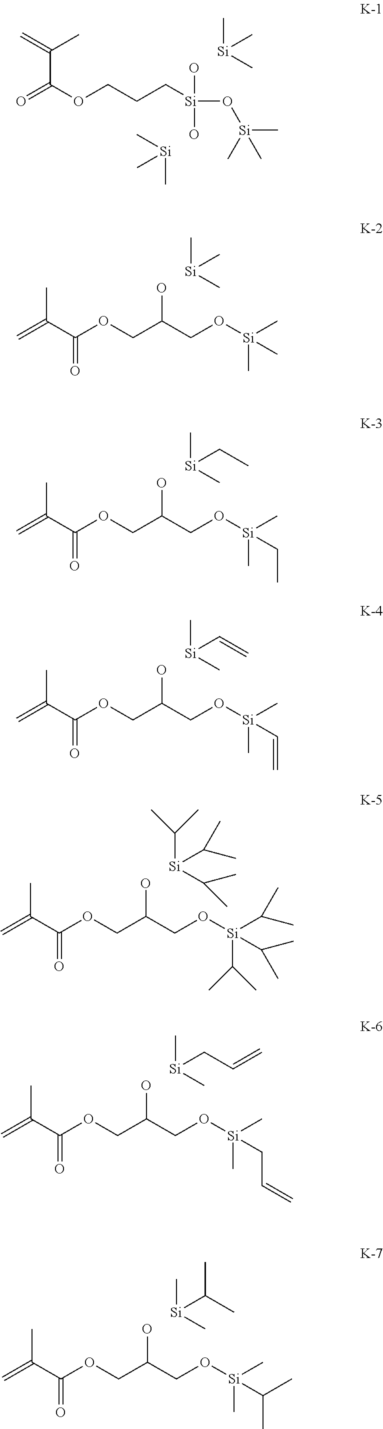

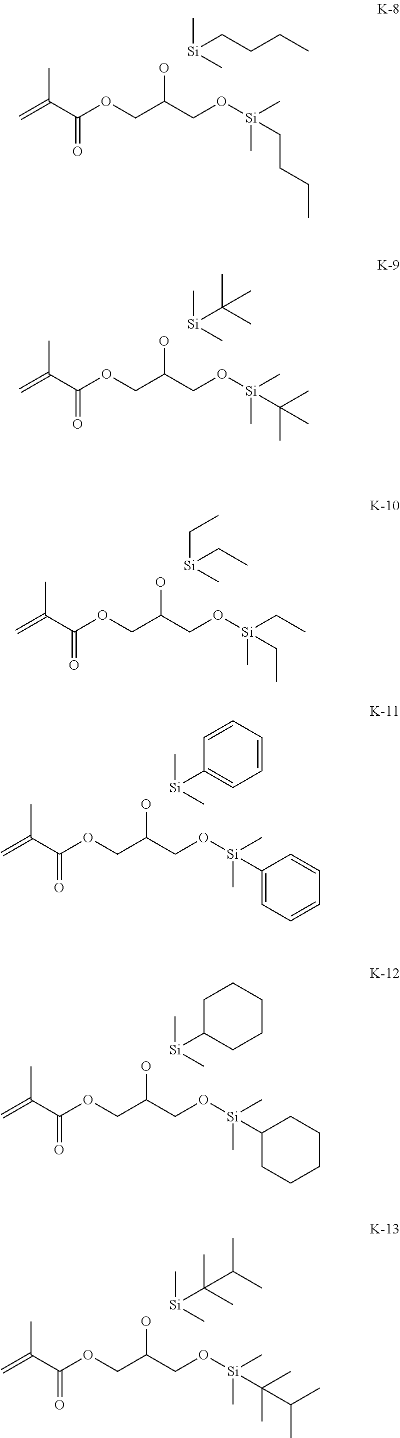

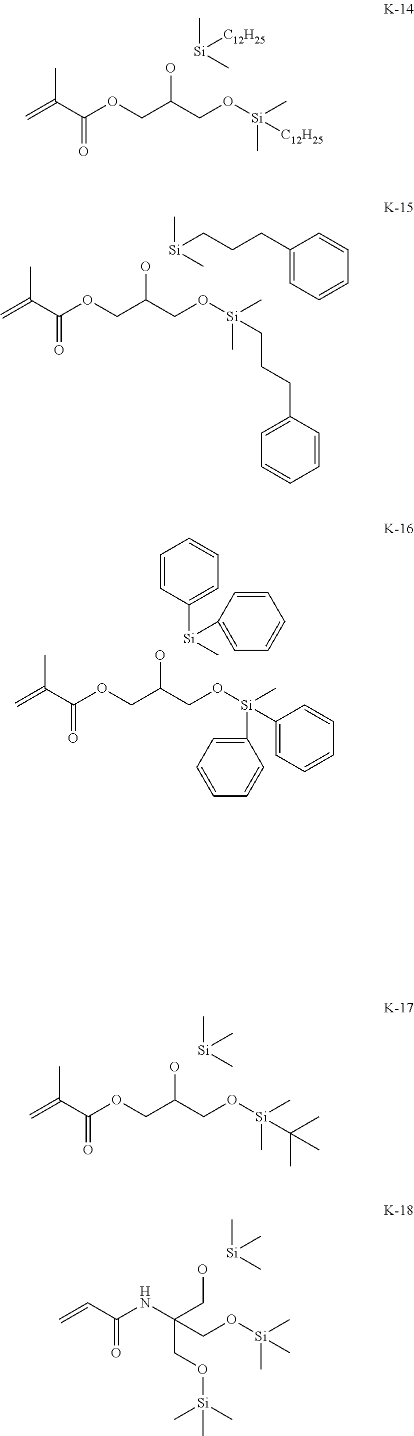

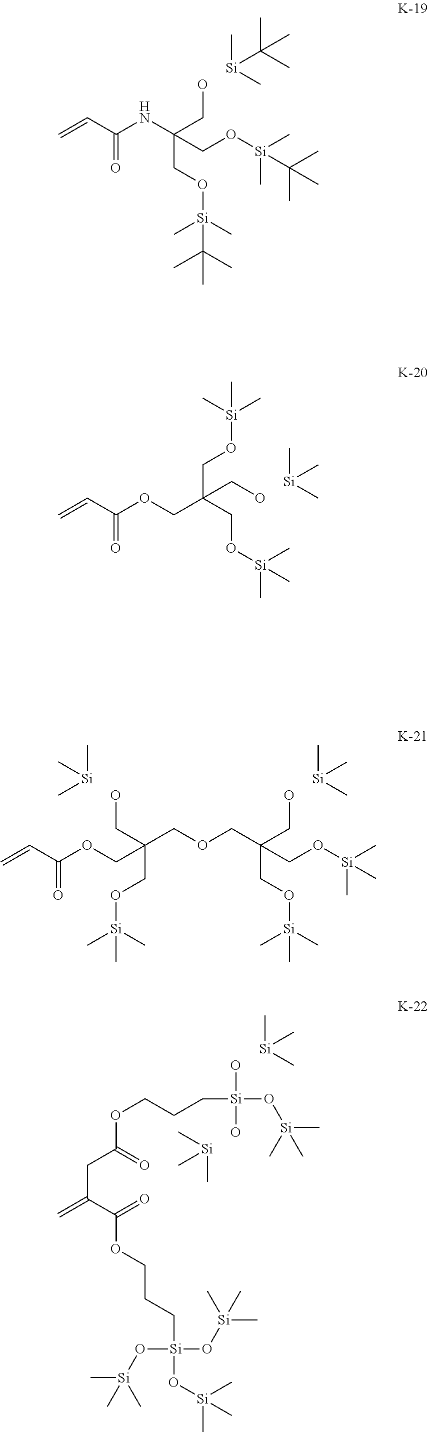

### (Repeating Unit K)

Examples of the repeating unit K including a functional group capable of being crosslinked with the reverse dispersion liquid crystal compound include a repeating unit represented by Formula (K).

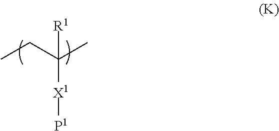

In Formula (K), R¹ represents a hydrogen atom or an alkyl group having 1 to 20 carbon atoms; and among these, a hydrogen atom or an alkyl group having 1 to 10 carbon atoms is preferable, a hydrogen atom or an alkyl group having 1 to 4 carbon atoms is more preferable, and a hydrogen atom or a methyl group is still more preferable.

In addition, in Formula (K), X¹ represents a single bond, —O—, —S—, —COO—, —OCO—, —CONR²—, —NR²COO—, —CR²N—, a substituted or unsubstituted divalent aliphatic group, a substituted or unsubstituted divalent aromatic group, or a divalent linking group selected from the group consisting of a combination thereof, where R² represents a hydrogen atom, an alkyl group having 1 to 20 carbon atoms, or —X¹—P¹. In a case where R² is —X¹—P¹, P¹ represents a polymerizable group as in P¹ of Formula (K) described above.

Examples of the substituted or unsubstituted divalent aliphatic group represented by X¹ include an alkylene group having 1 to 20 carbon atoms, which may have a substituent, and a cycloalkylene group having 3 to 20 carbon atoms (for example, a cyclohexylene group), which may have a substituent; and among these, an alkylene group having 1 to 15 carbon atoms is preferable, an alkylene group having 1 to 8 carbon atoms is more preferable, and a methylene group, an ethylene group, a propylene group, or a butylene group is still more preferable.

In addition, examples of the substituted or unsubstituted divalent aromatic group represented by X¹ include a divalent aromatic hydrocarbon group which may have a substituent or a divalent aromatic heterocyclic group which may have a substituent. Examples of the divalent aromatic hydrocarbon group include a group obtained by removing one hydrogen atom from each of two carbon atoms constituting a ring structure of an aromatic hydrocarbon ring such as a benzene ring, a naphthalene ring, an anthracene ring, a triphenylene ring, and a fluorene ring; and among these, a phenylene group or a naphthylene group obtained by removing one hydrogen atom from each of two carbon atoms constituting a ring structure of a benzene ring or a naphthalene ring is preferable. On the other hand, examples of the divalent aromatic heterocyclic group include a group obtained by removing one hydrogen atom from each of two carbon atoms constituting a ring structure of an aromatic heterocyclic ring such as a furan ring, a pyrrole ring, a thiophene ring, a pyridine ring, a thiazole ring, a benzothiazole ring, an oxadiazole ring, a thiazolothiazole ring, and a phenanthroline ring.

Examples of the substituent which may be included in the divalent aliphatic group or the divalent aromatic group include a halogen atom, a hydroxy group, an amino group, an acryloyloxy group, a methacryloyloxy group, an alkyl group having 1 to 20 carbon atoms, a carboxyl group, a cyano group, —X¹—P¹, and a group obtained by combining these groups with any one or more of —O—, —S—, —COO—, —OCO—, —CONR²—, —NR²COO—, —HC═CH—, or —CR²N—. R² represents a hydrogen atom, an alkyl group having 1 to 20 carbon atoms, or —X¹—P¹. In a case where R² is —X¹—P¹, P¹ represents a polymerizable group as in P¹ of Formula (K) described above.

The alkyl group having 1 to 20 carbon atoms represented by R² is preferably an alkyl group having 1 to 6 carbon atoms, and specific examples thereof include a methyl group, an ethyl group, a propyl group, an isopropyl group, a n-butyl group, an isobutyl group, a sec-butyl group, a tert-butyl group, a n-pentyl group, and a n-hexyl group.

In addition, in Formula (K), P¹ represents a polymerizable group.

Suitable examples of the polymerizable group include the polymerizable group represented by any of Formulae (P-1) to (P-20) described above, and among these, an acryloyloxy group or a methacryloyloxy group is preferable.

In the present invention, from the viewpoint of ease of manufacturing, economy, and radical polymerizability, the above-described repeating unit represented by Formula (K) is preferably a repeating unit in which, in Formula (K), R¹ is a hydrogen atom or a methyl group, and X¹ is a divalent linking group selected from the group consisting of a combination of —O—, —COO—, —OCO—, and a substituted or unsubstituted divalent aliphatic group (preferably an alkylene group having 2 to 8 carbon atoms).

Specific examples of the above-described repeating unit represented by Formula (K) include repeating units represented by the following formulae.

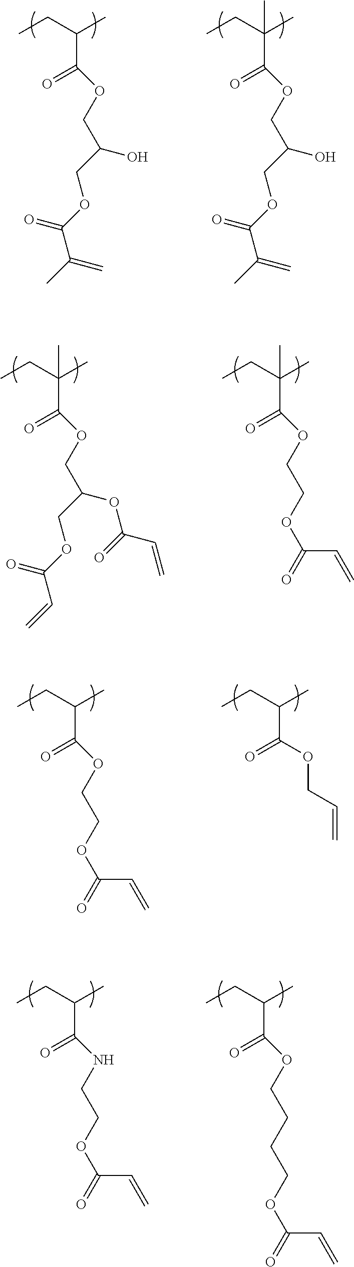

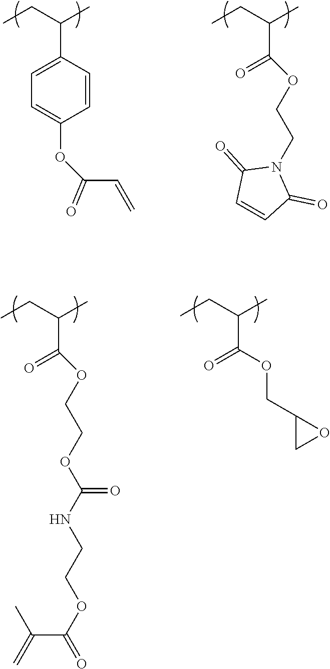

In the present invention, from the viewpoint of further suppressing the cohesive failure, a content of the repeating unit K is preferably 10 mol % or more, more preferably 10 to 40 mol %, and still more preferably 15 to 35 mol %.

### (Repeating Unit M)

Examples of the repeating unit M including a mesogen group include a repeating unit represented by Formula (M).

Here, the mesogen group is a group representing a main skeleton of a liquid crystal molecule which contributes to liquid crystal formation, the details thereof are as described in M1 of Formula (M) described below, and specific examples thereof are also the same as described below.

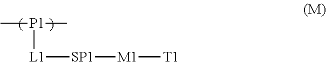

In Formula (M), P1 represents a main chain of the repeating unit, L1 represents a single bond or a divalent linking group, SP1 represents a spacer group, M1 represents a mesogen group having two or more cyclic structures, and T1 represents a terminal group.

In Formula (M), specific examples of the main chain of the repeating unit, represented by P1, include groups represented by Formulae (P1-A) to (P1-D); and among these, from the viewpoint of diversity and handleability of a monomer serving as a raw material, a group represented by Formula (P1-A) is preferable.

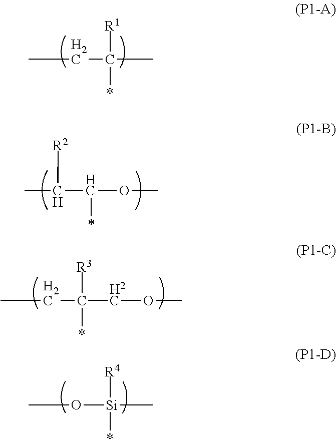

In Formulae (P1-A) to (P1-D), “*” represents a bonding position to L1 in Formula (M).

In Formulae (P1-A) to (P1-D), R¹, R², R³, and R⁴ each independently represent a hydrogen atom, a halogen atom, a cyano group, an alkyl group having 1 to 10 carbon atoms, or an alkoxy group having 1 to 10 carbon atoms. The above-described alkyl group may be a linear or branched alkyl group, or an alkyl group having a cyclic structure (cycloalkyl group). In addition, the number of carbon atoms in the above-described alkyl group is preferably 1 to 5.

It is preferable that the group represented by Formula (P1-A) is one unit of a partial structure of poly(meth)acrylic acid ester, which is obtained by polymerization of (meth)acrylic acid ester.

It is preferable that the group represented by Formula (P1-B) is an ethylene glycol unit formed by ring-opening polymerization of an epoxy group of a compound having the epoxy group.

It is preferable that the group represented by Formula (P1-C) is a propylene glycol unit formed by ring-opening polymerization of an oxetane group of a compound having the oxetane group.

It is preferable that the group represented by Formula (P1-D) is a siloxane unit of a polysiloxane obtained by polycondensation of a compound having at least one of an alkoxysilyl group or a silanol group. Here, examples of the compound having at least one of an alkoxysilyl group or a silanol group include a compound having a group represented by Formula SiR¹⁴(OR¹⁵)₂—. In the formula, R¹⁴ has the same definition as that for R¹⁴ in Formula (P1-D), and a plurality of R¹⁵'s each independently represent a hydrogen atom or an alkyl group having 1 to 10 carbon atoms.

In Formula (M), L1 represents a single bond or a divalent linking group.

Examples of the divalent linking group represented by L1 include —C(O)O—, —OC(O)—, —O—, —S—, —C(O)NR³—, —NR³C(O)—, —SO₂—, and —NR³R⁴—. In the formulae, R³ and R⁴ each independently represent a hydrogen atom or an alkyl group having 1 to 6 carbon atoms, which may have a substituent (for example, the substituent W described above).

In a case where P1 is the group represented by Formula (P1-A), from the viewpoint of improving the alignment degree of the optically anisotropic layer, L1 is preferably a group represented by —C(O)O—.

In a case where P1 is the group represented by any of Formulae (P1-B) to (P1-D), from the viewpoint of improving the alignment degree of the optically anisotropic layer, L1 is preferably a single bond.

In Formula (M), from the viewpoint of easily expressing liquid crystallinity and availability of raw materials, it is preferable that the spacer group represented by SP1 has at least one structure selected from the group consisting of an alkyleneoxy structure, an oxyethylene structure, an oxypropylene structure, a polysiloxane structure, and an alkylene fluoride structure.

Here, the alkyleneoxy structure represented by SP1 is preferably a group represented by *¹—(CH₂)ₙ₁—O—*². In the formula, n1 represents an integer of 1 to 20, *¹ represents a bonding position to L1 in Formula (1) described above, and *2 represents a bonding position to M1 in Formula (1) described above. From the viewpoint of improving the alignment degree of the optically anisotropic layer, n1 is preferably an integer of 1 to 10, more preferably an integer of 2 to 8, and most preferably 2 to 6.

In addition, the oxyethylene structure represented by SP1 is preferably a group represented by *—(CH₂—CH₂O)ₙ₂—*. In the formula, n2 represents an integer of 1 to 20, and * represents a bonding position to L1 or M1 in Formula (1). From the viewpoint of improving the alignment degree of the optically anisotropic layer, n2 is preferably an integer of 2 to 10, more preferably an integer of 2 to 4, and most preferably 3.

In addition, the oxypropylene structure represented by SP1 is preferably a group represented by *—(CH(CH₃)—CH₂O)ₙ₄—*— from the viewpoint of improving the alignment degree of the optically anisotropic layer. In the formula, n3 represents an integer of 1 to 3, and * represents a bonding position to L1 or M1.

In addition, the polysiloxane structure represented by SP1 is preferably a group represented by *—(Si(CH₃)₂—O)ₙ₄—*— from the viewpoint of improving the alignment degree of the optically anisotropic layer. In the formula, n4 represents an integer of 6 to 10, and * represents a bonding position to L1 or M1.

In addition, the fluorinated alkylene structure represented by SP1 is preferably a group represented by *—(CF₂—CF₂)ₙ₅—*— from the viewpoint of improving the alignment degree of the optically anisotropic layer. In the formula, n5 represents an integer of 6 to 10, and * represents a bonding position to L1 or M1.

The mesogen group represented by M1 in Formula (M) is a group representing a main skeleton of a liquid crystal molecule which contributes to liquid crystal formation. A liquid crystal molecule exhibits liquid crystallinity which is in an intermediate state (mesophase) between a crystal state and an isotropic liquid state. The mesogen group is not particularly limited, and for example, particular description on pages 7 to 16 of “Flussige Kristalle in Tabellen II” (VEB Deutsche Verlag fur Grundstoff Industrie, Leipzig, 1984) and particular description in Chapter 3 of “Liquid Crystal Handbook” (Maruzen, 2000) edited by Liquid Crystal Handbook Editing Committee can be referred to.

As the mesogen group, for example, a group having at least one cyclic structure selected from the group consisting of an aromatic hydrocarbon group, a heterocyclic group, and an alicyclic group is preferable.

From the viewpoint of improving the alignment degree of the optically anisotropic layer, the mesogen group preferably has an aromatic hydrocarbon group, more preferably has two to four aromatic hydrocarbon groups, and still more preferably has two or three aromatic hydrocarbon groups.

As the mesogen group, from the viewpoint of exhibiting the liquid crystallinity, adjusting the liquid crystal phase transition temperature, availability of raw materials, synthetic suitability, and improving the alignment degree of the optically anisotropic layer, a group represented by Formula (M1-A) or Formula (M1-B) is preferable, and a group represented by Formula (M1-B) is more preferable.

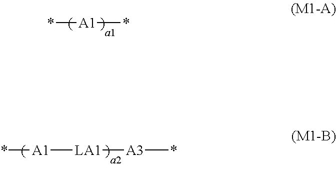

In Formula (M1-A), A1 represents a divalent group selected from the group consisting of an aromatic hydrocarbon group, a heterocyclic group, and an alicyclic group. These groups may be substituted with an alkyl group, a fluorinated alkyl group, an alkoxy group, or a substituent (for example, the above-described substituent W).

It is preferable that the divalent group represented by A1 is a 4- to 6-membered ring. In addition, the divalent group represented by A1 may be a monocyclic ring or a fused ring.
* represents a bonding position to SP1 or T1.

Examples of the divalent aromatic hydrocarbon group represented by A1 include a phenylene group, a naphthylene group, a fluorene-diyl group, an anthracene-diyl group, and a tetracene-diyl group. From the viewpoint of design diversity of the mesogenic skeleton and the availability of raw materials, a phenylene group or a naphthylene group is preferable and a phenylene group is more preferable.

The divalent heterocyclic group represented by A1 may be any of aromatic or non-aromatic, but from the viewpoint of further improving the alignment degree, a divalent aromatic heterocyclic group is preferable.

Examples of atoms other than carbon, constituting the divalent aromatic heterocyclic group, include a nitrogen atom, a sulfur atom, and an oxygen atom. In a case where the aromatic heterocyclic group has a plurality of atoms other than carbon, constituting a ring, these atoms may be the same or different from each other.

Specific examples of the divalent aromatic heterocyclic group include a pyridylene group (pyridine-diyl group), a pyridazine-diyl group, an imidazole-diyl group, a thienylene group (thiophene-diyl group), a quinolylene group (quinoline-diyl group), an isoquinolylene group (isoquinoline-diyl group), an oxazole-diyl group, a thiazole-diyl group, an oxadiazole-diyl group, a benzothiazole-diyl group, a benzothiadiazole-diyl group, a phthalimido-diyl group, a thienothiazole-diyl group, a thiazolothiazole-diyl group, a thienothiophene-diyl group, and a thienooxazole-diyl group.

Specific examples of the divalent alicyclic group represented by A1 include a cyclopentylene group and a cyclohexylene group.

In Formula (M1-A), a1 represents an integer of 1 to 10. In a case where a1 represents 2 or more, a plurality of A1's may be the same or different from each other.

In Formula (M1-B), A2 and A3 each independently represent a divalent group selected from the group consisting of an aromatic hydrocarbon group, a heterocyclic group, and an alicyclic group. Specific examples and suitable aspects of A2 and A3 are the same as those for A1 in Formula (M1-A), and thus the description thereof will not be repeated.

In Formula (M1-B), a2 represents an integer of 1 to 10, and in a case where a2 is 2 or more, a plurality of A2's may be the same or different from each other, a plurality of A3's may be the same or different from each other, and a plurality of LAi's may be the same or different from each other. From the viewpoint of improving the alignment degree of the optically anisotropic layer, a2 is preferably 1 or 2.

In Formula (M1-B), in a case where a2 is 1, LA1 represents a divalent linking group. In a case where a2 is 2 or more, a plurality of LA1's each independently represent a single bond or a divalent linking group, and at least one of the plurality of LA1's is a divalent linking group. In a case where a2 is 2, from the viewpoint of improving the alignment degree of the optically anisotropic layer, it is preferable that both of two LA1's are divalent linking groups.

Examples of the divalent linking group represented by LA1 in Formula (M1-B) include —O—, —(CH₂)_{g}—, —(CF₂)_{g}—, —Si(CH₃)₂—, —(Si(CH₃)₂₀)_{g}—, —(OSi(CH₃)₂)_{g}— (g represents an integer of 1 to 10), —N(Z)—, —C(Z)═C(Z′)—, —C(Z)=N—, —N═C(Z)—, —C(Z)₂—C(Z′)₂—, —C(O)—, —OC(O)—, —C(O)O—, —O—C(O)O—, —N(Z)C(O)—, —C(O)N(Z)—, —C(Z)═C(Z′)—C(O)O—, —O—C(O)—C(Z)═C(Z′)—, —C(Z)=N—, —N═C(Z)—, —C(Z)═C(Z′)—C(O)N(Z″)—, —N(Z″)—C(O)—C(Z)═C(Z′)—, —C(Z)═C(Z′)—C(O)—S—, —S—C(O)—C(Z)═C(Z′)—, —C(Z)=N—N═C(Z′)—(Z, Z′, and Z″ independently represent hydrogen, a C₁ to C₄ alkyl group, a cycloalkyl group, an aryl group, a cyano group, or a halogen atom), —C≡C—, —N═N—, —S—, —S(O)—, —S(O)(O)—, —(O)S(O)O—, —O(O)S(O)O—, —SC(O)—, and —C(O)S—. Among these, from the viewpoint of improving the alignment degree of the optically anisotropic layer, —C(O)O— is preferable. LA1 may be a group obtained by combining two or more of these groups.

Specific examples of M1 include the following structures. In the following specific examples, “Ac” represents an acetyl group.

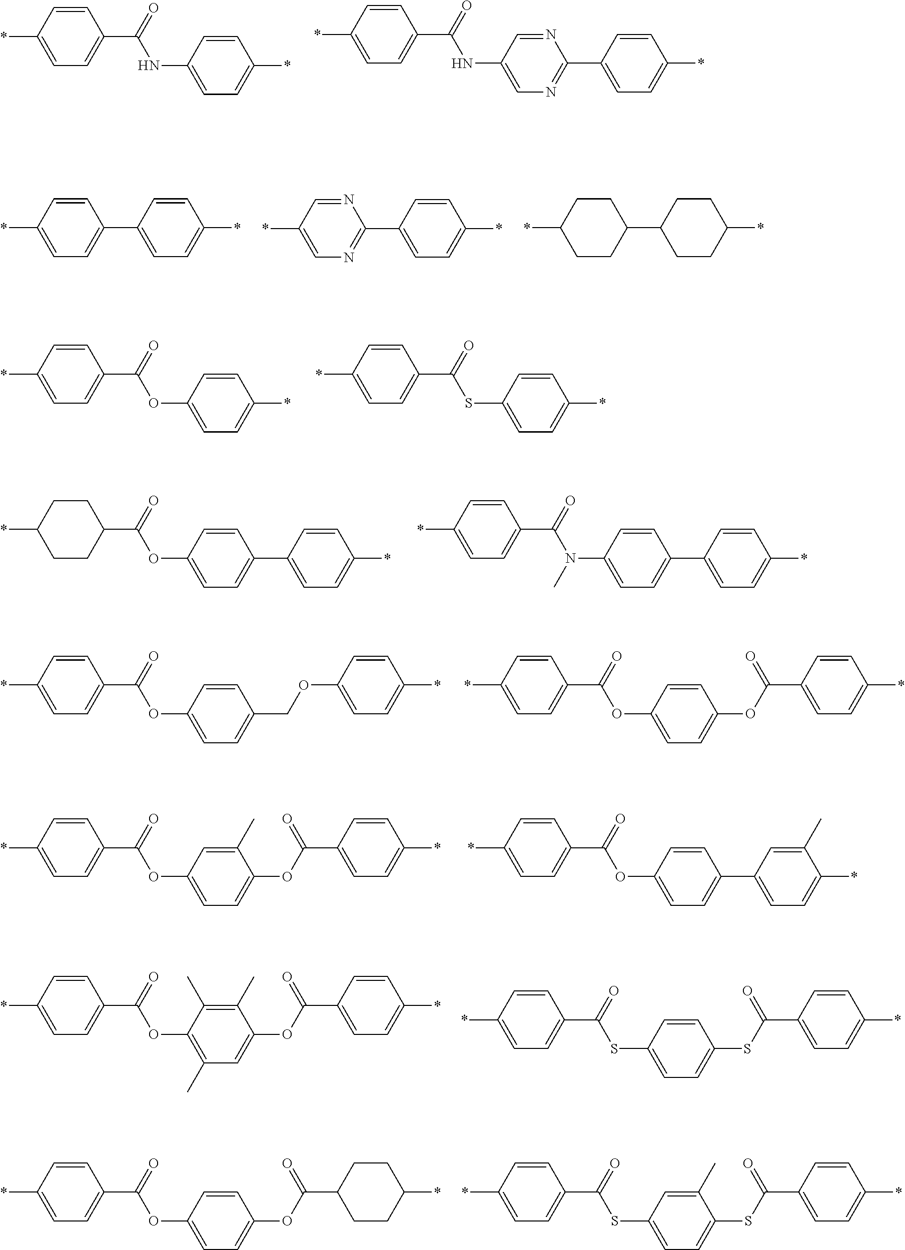

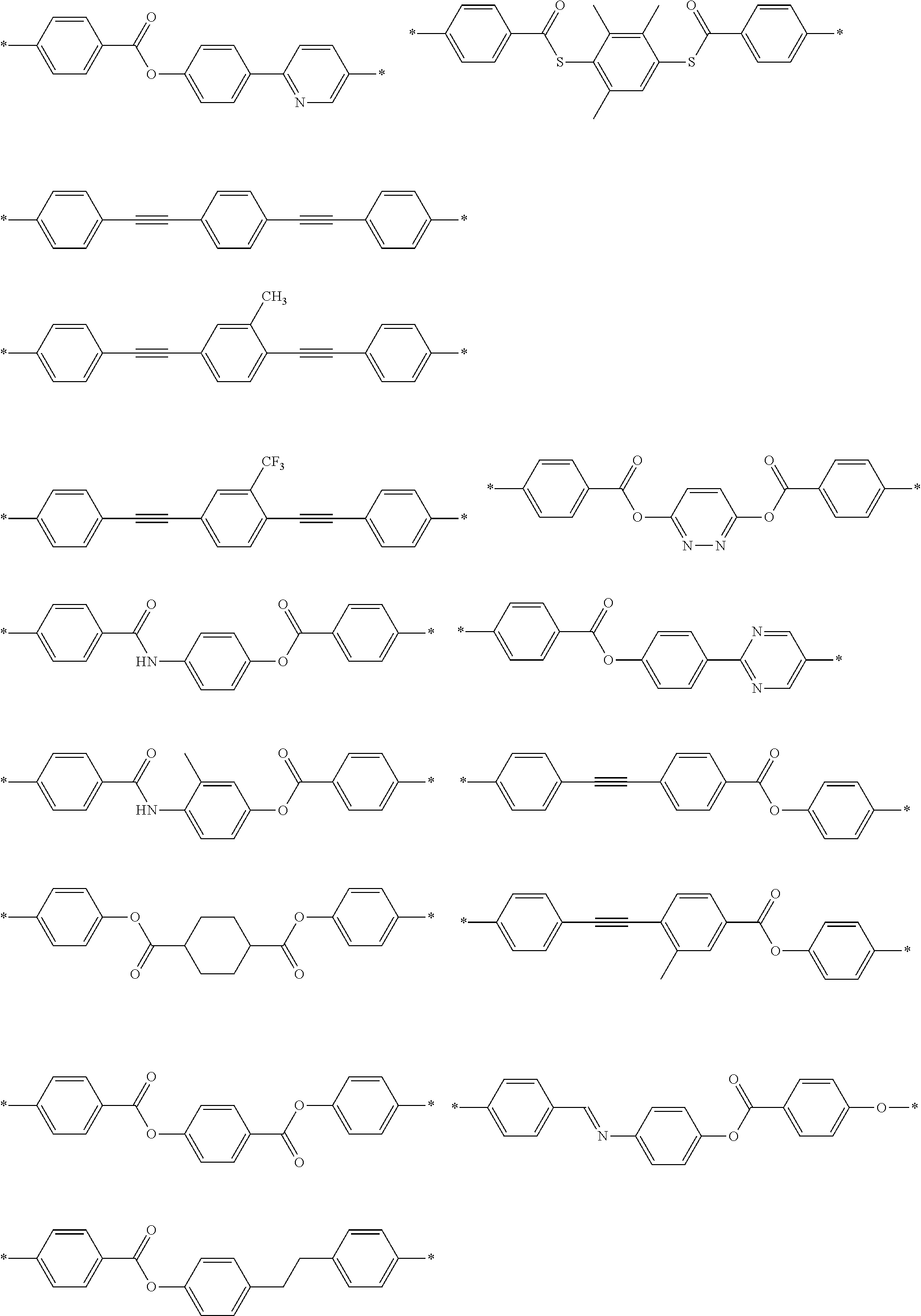

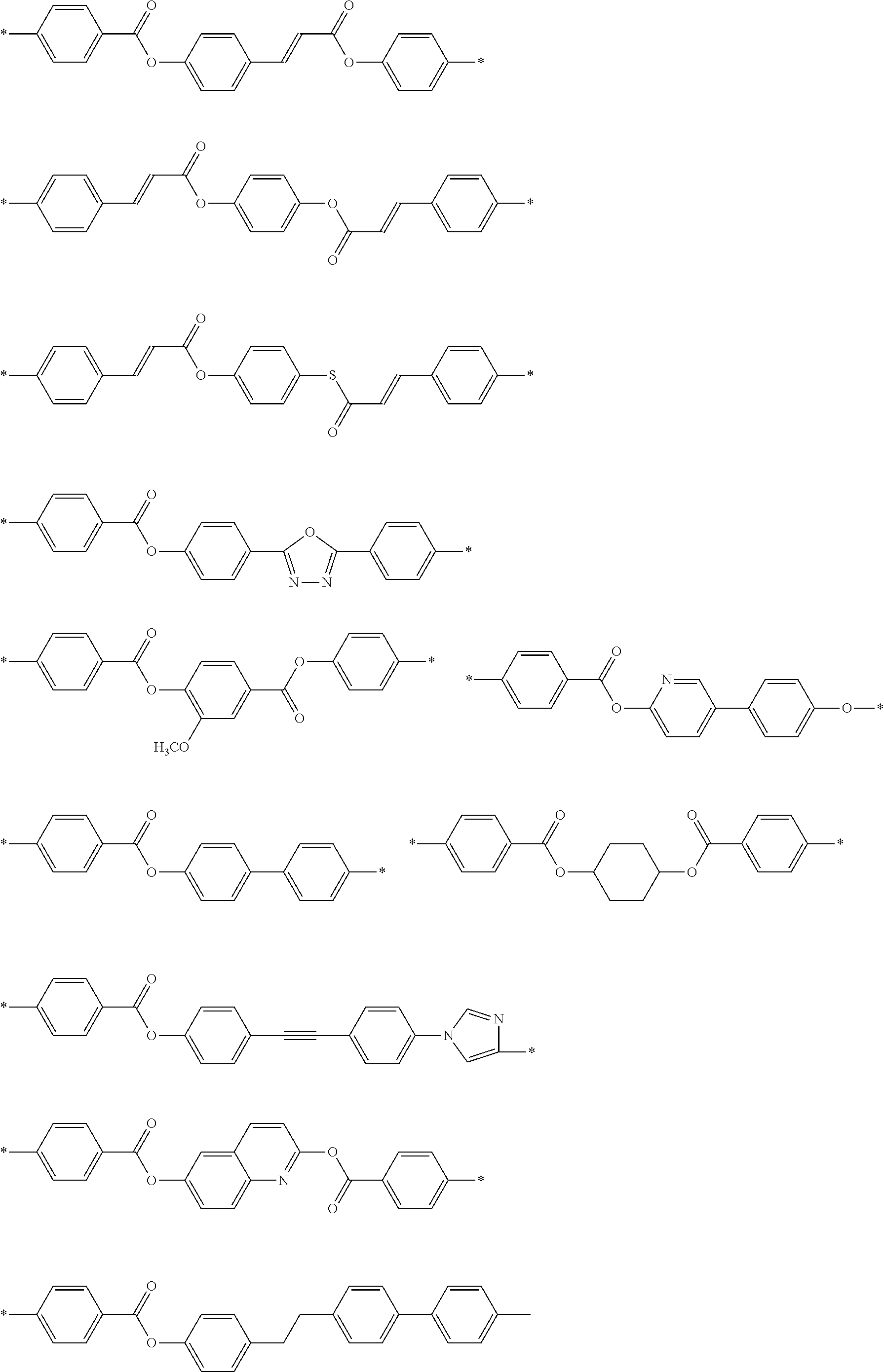

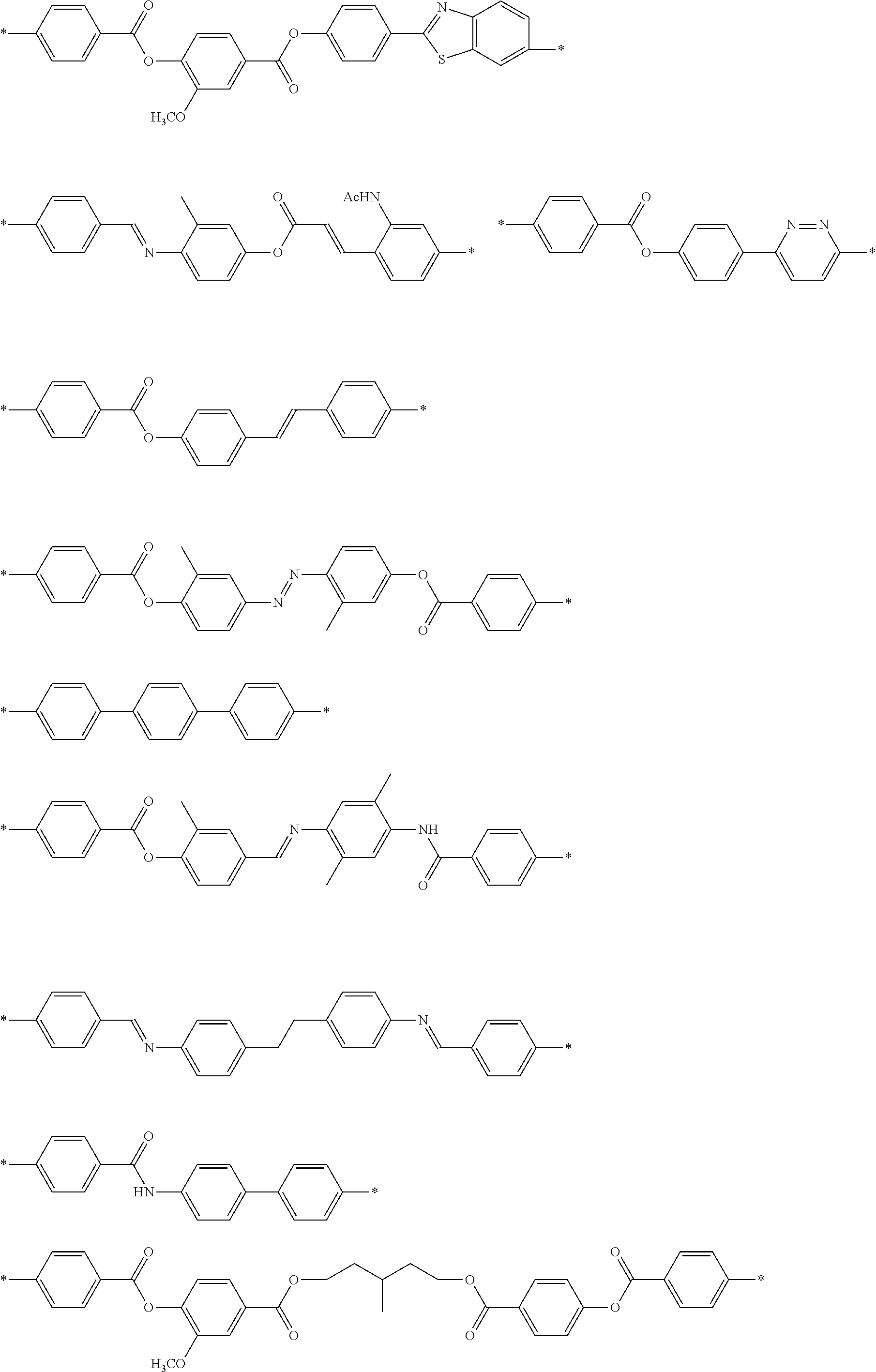

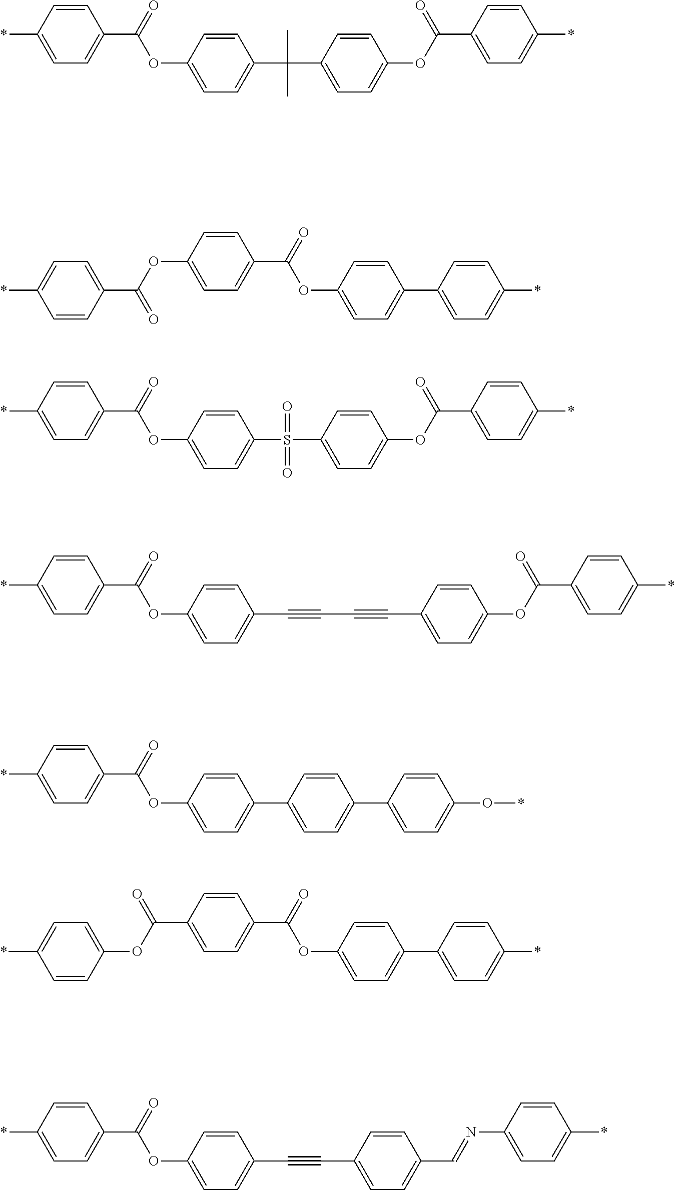

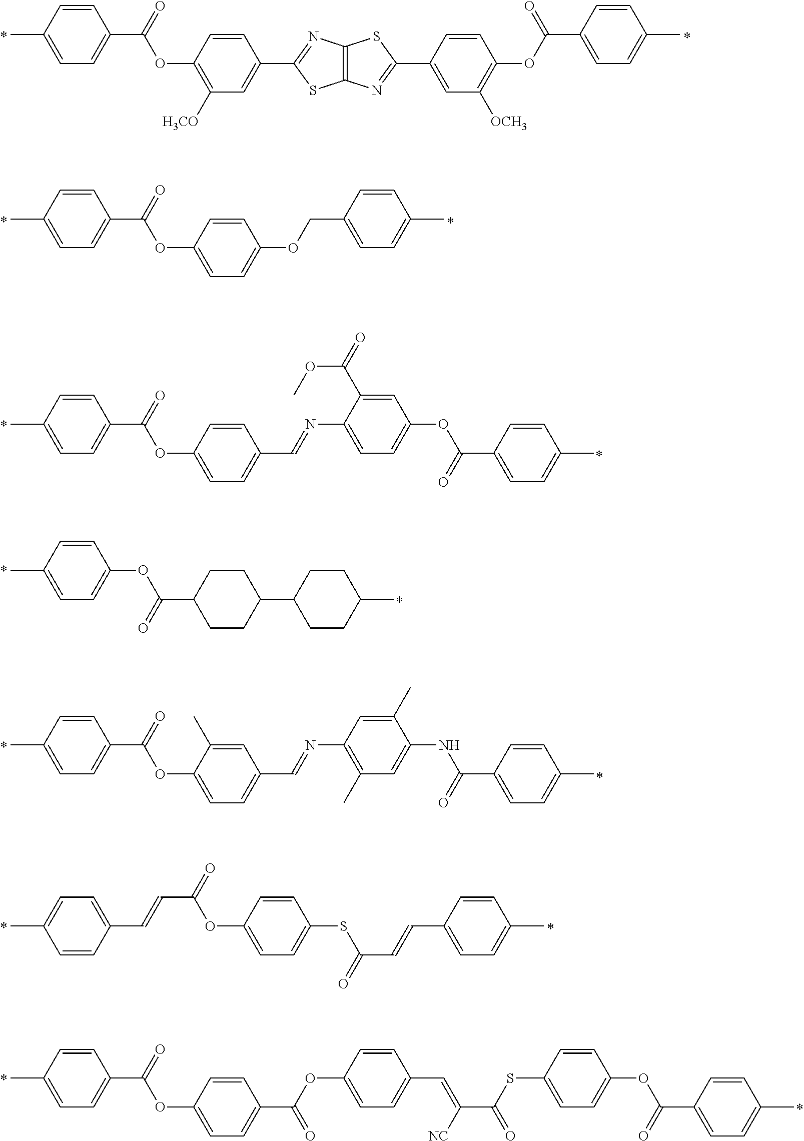

In Formula (M), examples of the terminal group represented by Ti include a hydrogen atom, a halogen atom, a cyano group, a nitro group, a hydroxy group, an alkyl group having 1 to 10 carbon atoms, an alkoxy group having 1 to 10 carbon atoms, an alkylthio group having 1 to 10 carbon atoms, an alkoxycarbonyloxy group having 1 to 10 carbon atoms, an alkoxycarbonyl group having 1 to 10 carbon atoms (ROC(O)—; R represents an alkyl group), an acyloxy group having 1 to 10 carbon atoms, an acylamino group having 1 to 10 carbon atoms, an alkoxycarbonylamino group having 1 to 10 carbon atoms, a sulfonylamino group having 1 to 10 carbon atoms, a sulfamoyl group having 1 to 10 carbon atoms, a carbamoyl group having 1 to 10 carbon atoms, a sulfinyl group having 1 to 10 carbon atoms, a ureido group having 1 to 10 carbon atoms, a (meth)acryloyloxy group-containing group, and a boronic acid group (—B(OR)₂) [R represents a hydrogen atom or an alkyl group, and two R's may be linked to each other]. Examples of the (meth)acryloyloxy group-containing group include a group represented by -L-A (L represents a single bond or a linking group, specific examples of the linking group are the same as those for Li and SP described above, and A represents a (meth)acryloyloxy group).

From the viewpoint of improving the alignment degree of the optically anisotropic layer and further suppressing the cohesive failure, T1 is preferably an alkoxy group having 1 to 10 carbon atoms or a boronic acid group, and more preferably a boronic acid group. These terminal groups may be further substituted with the groups or polymerizable groups described in JP2010-244038A.

Specific examples of the repeating unit M include repeating units represented by the following structural formulae.

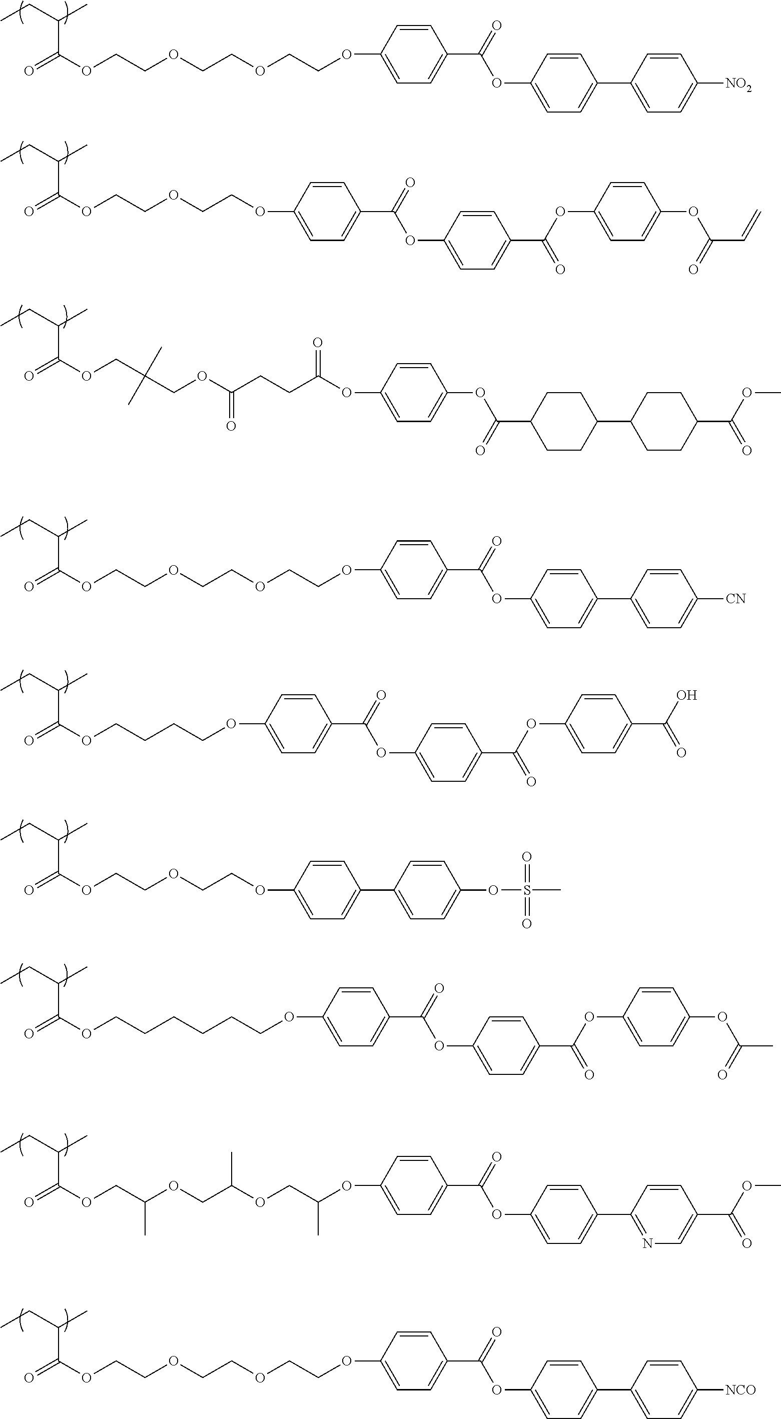

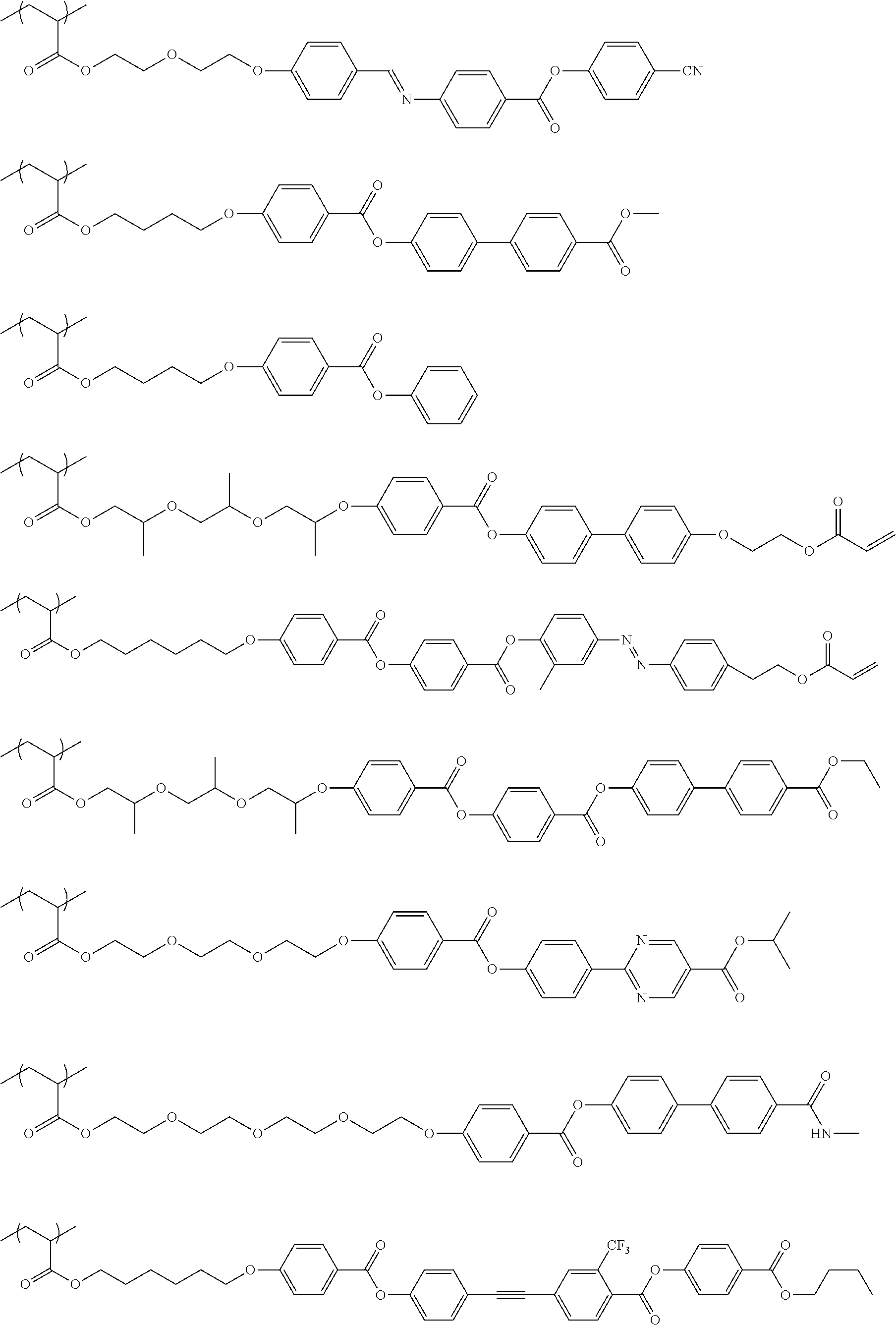

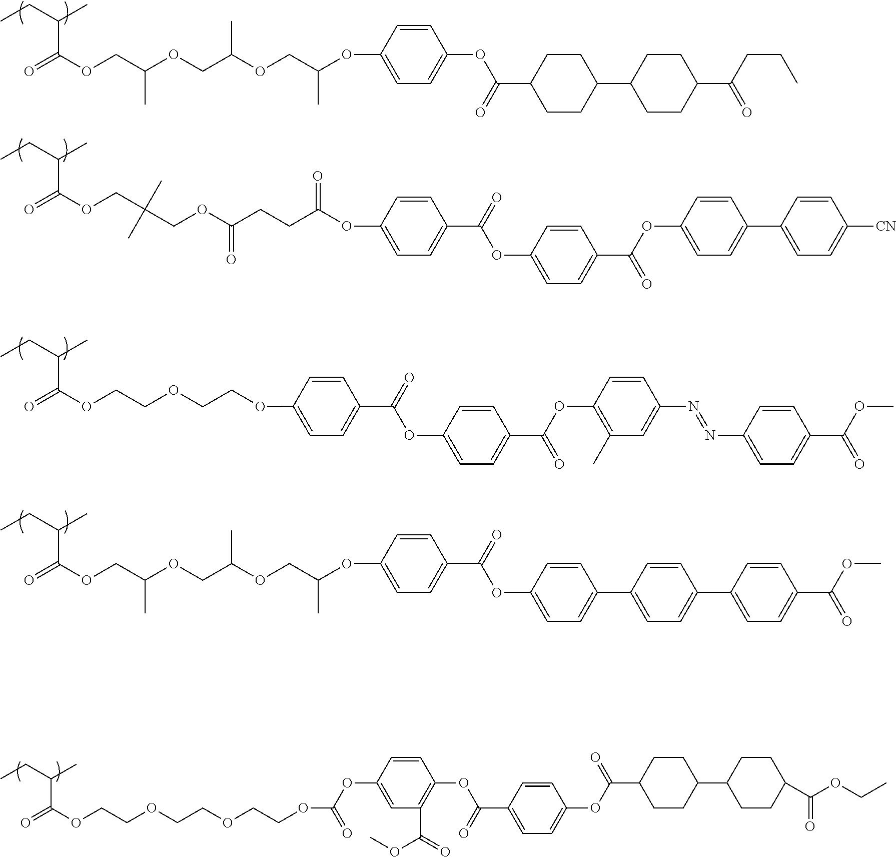

In the present invention, from the viewpoint of further suppressing the cohesive failure, it is preferable that the above-described repeating unit M further includes the boronic acid group in addition to the mesogen group, and it is more preferable that T1 in Formula (M) is the boronic acid group. Suitable specific examples thereof include repeating units represented by the following formulae.

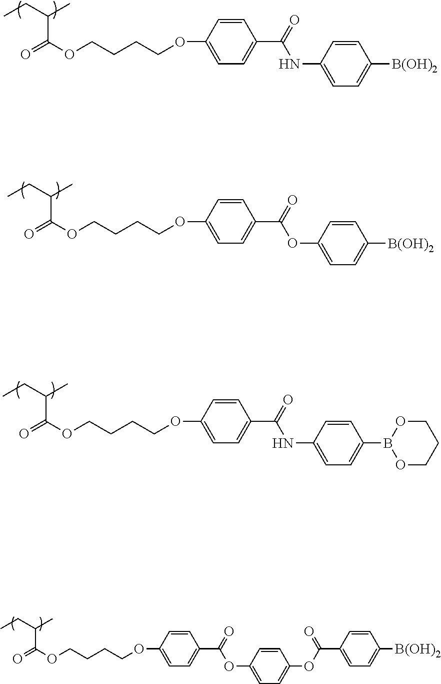

In addition, in the present invention, from the viewpoint of further suppressing the cohesive failure, in a case where a value of the content (unit: mol %) of the above-described repeating unit M is denoted by m and a value of the content (unit: mol %) of the repeating unit K is denoted by k, it is preferable that the following expressions (1) and (2) are satisfied.

$$m / k \leq 1 \qquad ( 1 )$$

$$m \leq 50 \qquad ( 2 )$$

### (Repeating Unit X)

The content of the repeating unit X in the specific surfactant, in which the difference in I/O value with the reverse dispersion liquid crystal compound is 0.9 or more, is 8 mol % or less.

Here, as described above, in a case where the above-described liquid crystal composition contains two or more kinds of the above-described surfactants (that is, surfactants having the repeating unit H), the requirement regarding the content of the repeating unit X (8 mol % or less) is a requirement which is satisfied independently by all kinds of the surfactants.

Therefore, for example, in the liquid crystal composition disclosed in paragraph [0145] of JP2021-193825A, which contains two leveling agents (surfactants), in a case of containing a surfactant having a structure also described below [weight-average molecular weight: 15,000; a numerical value in the following formula indicates a content (% by mass) of each repeating unit with respect to all repeating units], the content of the repeating unit X, in which the difference in I/O value with the liquid crystal compound is 0.9 or more, is 63 mol % (that is, more than 8 mol %), and thus JP2021-193825A is a comparative example as in Comparative Example 1 of the present specification.

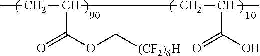

In the present invention, from the viewpoint of further suppressing the occurrence of precipitates, it is preferable that the above-described repeating unit X includes a carboxy group, and it is more preferable that the above-described repeating unit X is a repeating unit represented by Formula (X-1) or (X-2).

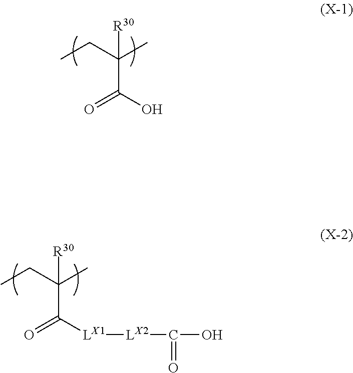

In Formulae (X-1) and (X-2), R³⁰ represents a hydrogen atom or an alkyl group having 1 to 20 carbon atoms; and among these, a hydrogen atom or an alkyl group having 1 to 10 carbon atoms is preferable, a hydrogen atom or an alkyl group having 1 to 4 carbon atoms is more preferable, and a hydrogen atom or a methyl group is still more preferable.

Specific examples of a monomer forming the above-described repeating unit represented by Formula (X-1) include acrylic acid and methacrylic acid.

R³⁰ in Formula (X-2) is the same as that described in Formula (X-1) above.

In Formula (X-2), L^{X1} represents a single bond, —O—, or —NR^{X}—. Here, R^{X} represents a hydrogen atom or a substituent. Regarding —NR^{X}— in L^{X1}, the substituent in R^{X} is preferably an alkyl group, more preferably a linear alkyl group having 1 to 4 carbon atoms, and still more preferably a methyl group or an ethyl group. As L^{X1}, —O— or NH— is preferable, and —O— is more preferable.

In Formula (X-2), Lx² represents a divalent aliphatic hydrocarbon group having 1 to 20 carbon atoms. Examples of the divalent aliphatic hydrocarbon group having 1 to 20 carbon atoms include a linear or branched alkylene group having 1 to 20 carbon atoms, a linear or branched alkenylene group having 1 to 20 carbon atoms, and a linear or branched alkynylene group having 1 to 20 carbon atoms; and among these, a linear or branched alkylene group having 1 to 20 carbon atoms is preferable, an alkylene group having 1 to 12 carbon atoms is more preferable, and an alkylene group having 2 to 8 carbon atoms is still more preferable.

In addition, in the present invention, from the viewpoint of further suppressing the occurrence of precipitates, the above-described content of the repeating unit X is preferably 5 mol % or less, and more preferably 0 to 3 mol %.

Here, as described above, in a case where the above-described liquid crystal composition contains two or more kinds of the surfactants, the requirement regarding the content of the repeating unit X (5 mol % or less) is a requirement which is satisfied independently by all kinds of the surfactants.

Furthermore, in the present invention, from the viewpoint of improving unevenness other than the precipitates (that is, streaky unevenness), a content of the specific surfactant is preferably 0.05% by mass or more, more preferably 0.05% to 0.80% by mass, and still more preferably 0.05% to 0.50% by mass with respect to the total mass of solid contents of the liquid crystal composition.

### <Alignment Auxiliary Agent>

From the viewpoint of improving the aligning properties of the optically anisotropic layer (liquid crystal cured layer), the liquid crystal composition preferably contains a compound including a mesogen group having the same structure as the mesogen group included in the above-described repeating unit M (hereinafter, also referred to as “alignment auxiliary agent”).

As the alignment auxiliary agent, for example, a boronic acid monomer having a polymerizable group and a boronic acid group represented by Formula (B) is preferable.

Here, the polymerizable group included in the boronic acid monomer is not particularly limited; and suitable examples thereof include the polymerizable groups represented by any of Formulae (P-1) to (P-20) described above.

The number of boronic acid groups represented by Formula (B), included in the boronic acid monomer, is not particularly limited, and may be one or a plurality (two or more).

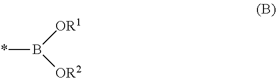

In Formula (B), * represents a bonding position.

R¹ and R² each independently represent a hydrogen atom, an aliphatic hydrocarbon group which may have a substituent, an aryl group which may have a substituent, or a heterocyclic group which may have a substituent, and R¹ and R² may be linked to each other to form a ring.

Examples of the aliphatic hydrocarbon group represented by one aspect of R¹ and R² include a linear or branched alkyl group having 1 to 20 carbon atoms, which may be substituted or unsubstituted, (for example, a methyl group, an ethyl group, an isopropyl group, and the like), a substituted or unsubstituted cyclic alkyl group having 3 to 20 carbon atoms (for example, a cyclohexyl group and the like), and an alkenyl group having 2 to 20 carbon atoms (for example, a vinyl group and the like).

Examples of the aryl group represented by one aspect of R¹ and R² include a substituted or unsubstituted phenyl group having 6 to 20 carbon atoms (for example, a phenyl group, a tolyl group, and the like), and a substituted or unsubstituted naphthyl group having 10 to 20 carbon atoms.

Examples of the heterocyclic group represented by one aspect of R¹ and R² include a substituted or unsubstituted 5-membered or 6-membered ring group including at least one heteroatom (for example, a nitrogen atom, an oxygen atom, a sulfur atom, and the like); and examples thereof include a pyridyl group, an imidazolyl group, a furyl group, a piperidyl group, and a morpholino group. R¹ and R² may be linked to each other to form a ring, and for example, isopropyl groups of R¹ and R² may be linked to each other to form a 4,4,5,5-tetramethyl-1,3,2-dioxaborolane ring.

Examples of the substituent which may be included in the aliphatic hydrocarbon group, the aryl group, and the heterocyclic group include the substituents described in the above substituent group A.

In Formula (B), as R¹ and R², a hydrogen atom, a linear or branched alkyl group having 1 to 3 carbon atoms, or an aspect in which R¹ and R² are linked to each other to form a ring is preferable, and a hydrogen atom is more preferable.

A molecular weight of the boronic acid monomer is not particularly limited, but from the viewpoint that compatibility with a polyfunctional monomer is excellent, it is preferably 120 to 1,200 and more preferably 180 to 800.

Suitable aspects of the boronic acid monomer include a boronic acid monomer represented by Formula (B-1) from the viewpoint of further suppressing the cohesive failure.

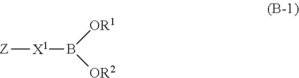

The definitions of R¹ and R² in Formula (B-1) are as described above.

Z represents a polymerizable group. The definition of the polymerizable group is as described above.

X¹ represents a single bond or a divalent linking group. Examples of the divalent linking group include —O—, —CO—, —NH—, —CO—NH—, —COO—, —O—COO—, an alkylene group, an arylene group, a heterocyclic group (heteroaryl group), and a divalent linking group selected from a combination of these groups.

Examples of the combination include an arylene group-COO-arylene group-O-alkylene group- and -arylene group-C00-alkylene group-.

Specific examples of the boronic acid monomer are described below, but the present invention is not limited thereto.

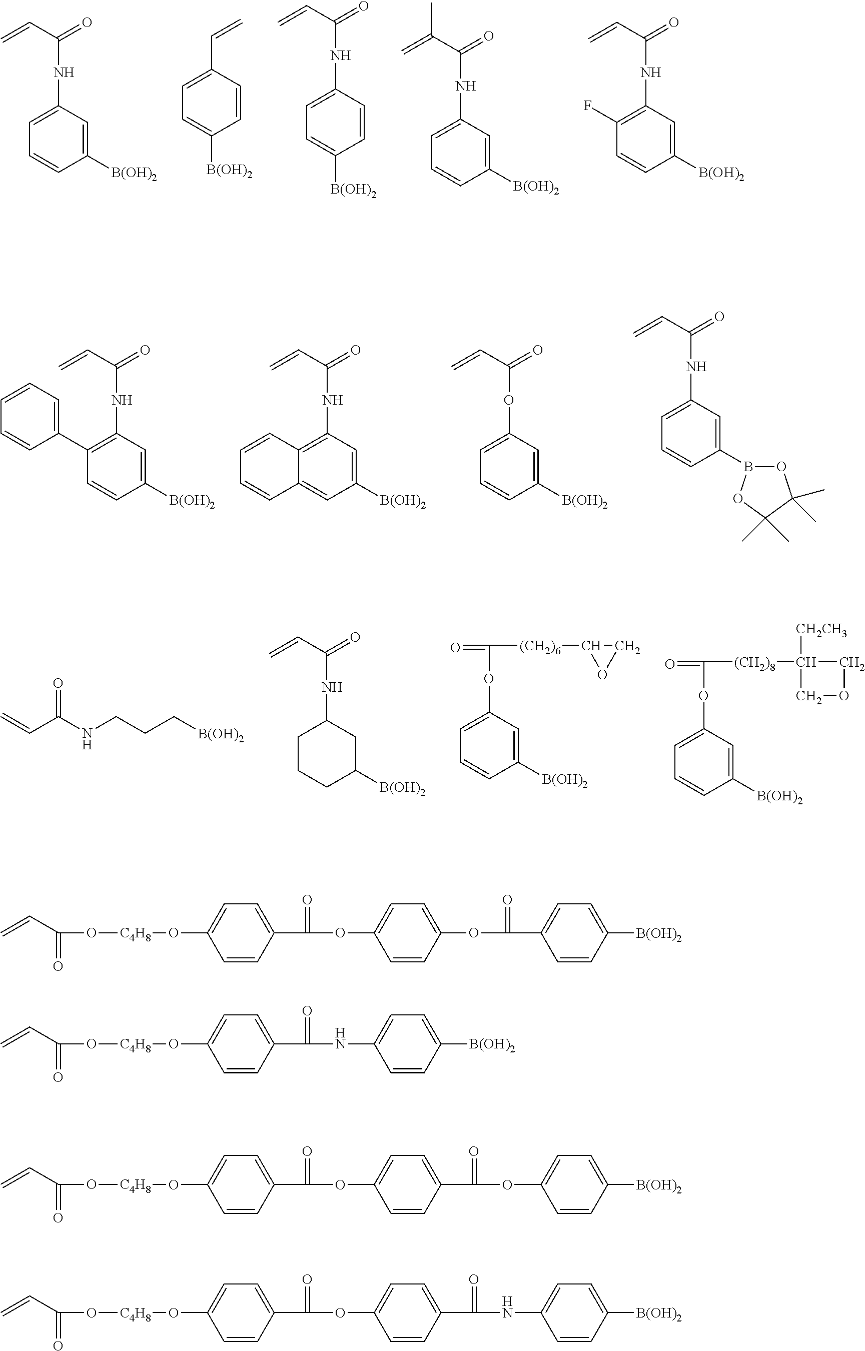

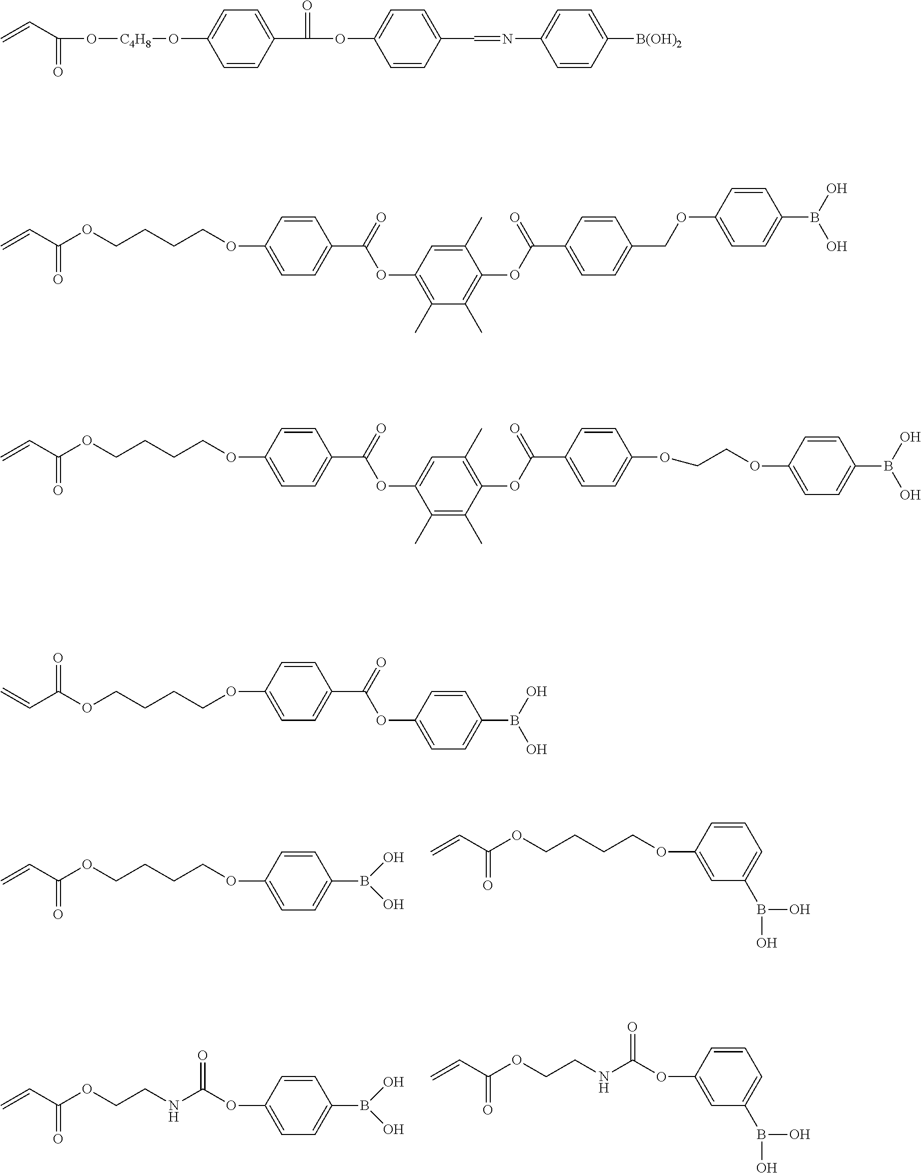

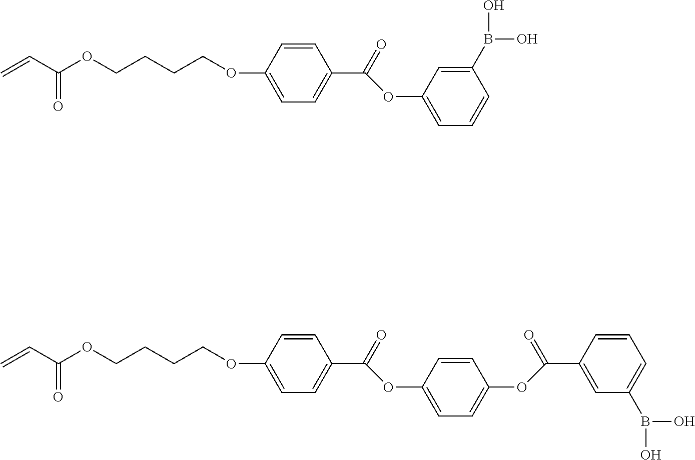 [SMILES: C=CC(=O)OCCCCOc1ccc(C(=O)Oc2cccc(B(O)O)c2)cc1 ; C=CC(=O)OCCCCOc1ccc(C(=O)Oc2ccc(OC(=O)c3cccc(B(O)O)c3)cc2)cc1]

In a case where the liquid crystal composition contains the alignment auxiliary agent, a content of the alignment auxiliary agent is preferably 0.500 by mass or more, and more preferably 1% o to 10o by mass with respect to the total mass of solid contents of the liquid crystal composition.

### <Solvent>

The liquid crystal composition preferably contains a solvent.

Examples of the solvent include ketones (for example, acetone, 2-butanone, methyl ethyl ketone, methyl isobutyl ketone, cyclohexanone, cyclopentanone, and the like), ethers (for example, dioxane, tetrahydrofuran, and the like), aliphatic hydrocarbons (for example, hexane and the like), alicyclic hydrocarbons (for example, cyclohexane and the like), aromatic hydrocarbons (for example, toluene, xylene, trimethylbenzene, and the like), halogenated hydrocarbons (for example, dichloromethane, dichloroethane, dichlorobenzene, chlorotoluene, and the like), esters (for example, methyl acetate, ethyl acetate, butyl acetate, and the like), water, alcohols (for example, ethanol, isopropanol, butanol, cyclohexanol, and the like), cellosolves (for example, methyl cellosolve, ethyl cellosolve, and the like), cellosolve acetates, sulfoxides (for example, dimethyl sulfoxide and the like), and amides (for example, dimethyl formamide, dimethyl acetamide, and the like). The solvent may be used alone or in combination of two or more kinds thereof.

### <Polymerization Initiator>

The liquid crystal composition preferably contains a polymerization initiator.

The polymerization initiator is preferably a photopolymerization initiator capable of initiating a polymerization reaction by ultraviolet irradiation.

Examples of the photopolymerization initiator include α-carbonyl compounds (described in U.S. Pat. Nos. 2,367,661A and 2,367,670A), acyloin ethers (described in U.S. Pat. No. 2,448,828A), α-hydrocarbon-substituted aromatic acyloin compounds (described in U.S. Pat. No. 2,722,512A), polynuclear quinone compounds (described in U.S. Pat. Nos. 3,046,127A and 2,951,758A), combinations of triarylimidazole dimer and p-aminophenyl ketone (described in U.S. Pat. No. 3,549,367A), acridine and phenazine compounds (described in JP1985-105667A (JP-S60-105667A) and U.S. Pat. No. 4,239,850A), oxadiazole compounds (described in U.S. Pat. No. 4,212,970A), and acyl phosphine oxide compounds (described in JP1988-40799B (JP-S63-40799B), JP1993-29234B (JP-H05-29234B), JP1998-95788A (JP-H10-95788A), and JP1998-29997A (JP-H10-29997A)).

As the polymerization initiator, an oxime-type polymerization initiator is also preferable. Specific examples thereof include initiators described in paragraphs [0049] to [0052] of WO2017/170443A.

### <Other Components>

The liquid crystal composition may contain a component other than the above-described components. Examples of other components include a liquid crystal compound other than the above-described reverse dispersion liquid crystal compound (for example, a liquid crystal compound having forward wavelength dispersion), a tilt angle controller, a plasticizer, and a crosslinking agent.

### <Method of Forming Optically Anisotropic Layer (Liquid Crystal Cured Layer)>

The optically anisotropic layer of the optical film according to the embodiment of the present invention is a liquid crystal cured layer formed by immobilizing the reverse dispersion liquid crystal compound in a vertically aligned state using the above-described liquid crystal composition.

Examples of a method of forming the optically anisotropic layer include a method of vertically aligning the reverse dispersion liquid crystal compound using the above-described liquid crystal composition, and then immobilizing the reverse dispersion liquid crystal compound by polymerization.

Here, conditions for setting the desired vertical alignment state are not particularly limited; but it is preferable to perform a heat treatment, and it is more preferable to perform a cooling treatment after the heat treatment. From the viewpoint of manufacturing suitability, a heating temperature in the heat treatment is preferably 10° C. to 250° C., more preferably 50° C. to 200° C., and still more preferably 70° C. to 150° C. In addition, a heating time in the heat treatment is preferably 1 to 300 seconds and more preferably 1 to 60 seconds. In addition, a temperature in the cooling treatment after the heat treatment is not particularly limited as long as it is lower than the heating temperature in the heat treatment, but is preferably room temperature (23° C.) to 80° C.

In addition, conditions for the above-described polymerization are not particularly limited, but ultraviolet rays are preferably used in the polymerization by light irradiation. An irradiation amount is preferably 10 mJ/cm² to 50 J/cm², more preferably 20 mJ/cm² to 5 J/cm², still more preferably 30 mJ/cm² to 3 J/cm², and particularly preferably 50 to 1,000 mJ/cm². In order to promote the polymerization reaction, the treatment may be performed under heating conditions.

The optically anisotropic layer of the optical film according to the embodiment of the present invention is preferably a positive C-plate.

Here, the positive C-plate is defined as follows.

That is, the positive C-plate satisfies a relationship of an expression (C1) in a case where a refractive index in the slow axis direction in a film plane (in a direction such that the in-plane refractive index is maximum) is defined as nx, a refractive index in the in-plane direction orthogonal to the in-plane slow axis is defined as ny, and a thickness-direction refractive index is defined as nz. In the positive C-plate, Rth exhibits a negative value.

$$nz > nx \approx ny \qquad Expression ( C1 )$$

The symbol “≈” encompasses not only a case where both sides are completely the same as each other but also a case where the both sides are substantially the same as each other. As the expression “substantially the same”, for example, “nx≈ny” includes a case where (nx−ny)×d (here, d is a thickness of the film) is 0 to 10 nm, preferably 0 to 5 nm.

A thickness of the optically anisotropic layer of the optical film according to the embodiment of the present invention is not particularly limited, but is preferably 0.1 to 10 μm and more preferably 0.5 to 5 μm.

### [Substrate]

The optical film according to the embodiment of the present invention may include a substrate for supporting the optically anisotropic layer.

Such a substrate is preferably transparent. The term “transparent” in the present invention indicates that the transmittance of visible light is 60% or more, preferably 80% or more and more preferably 90% or more.

In the present invention, from the viewpoint of improving display performance in a case of being used in an image display device (particularly, in a liquid crystal display device), the substrate is preferably a positive A-plate.

Here, in the present specification, the positive A-plate is defined as follows.

That is, the positive A-plate satisfies a relationship of an expression (A1) in a case where a refractive index in the slow axis direction in a film plane (in a direction such that the in-plane refractive index is maximum) is defined as nx, a refractive index in the in-plane direction orthogonal to the in-plane slow axis is defined as ny, and a thickness-direction refractive index is defined as nz. In the positive A-plate, Rth indicates a positive value.

$$nx > ny \approx nz \qquad Expression ( A1 )$$

The symbol “≈” encompasses not only a case where both sides are completely the same as each other but also a case where the both sides are substantially the same as each other. As the expression “substantially the same”, for example, “ny≈nz” includes a case where (ny−nz)×d (here, d is a thickness of the film) is −10 to 10 nm, preferably −5 to 5 nm.

In addition, in the present invention, it is preferable that the above-described substrate is another liquid crystal cured layer different from the above-described optically anisotropic layer (liquid crystal cured layer).

Examples of the other liquid crystal cured layer include a liquid crystal cured layer formed by fixing an alignment state (particularly, a horizontal alignment state) of a liquid crystal compound contained in a liquid crystal composition which does not contain the above-described reverse dispersion liquid crystal compound and/or the specific surfactant; and a liquid crystal cured layer formed by, using a liquid crystal composition containing the above-described reverse dispersion liquid crystal compound and the specific surfactant, immobilizing the reverse dispersion liquid crystal compound in a horizontally aligned state.

Here, regarding the horizontal alignment, the horizontal alignment in a case where the liquid crystal compound is a rod-like liquid crystal compound is also referred to as a homogeneous alignment, and means an alignment in which an angle between a surface (main surface) of the liquid crystal cured layer and a director of the rod-like liquid crystal compound is within a range of 0° to 20°. An alignment in which the above-described angle is within a range of 0° to 10° is preferable, and an alignment in which the above-described angle is within a range of 0° to 5° is more preferable.

In addition, the horizontal alignment in a case where the liquid crystal compound is a disk-like liquid crystal compound means an alignment in which an angle between a surface (main surface) of the liquid crystal cured layer and a disc plane of the disk-like liquid crystal compound is within a range of 0° to 20°. An alignment in which the above-described angle is within a range of 0° to 10° is preferable, and an alignment in which the above-described angle is within a range of 0° to 5° is more preferable.

Furthermore, in the present invention, a polymer film described in a support, which will be described later, may be used as the above-described substrate.

### [Support]

In a case where the optical film according to the embodiment of the present invention includes the above-described other liquid crystal cured layer as the above-described substrate, the optical film may include a support for supporting the other liquid crystal cured layer.

Such a support is preferably transparent. The term “transparent” in the present invention indicates that the transmittance of visible light is 60% or more, preferably 80% or more and more preferably 90% or more.

Examples of the above-described support include a glass substrate and a polymer film. Examples of a material of the polymer film include cellulose-based polymers; acrylic polymers having an acrylic acid ester polymer such as polymethyl methacrylate and a lactone ring-containing polymer; thermoplastic norbornene-based polymers; polycarbonate-based polymers; polyester-based polymers such as polyethylene terephthalate and polyethylene naphthalate; styrene-based polymers such as polystyrene and an acrylonitrile-styrene copolymer (AS resin); polyolefin-based polymers such as polyethylene, polypropylene, and an ethylene-propylene copolymer; vinyl chloride-based polymers; amide-based polymers such as nylon and aromatic polyamide; imide-based polymers; sulfone-based polymers; polyether sulfone-based polymers; polyether ether ketone-based polymers; polyphenylene sulfide-based polymers; vinylidene chloride-based polymers; vinyl alcohol-based polymers; vinyl butyral-based polymers; arylate-based polymers; polyoxymethylene-based polymers; epoxy-based polymers; and polymers obtained by mixing these polymers.

A thickness of the above-described support is not particularly limited, but is preferably 1 to 200 m and more preferably 2 to 100 m.

### [Alignment Film]

The optically anisotropic layer (liquid crystal cured layer) of the optical film according to the embodiment of the present invention and any other liquid crystal cured layer may be formed on a surface of an alignment film (particularly, a photo-alignment film described later).

The alignment film may be any film as long as it has a function of aligning the liquid crystal compound contained in the composition.

The alignment film generally contains a polymer as a main component. A polymer material for the alignment film is described in many documents, and many commercially available products can be used.

As the polymer material for the alignment film, a polyvinyl alcohol, a polyimide, or a derivative thereof is preferable, and a modified or unmodified polyvinyl alcohol is more preferable.

Examples of the alignment film which may be included in the optical film include alignment films described in Line 24 on Page 43 to Line 8 on Page 49 of WO01/88574A; alignment films consisting of modified polyvinyl alcohols described in paragraphs [0071] to [0095] of JP3907735B; and liquid crystal alignment films formed using a liquid crystal aligning agent described in JP2012-155308A.

Since an object does not come into contact with a surface of the alignment film in the formation of the alignment film and the deterioration of a surface condition can be prevented, it is preferable to use a photo-alignment film as the alignment film.

The photo-alignment film is not particularly limited; but an alignment film formed by a polymer material such as a polyamide compound and a polyimide compound described in paragraphs [0024] to [0043] of WO2005/096041A, a liquid crystal alignment film formed by a liquid crystal aligning agent having a photo-aligned group described in JP2012-155308A, trade name LPP-JP265CP manufactured by Rolic Technologies Ltd., or the like can be used.

A thickness of the above-described alignment film is not particularly limited, but is preferably 0.01 to 10 μm, more preferably 0.01 to 1 μm, and still more preferably 0.01 to 0.5 μm.

### [Polarizing Plate]

The polarizing plate according to the embodiment of the present invention is a polarizing plate including the above-described optical film according to the embodiment of the present invention, and a polarizer.

### [Polarizer]

The polarizer included in the polarizing plate according to the embodiment of the present invention is not particularly limited as long as the polarizer is a member having a function of converting light into specific linearly polarized light, and a known absorptive type polarizer and reflective type polarizer in the related art can be used.

An iodine-based polarizer, a dye-based polarizer using a dichroic dye, a polyene-based polarizer, or the like is used as the absorptive type polarizer. The iodine-based polarizer and the dye-based polarizer include a coating type polarizer and a stretching type polarizer, and any one of these polarizers can be applied. However, a polarizer which is produced by allowing polyvinyl alcohol to adsorb iodine or a dichroic dye and performing stretching is preferable.

In addition, examples of a method of obtaining a polarizer by performing stretching and dyeing in a state of a laminated film in which a polyvinyl alcohol layer is formed on a substrate include methods disclosed in JP5048120B, JP5143918B, JP4691205B, JP4751481B, and JP4751486B, and known technologies related to these polarizers can be preferably used.

A polarizer in which thin films having different birefringence are laminated, a wire grid type polarizer, a polarizer in which a cholesteric liquid crystal having a selective reflection range and a ¼ wavelength plate are combined, or the like is used as the reflective type polarizer.

Among these, from the viewpoint of more excellent adhesiveness, a polarizer containing a polyvinyl alcohol-based resin (polymer including —CH₂—CHOH— as a repeating unit; in particular, at least one selected from the group consisting of polyvinyl alcohol and an ethylene-vinyl alcohol copolymer) is preferable.

In the present invention, a thickness of the polarizer is not particularly limited, but is preferably 5 to 40 m, more preferably 5 to 30 m, and still more preferably 5 to 20 m. With the above-described thickness, it is possible to reduce the thickness of a display device.

### [Image Display Device]

The image display device according to the embodiment of the present invention is an image display device including the optical film according to the embodiment of the present invention or the polarizing plate according to the embodiment of the present invention (hereinafter, collectively referred to as “optical film or the like according to the embodiment of the present invention”).

A display element used in the image display device is not particularly limited, and examples thereof include a liquid crystal cell, an organic EL display panel, and a plasma display panel. Among these, a liquid crystal cell or an organic EL display panel is preferable, and a liquid crystal cell is more preferable.

That is, as the image display device, a liquid crystal display device using a liquid crystal cell as the display element or an organic EL display device using an organic EL display panel as the display element is preferable, and the liquid crystal display device is more preferable.

### [Liquid Crystal Display Device]

A liquid crystal display device as an example of the image display device is a liquid crystal display device including the optical film or the like according to the embodiment of the present invention and a liquid crystal cell.

Among polarizing plates provided on both sides of the liquid crystal cell, it is preferable that the optical film or the like according to the embodiment of the present invention is used as a polarizing plate on the front side, and it is more preferable that the optical film or the like according to the embodiment of the present invention is used as polarizing plates on the front and rear sides.

Hereinafter, the liquid crystal cell constituting the liquid crystal display device will be described in detail.

### <Liquid Crystal Cell>

It is preferable that the liquid crystal cell used in the liquid crystal display device is in a vertical alignment (VA) mode, an optically compensated bend (OCB) mode, an in-plane-switching (IPS) mode, a fringe-field-switching (FFS) mode, or a twisted nematic (TN) mode, but is not limited thereto.

In the liquid crystal cell in a TN mode, rod-like liquid crystal molecules are substantially horizontally aligned at the time of no voltage application and further twisted and aligned at 600 to 120°. The liquid crystal cell in a TN mode is most frequently used as a color TFT liquid crystal display device and is described in a plurality of documents.

In the liquid crystal cell in a VA mode, rod-like liquid crystal molecules are substantially vertically aligned at the time of no voltage application. The concept of the liquid crystal cell in a VA mode includes (1) a liquid crystal cell in a VA mode in a narrow sense where rod-like liquid crystal molecules are aligned substantially vertically at the time of no voltage application and substantially horizontally at the time of voltage application (described in JP1990-176625A (JP-H2-176625A)), (2) a liquid crystal cell (in an MVA mode) (SID97, described in Digest of tech. Papers (proceedings) 28 (1997) 845) in which the VA mode is formed to have multi-domain in order to widen the viewing angle, (3) a liquid crystal cell in a mode (n-ASM mode) in which rod-like liquid crystal molecules are substantially vertically aligned at the time of no voltage application and twistedly multi-domain aligned at the time of voltage application (described in proceedings of Japanese Liquid Crystal Conference, pp. 58 to 59 (1998)), and (4) a liquid crystal cell in a SURVIVAL mode (presented at LCD International 98). In addition, the liquid crystal cell in the VA mode may be any of a patterned vertical alignment (PVA) type, an optical alignment type, or a polymer-sustained alignment (PSA) type. The details of these modes are described in JP2006-215326A and JP2008-538819A.

In an IPS mode liquid crystal cell, rod-like liquid crystal molecules are substantially aligned parallel to a substrate and application of an electric field parallel to a surface of the substrate causes the liquid crystal molecules to respond planarly. In the IPS mode, black display is carried out in a state where no electric field is applied, and absorption axes of a pair of upper and lower polarizing plates are orthogonal to each other. A method of reducing light leakage during black display in an oblique direction and improve the viewing angle using an optical compensation sheet is disclosed in JP1998-54982A (JP-H10-54982A), JP1999-202323A (JP-H11-202323A), JP1997-292522A (JP-H9-292522A), JP1999-133408A (JP-H11-133408A), JP1999-305217A (JP-H11-305217A), JP1998-307291A (JP-H10-307291A), and the like.

### [Organic EL Display Device]

Examples of an organic EL display device as an example of the image display device include an aspect in which the polarizing plate according to the embodiment of the present invention (a polarizing plate in which the polarizer is disposed on a viewing side) and an organic EL display panel are provided in this order from a viewing side.

In addition, the organic EL display panel is a display panel formed of an organic EL element obtained by sandwiching an organic light emitting layer (organic electroluminescence layer) between electrodes (between a cathode and an anode). The configuration of the organic EL display panel is not particularly limited, and a known configuration is employed.

### EXAMPLES

Hereinafter, the present invention will be described in more detail with reference to Examples. The materials, amounts used, proportions, treatment contents, treatment procedures, and the like shown in the following examples can be modified as appropriate in the range of not departing from the spirit of the present invention. Therefore, the scope of the present invention should not be construed as being limited to Examples.

### Example 1

### [Production of Cellulose Acylate Film 1 (Support)]

### <Preparation of Core Layer Cellulose Acylate Dope 1>

The following composition was put into a mixing tank and stirred to dissolve the respective components, thereby preparing a core layer cellulose acylate dope 1.

Core layer cellulose acylate dope 1

| | | |
|---|---|---|
| Cellulose acetate having acetyl | 100 | parts by mass |
| substitution degree of 2.88 | | |
| Polyester shown below | 12 | parts by mass |
| Durability improver shown below | 4 | parts by mass |
| Methylene chloride (first solvent) | 430 | parts by mass |
| Methanol (second solvent) | 64 | parts by mass |

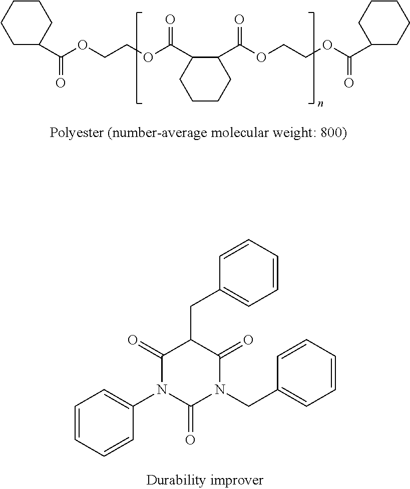

### <Preparation of Outer Layer Cellulose Acylate Dope 1>

10 parts by mass of the following matting agent dispersion liquid 1 was added to 90 parts by mass of the above-described core layer cellulose acylate dope 1, thereby preparing an outer layer cellulose acylate dope 1.

Matting agent dispersion liquid 1

| | | |
|---|---|---|
| Silica particles having an average | 2 | parts by mass |
| particle diameter of 20 nm (AEROSIL R972, | | |
| manufactured by Nippon Aerosil Co., Ltd.) | | |
| Methylene chloride (first solvent) | 76 | parts by mass |
| Methanol (second solvent) | 11 | parts by mass |
| Core layer cellulose acylate dope 1 | 1 | part by mass |

### <Production of Cellulose Acylate Film 1 (Support)>

The above-described core layer cellulose acylate dope 1 and the above-described outer layer cellulose acylate dope 1 were filtered using a filter paper with an average hole diameter of 34 m and a sintered metal filter with an average hole diameter of 10 m. Thereafter, the above-described core layer cellulose acylate dope 1 and the outer layer cellulose acylate dopes 1 on both sides thereof were cast simultaneously on a drum at 20° C. from a casting port in three layers, using a band casting machine.

Subsequently, a film was peeled off from the drum in a state in which a solvent content of the film on the drum was approximately 20% by mass. Both ends of the obtained film in a width direction were fixed with tenter clips, and the film was dried while being stretched 1.1 times in the width direction in a state in which the solvent content of the film was 3% to 15% by mass.

Thereafter, the obtained film was further dried while being transported between rolls of a heat treatment device, thereby producing a cellulose acylate film having a film thickness of 60 m. The cellulose triacetate film after drying was cooled to 30° C. or lower, both ends were cut to make a width 1,340 mm, and knurling (formation of unevenness portions) was carried out on both ends of the film to produce a cellulose acylate film 1 (support). The unevenness portions were imparted by carrying out embossing from one surface side.

### [Formation of Photo-Alignment Film 1 and Optically Anisotropic Layer 1-1 (Other Liquid Crystal Cured Layer)]

### <Preparation of Composition 1-1 for Forming Photo-Alignment Film>

8.4 parts by mass of the following copolymer C3 and 0.3 parts by mass of the following thermal acid generator D1 were added to a mixed liquid containing 80 parts by mass of butyl acetate and 20 parts by mass of methyl ethyl ketone to prepare a composition 1 for a photo-alignment film.

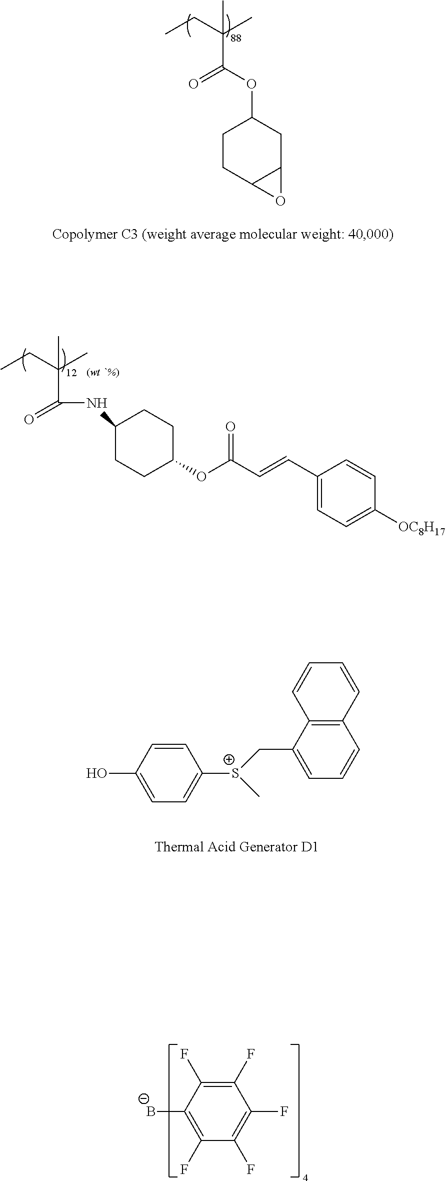

### <Preparation of Polymerizable Liquid Crystal Composition 1-1>

A polymerizable liquid crystal composition 1-1 for forming an optically anisotropic layer, having the following formulation, was prepared.

Polymerizable liquid crystal composition 1-1

| | | |
|---|---|---|
| Liquid crystal compound R1 shown below | 42.00 | parts by mass |
| Liquid crystal compound R2 shown below | 42.00 | parts by mass |
| Liquid crystal compound A1 shown below | 12.00 | parts by mass |
| Liquid crystal compound T1 shown below | 4.00 | parts by mass |
| Polymerization initiator S1 shown below | 0.50 | parts by mass |
| Surfactant P1-1 shown below | 0.20 | parts by mass |
| HISOLVE MTEM (manufactured by TOHO | 2.00 | parts by mass |
| Chemical Industry Co., Ltd.) | | |
| NK Ester A-200 (manufactured by | 1.00 | part by mass |
| Shin-Nakamura Chemical Co., Ltd.) | | |
| Methyl ethyl ketone | 424.80 | parts by mass |

A group adjacent to the acryloyloxy group of the following rod-like liquid crystal compounds R1 and R2 represents a propylene group (group in which the methyl group is substituted with an ethylene group), and the following rod-like liquid crystal compounds R1 and R2 represent a mixture of regioisomers with different positions of methyl groups.

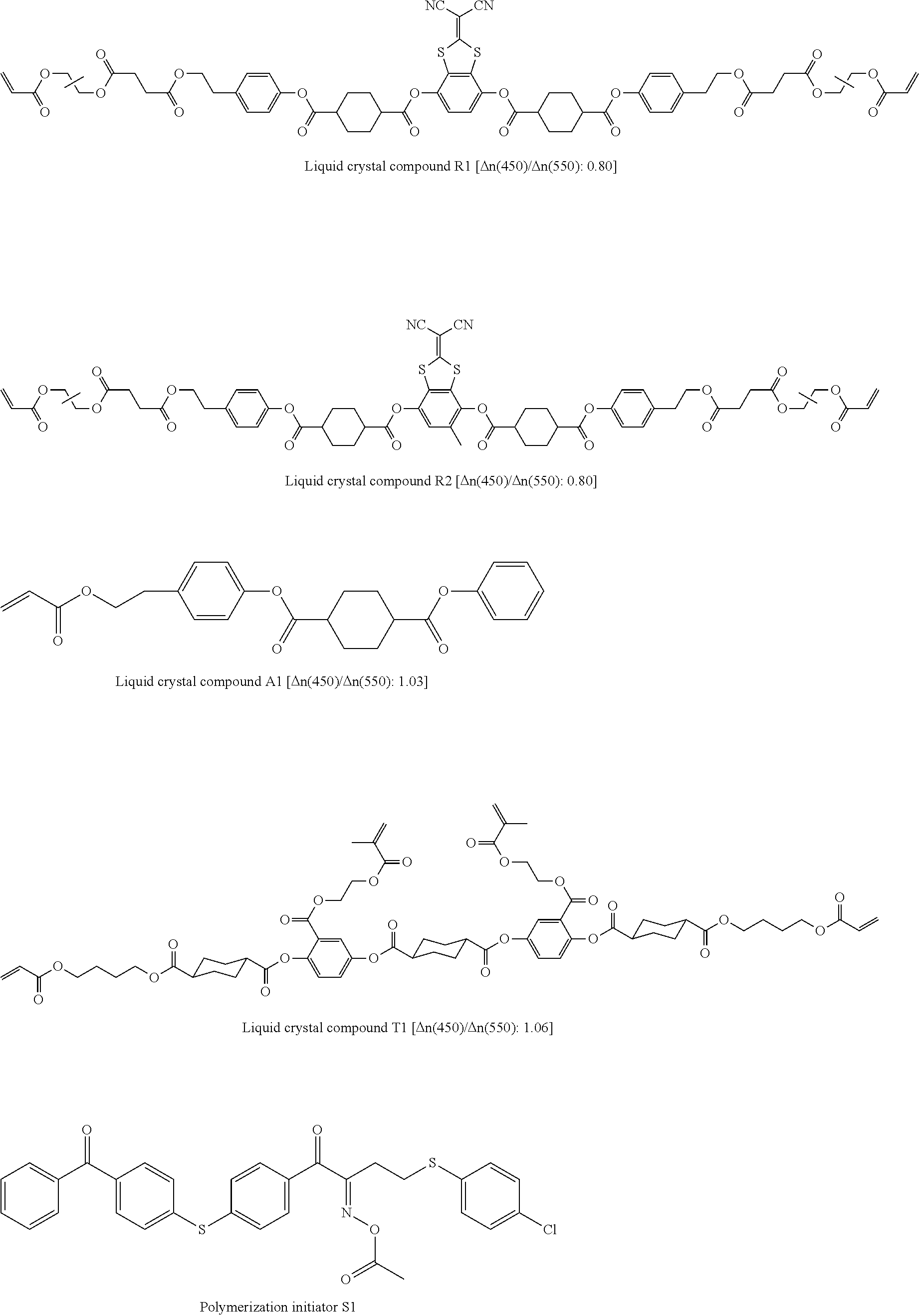

Surfactant P1-1 [in the following formula, 32.5 and 67.5 indicate contents (% by mass) of each repeating unit with respect to all repeating units in the surfactant P1]

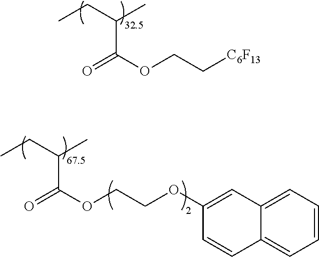

The composition 1 for a photo-alignment film prepared above was applied onto a surface of the knurling protrusion side of the produced cellulose acylate film 1 (support) with a die coater. Thereafter, the solvent was removed by drying at 80° C. for 5 minutes to form a 0.2 μm-thick photoisomerization composition layer. The obtained photoisomerization composition layer was irradiated with polarized ultraviolet rays (10 mJ/cm², using an ultra-high pressure mercury lamp) to form a photo-alignment film 1 having a thickness of 0.2 μm.

Next, the polymerizable liquid crystal composition 1-1 prepared above was applied onto a surface of the photo-alignment film 1 with a die coater to form a composition layer. The formed composition layer was heated to a temperature at which an isotropic phase was exhibited, and then cooled to stabilize the alignment at a temperature at which a smectic phase was exhibited. Thereafter, the alignment was fixed by carrying out ultraviolet irradiation (500 mJ/cm², using an ultra-high pressure mercury lamp) in a nitrogen atmosphere (oxygen concentration: 100 ppm) while maintaining the temperature, thereby forming an optically anisotropic layer 1-1 having a thickness of 2 μm. In this way, the photo-alignment film 1 and the optically anisotropic layer 1-1 were continuously applied onto the cellulose acylate film 1 for 3,000 m, and wound around a winding core to produce an elongated film F1. In the obtained optically anisotropic layer 1-1, a peeling force at an interface with the photo-alignment film 1 was 0.05 N/25 mm; and in a case where a phase difference of the peeled optically anisotropic layer 1-1 was measured, it was confirmed that a slow axis direction was a longitudinal direction of the film, an in-plane retardation Re(550) was 130 nm, Re(450)/Re(550) was 0.85, and the optically anisotropic layer 1-1 was a positive A-plate.

### [Formation of Optically Anisotropic Layer 2-1]

### <Preparation of Polymerizable Liquid Crystal Composition 2-1>

A polymerizable liquid crystal composition 2-1 for forming an optically anisotropic layer, having the following formulation, was prepared.

The blending amount (0.17 parts by mass) of the surfactant P2-1 was 0.14% by mass with respect to the total mass of solid contents of the polymerizable liquid crystal composition 2-1.

Polymerizable liquid crystal composition 2-1

| | | |
|---|---|---|
| Liquid crystal compound R1 shown above | 10.00 | parts by mass |
| Liquid crystal compound R2 shown above | 54.00 | parts by mass |
| Liquid crystal compound R3 shown below | 28.00 | parts by mass |
| Liquid crystal compound T1 shown above | 8.00 | parts by mass |
| Compound B1 (alignment auxiliary agent) | 4.50 | parts by mass |
| shown below | | |
| NK Ester A-600 (manufactured by Shin- | 12.00 | parts by mass |
| Nakamura Chemical Co., Ltd.) | | |
| Polymerization initiator S1 shown above | 1.50 | parts by mass |
| Surfactant P2-1 shown below | 0.17 | parts by mass |
| Methyl ethyl ketone | 225.00 | parts by mass |
| Methanol | 25.00 | parts by mass |

Liquid crystal compound R3 (mixture of the following liquid crystal compounds (RA), (RB), and (RC) at a mass ratio of 83:15:2; Me in the following liquid crystal compounds (RB) and (RC) represents a methyl group][Δn(450)/Δn(550): 1.06]

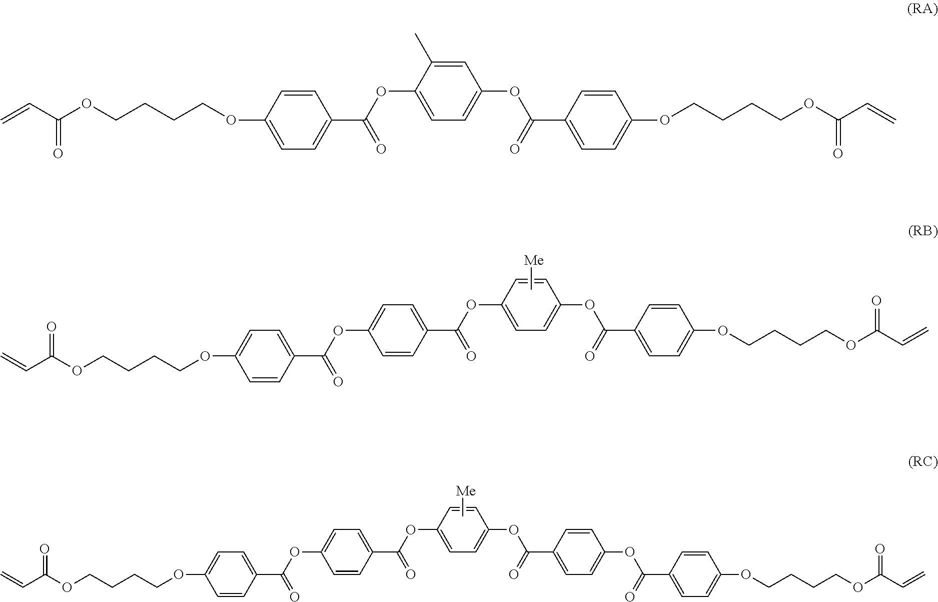

### Compound B1 (Alignment Auxiliary Agent)

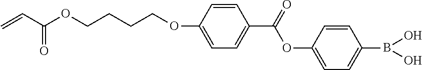 [SMILES: C=CC(=O)OCCCCOc1ccc(C(=O)Oc2ccc(B(O)O)cc2)cc1]

Surfactant P2-1 [weight-average molecular weight: 11,200; a numerical value in the following formula indicates a content (mol %) of each repeating unit with respect to all repeating units; each repeating unit in the formula corresponds, from left to right, to D1, D2, and D3 in Table 2]

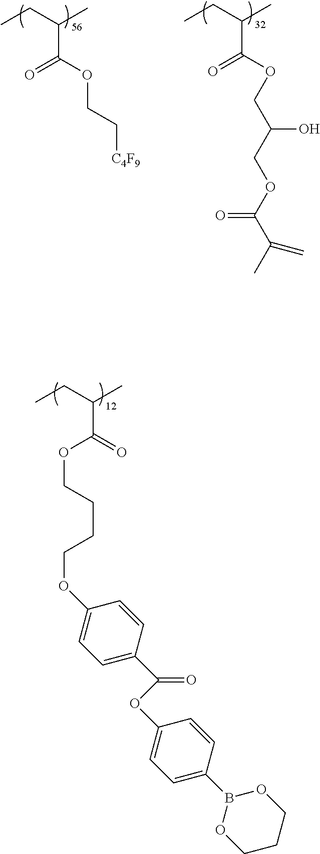

### [Production of Optical Film]

A surface of the optically anisotropic layer 1-1 was subjected to a corona treatment at a discharge amount of 150 W·min/m², and the polymerizable liquid crystal composition 2-1 prepared in the following formulation was applied onto the corona-treated surface with a die coater to form a composition layer. Next, in order to dry the solvent of the composition and align and age the liquid crystal compound, the composition layer was heated at 65° C. for 60 seconds. The vertical alignment state was fixed by irradiation with ultraviolet rays (150 mJ/cm²) at 50° C. in a nitrogen purge atmosphere with an oxygen concentration of 100 ppm, thereby producing an optically anisotropic layer 2-1 having a thickness of 1.5 μm. In this way, the optically anisotropic layer 2-1 was continuously applied onto the elongated film F1 for 3,000 m to produce an elongated optical film L1. In a case where a laminate of the optically anisotropic layers 1-1 and 2-1 was peeled off from the produced optical film L1, a phase difference of the laminate was measured, and the phase difference of the optically anisotropic layer 1-1 measured in advance was subtracted to calculate a phase difference of the optically anisotropic layer 2-1, it was confirmed that a thickness direction retardation RthC(550) was −90 nm, RthC(450)/RthC(550) was 0.88, and the optically anisotropic layer 2-1 was a positive C-plate (nz>nx=ny).

### Example 2

An elongated optical film L2 was produced by the same method as in Example 1, except that the surfactant P2-1 was changed to the following surfactant P2-2.

Surfactant P2-2 [weight-average molecular weight: 11,200; a numerical value in the following formula indicates a content (mol %) of each repeating unit with respect to all repeating units; each repeating unit in the formula corresponds, from left to right, to D1, D2, D3, and D4 in Table 2]

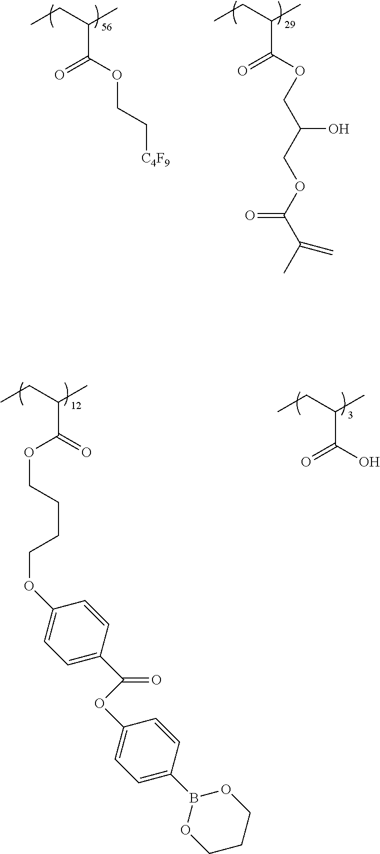

### Example 3

An elongated optical film L3 was produced by the same method as in Example 1, except that the surfactant P2-1 was changed to the following surfactant P2-3.

Surfactant P2-3 [weight-average molecular weight: 11,200; a numerical value in the following formula indicates a content (mol %) of each repeating unit with respect to all repeating units; each repeating unit in the formula corresponds, from left to right, to D1, D2, D3, and D4 in Table 2]

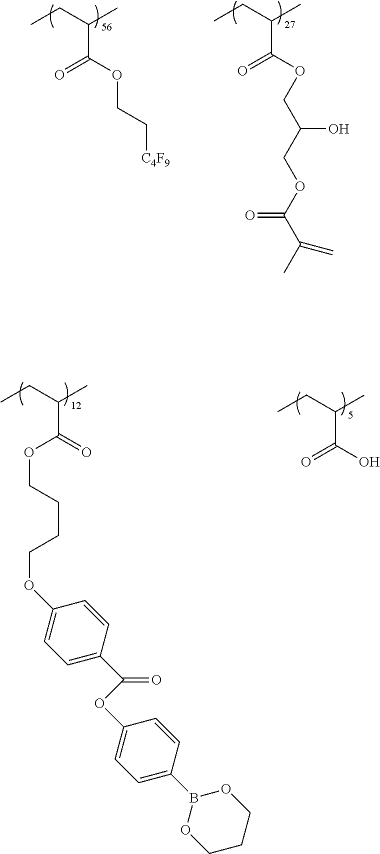

### Example 4

An elongated optical film L4 was produced by the same method as in Example 3, except that the addition amount of the surfactant P2-3 was changed to 0.08 parts by mass (0.07% by mass with respect to the total mass of solid contents).

### Example 5

### [Formation of Optically Anisotropic Layer 1-5]

An optically anisotropic layer 1-5 as a positive A-plate was formed by the same method as in Example 1, except that a polymerizable liquid crystal composition 1-5 having the following formulation was used instead of the polymerizable liquid crystal composition 1-1.

Polymerizable liquid crystal composition 1-5

| | | |
|---|---|---|
| Liquid crystal compound R2 shown above | 20.00 | parts by mass |
| Liquid crystal compound R4 shown below | 27.00 | parts by mass |
| Liquid crystal compound R5 shown below | 20.00 | parts by mass |
| Liquid crystal compound R6 shown below | 16.50 | parts by mass |
| Liquid crystal compound R7 shown below | 16.50 | parts by mass |
| Liquid crystal compound A2 shown below | 15.00 | parts by mass |
| Non-liquid crystal compound M1 shown below | 3.00 | parts by mass |
| Polymerization initiator S1 shown above | 0.50 | parts by mass |
| Surfactant P1-2 shown below | 0.09 | parts by mass |
| Cyclopentanone | 179.67 | parts by mass |
| Methyl ethyl ketone | 53.67 | parts by mass |

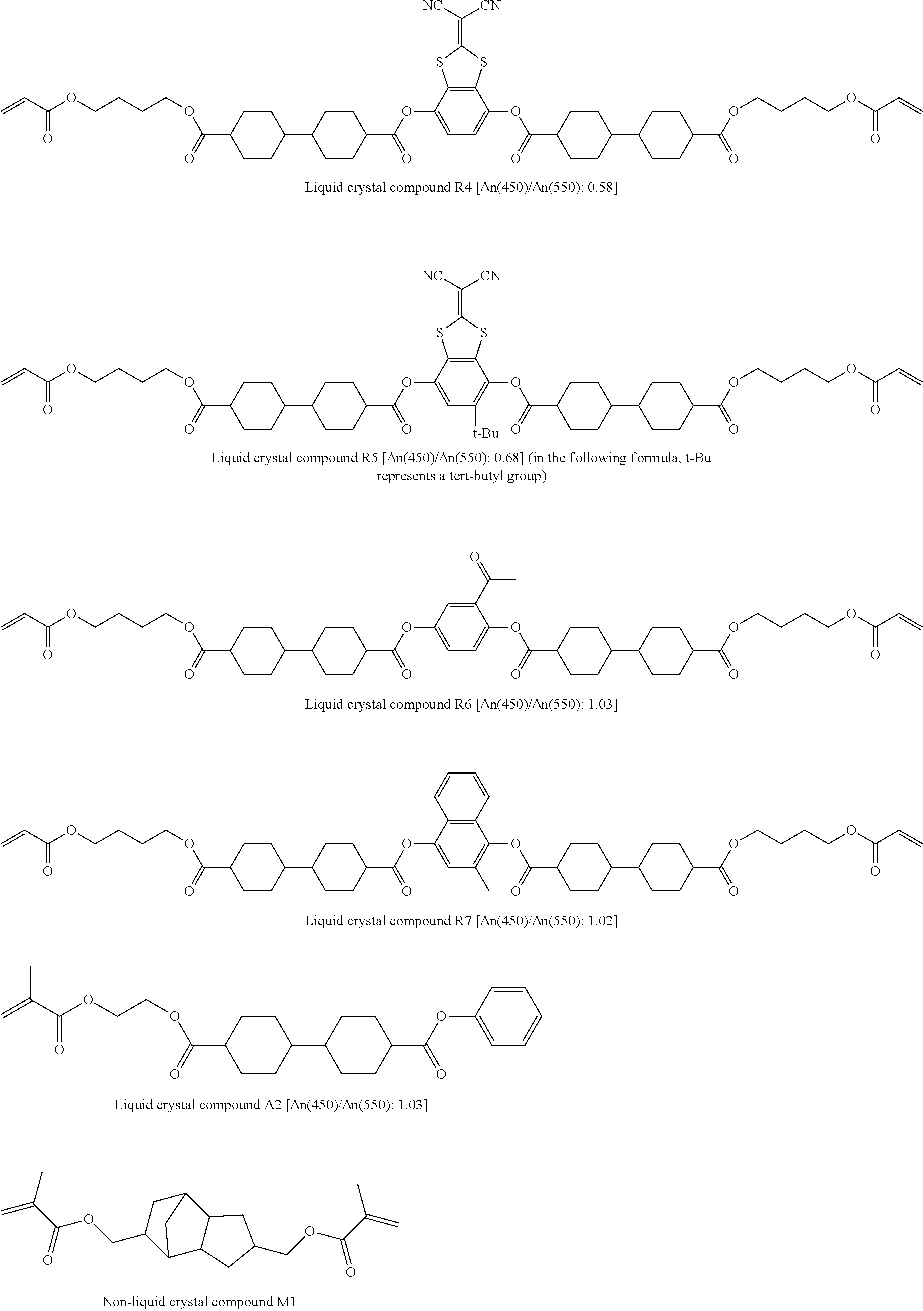

Surfactant P1-2 (in the following formula, numerical values indicate contents (% by mass) of each repeating unit with respect to all repeating units in the surfactant P1-2)

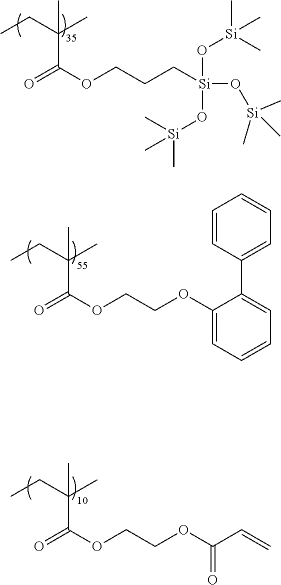

### [Formation of Optically Anisotropic Layer 2-5]

An elongated optical film L5 was produced by the same method as in Example 1, except that the optically anisotropic layer 1-5 was used instead of the optically anisotropic layer 1-1, and a polymerizable liquid crystal composition 2-5 having the following formulation was used instead of the polymerizable liquid crystal composition 2-1.

The blending amount (0.21 parts by mass) of the surfactant P2-4 in the polymerizable liquid crystal composition 2-5 was 0.18% by mass with respect to the total mass of solid contents of the polymerizable liquid crystal composition 2-5.

Polymerizable liquid crystal composition 2-5

| | | |
|---|---|---|
| Liquid crystal compound R2 shown above | 10.00 | parts by mass |
| Liquid crystal compound R4 shown above | 24.80 | parts by mass |
| Liquid crystal compound R5 shown above | 24.80 | parts by mass |
| Liquid crystal compound R6 shown above | 20.20 | parts by mass |
| Liquid crystal compound R7 shown above | 20.20 | parts by mass |
| Liquid crystal compound A2 shown above | 10.00 | parts by mass |
| Compound B1 shown above | 3.00 | parts by mass |
| Compound C3 shown below | 8.00 | parts by mass |
| Polymerization initiator S1 shown above | 3.00 | parts by mass |
| Surfactant P2-4 shown below | 0.21 | parts by mass |
| Cyclopentanone | 232.80 | parts by mass |
| Methyl ethyl ketone | 60.50 | parts by mass |
| Methanol | 9.10 | parts by mass |

### Compound C3 (Mixture of Following Compounds)

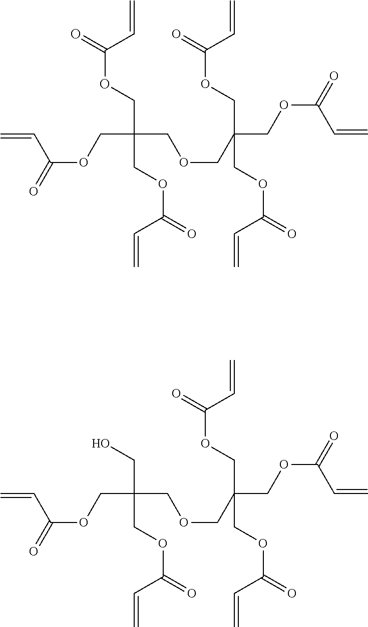

Surfactant P2-4 [weight-average molecular weight: 12,600; a numerical value in the following formula indicates a content (mol %) of each repeating unit with respect to all repeating units; each repeating unit in the formula corresponds, from left to right, to D8, D3, D2, and D4 in Table 2]

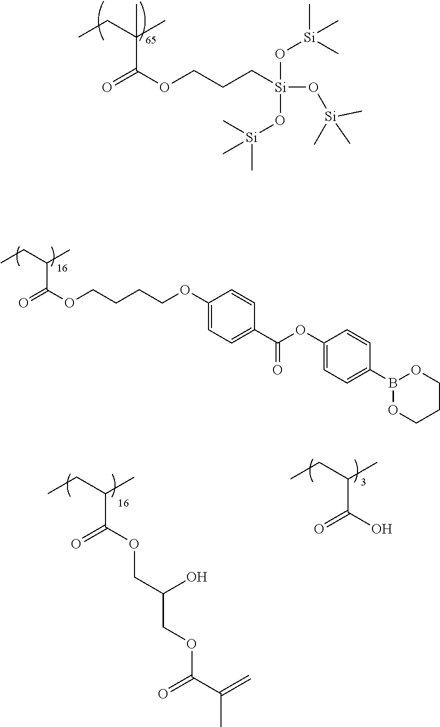

### Example 6

An elongated optical film L6 was produced by the same method as in Example 1, except that the surfactant P1-1 was changed to the surfactant P1-2, and the surfactant P2-1 was changed to the surfactant P2-4.

### Example 7

An elongated optical film L7 was produced by the same method as in Example 1, except that the surfactant P2-1 was changed to the following surfactant P2-5.

Surfactant P2-5 [weight-average molecular weight: 11,200; a numerical value in the following formula indicates a content (mol %) of each repeating unit with respect to all repeating units; each repeating unit in the formula corresponds, from left to right, to D1, D2, D3, and D5 in Table 2]

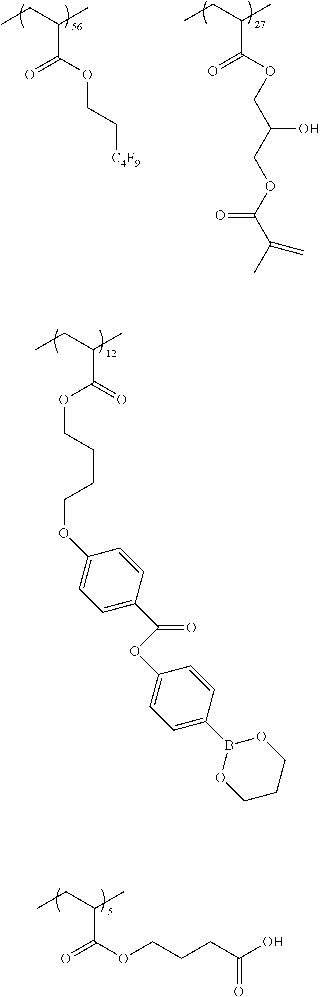

### Example 8

An elongated optical film L8 was produced by the same method as in Example 1, except that the surfactant P2-1 was changed to the following surfactant P2-6.

Surfactant P2-6 [weight-average molecular weight: 11,200; a numerical value in the following formula indicates a content (mol %) of each repeating unit with respect to all repeating units; each repeating unit in the formula corresponds, from left to right, to D1, D2, D3, and D6 in Table 2]

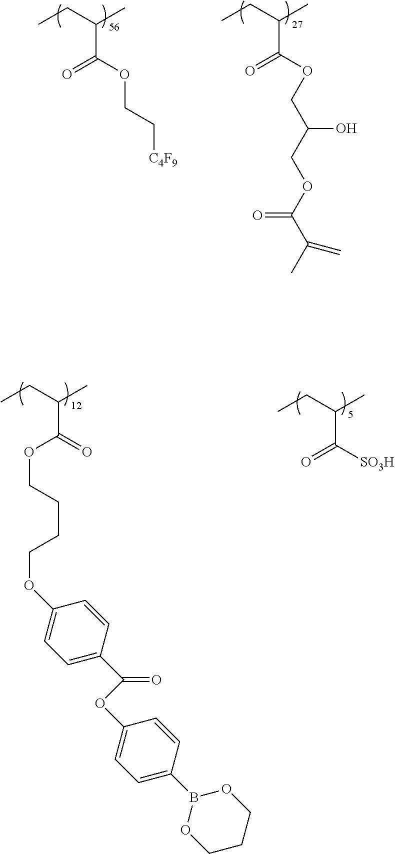

### Example 9

An elongated optical film L9 was produced by the same method as in Example 1, except that the surfactant P2-1 was changed to the following surfactant P2-7.

Surfactant P2-7 [weight-average molecular weight: 11,200; a numerical value in the following formula indicates a content (mol %) of each repeating unit with respect to all repeating units; each repeating unit in the formula corresponds, from left to right, to D1, D2, D3, and D4 in Table 2]

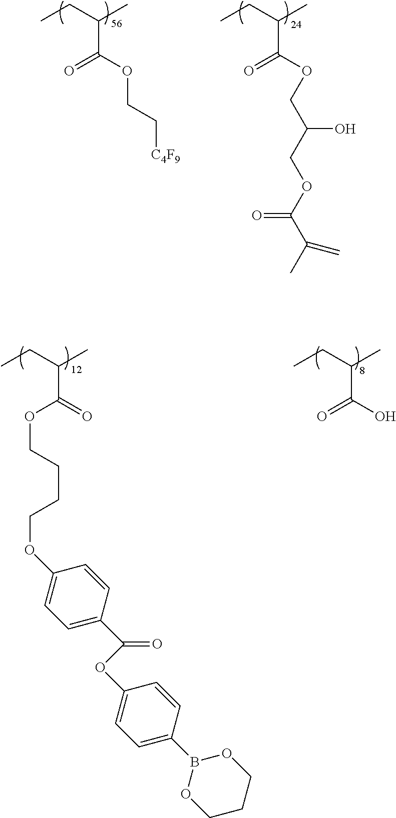

### Example 10

An elongated optical film L10 was produced by the same method as in Example 3, except that the addition amount of the surfactant P2-3 was changed to 0.05 parts by mass (0.04% by mass with respect to the total mass of solid contents).

### Example 11

An elongated optical film L11 was produced by the same method as in Example 1, except that the surfactant P2-1 was changed to the following surfactant P2-8.

Surfactant P2-8 [weight-average molecular weight: 11,200; a numerical value in the following formula indicates a content (mol %) of each repeating unit with respect to all repeating units; each repeating unit in the formula corresponds, from left to right, to D1, D2, D3, and D4 in Table 2]

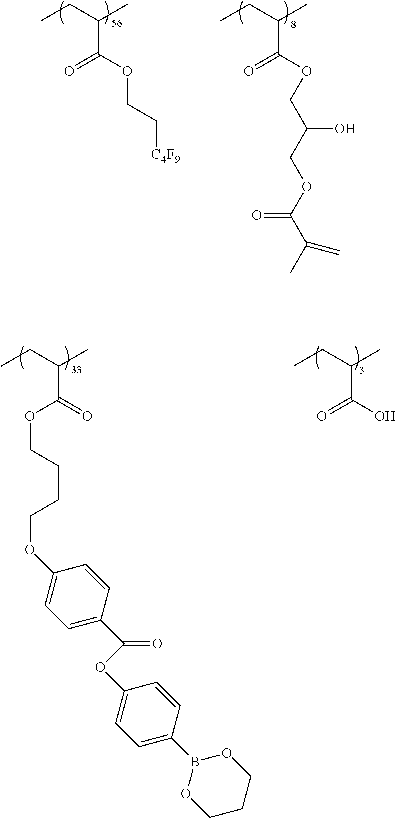

### Example 12

An elongated optical film L12 was produced by the same method as in Example 4, except that the compound B-1 (alignment auxiliary agent) was removed from the polymerizable liquid crystal composition 2-1.

### Example 13

An elongated optical film L13 was produced by the same method as in Example 1, except that the surfactant P2-1 was changed to the following surfactant P2-9.

Surfactant P2-9 [weight-average molecular weight: 11,200; a numerical value in the following formula indicates a content (mol %) of each repeating unit with respect to all repeating units; each repeating unit in the formula corresponds, from left to right, to D1, D2, D7, and D4 in Table 2]

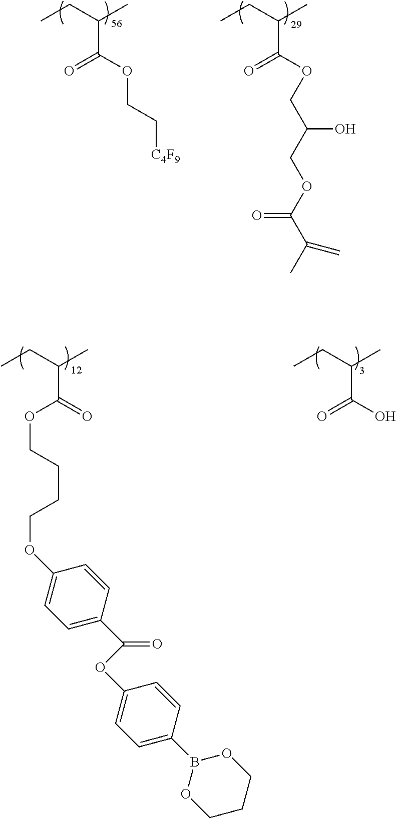

### Example 14

### [Formation of Optically Anisotropic Layer 1-14]

An optically anisotropic layer 1-14 as a positive A-plate was formed by the same method as in Example 1, except that a polymerizable liquid crystal composition 1-14 having the following formulation was used instead of the polymerizable liquid crystal composition 1-1.

Polymerizable liquid crystal composition 1-14

| | | |
|---|---|---|
| Liquid crystal compound R8 shown below | 100.00 | parts by mass |
| Polymerization initiator S1 shown below | 0.50 | parts by mass |
| Surfactant P1-1 shown below | 0.20 | parts by mass |
| HISOLVE MTEM (manufactured by TOHO | 2.00 | parts by mass |
| Chemical Industry Co., Ltd.) | | |
| NK Ester A-200 (manufactured by Shin- | 1.00 | part by mass |
| Nakamura Chemical Co., Ltd.) | | |
| Methyl ethyl ketone | 424.80 | parts by mass |

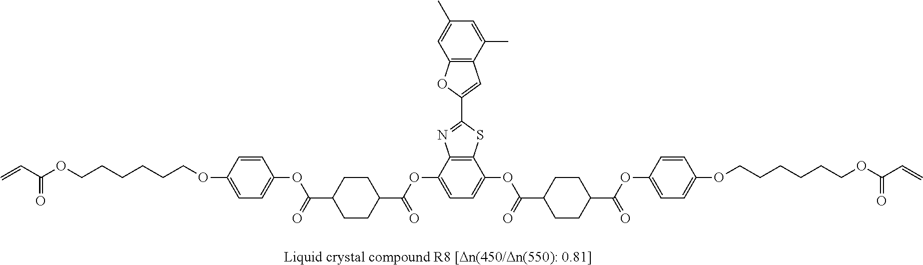 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c4sc(-c5cc6c(C)cc(C)cc6o5)nc34)CC2)cc1]

### [Formation of Optically Anisotropic Layer 2-14]

An elongated optical film L14 was produced by the same method as in Example 1, except that the optically anisotropic layer 1-14 was used instead of the optically anisotropic layer 1-1, and a polymerizable liquid crystal composition 2-14 having the following formulation was used instead of the polymerizable liquid crystal composition 2-1.

The blending amount (0.17 parts by mass) of the surfactant P2-1 in the polymerizable liquid crystal composition 2-14 was 0.14% by mass with respect to the total mass of solid contents of the polymerizable liquid crystal composition 2-14.

Polymerizable liquid crystal composition 2-14

| | | |
|---|---|---|
| Liquid crystal compound R8 shown above | 100.00 | parts by mass |
| Compound B1 (alignment auxiliary agent) | 4.50 | parts by mass |
| shown above | | |
| NK Ester A-600 (manufactured by Shin- | 12.00 | parts by mass |
| Nakamura Chemical Co., Ltd.) | | |
| Polymerization initiator S1 shown above | 1.50 | parts by mass |
| Surfactant P2-1 shown above | 0.17 | parts by mass |
| Methyl ethyl ketone | 225.00 | parts by mass |
| Methanol | 25.00 | parts by mass |

### Example 15

### [Formation of Optically Anisotropic Layer 1-15]

An optically anisotropic layer 1-15 as a positive A-plate was formed by the same method as in Example 1, except that a polymerizable liquid crystal composition 1-15 having the following formulation was used instead of the polymerizable liquid crystal composition 1-1.

Polymerizable liquid crystal composition 1-15

| | | |
|---|---|---|
| Liquid crystal compound R9 shown below | 100.00 | parts by mass |
| Polymerization initiator S1 shown above | 0.50 | parts by mass |
| Surfactant P1-1 shown above | 0.20 | parts by mass |
| HISOLVE MTEM (manufactured by TOHO | 2.00 | parts by mass |
| Chemical Industry Co., Ltd.) | | |
| NK Ester A-200 (manufactured by Shin- | 1.00 | part by mass |
| Nakamura Chemical Co., Ltd.) | | |
| Methyl ethyl ketone | 424.80 | parts by mass |

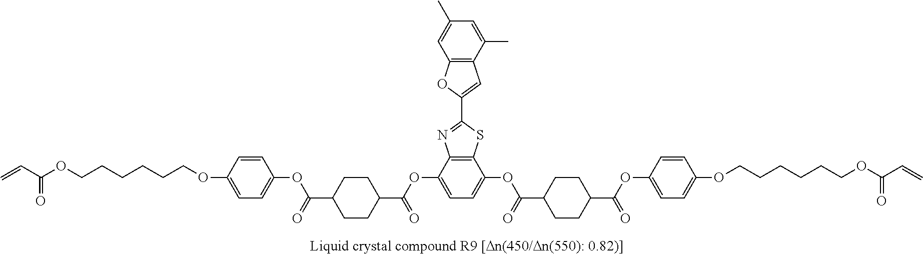 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c4sc(-c5cc6c(C)cc(C)cc6o5)nc34)CC2)cc1]

### [Formation of Optically Anisotropic Layer 2-15]

An elongated optical film L15 was produced by the same method as in Example 1, except that the optically anisotropic layer 1-15 was used instead of the optically anisotropic layer 1-1, and a polymerizable liquid crystal composition 2-15 having the following formulation was used instead of the polymerizable liquid crystal composition 2-1.

The blending amount (0.17 parts by mass) of the surfactant P2-1 in the polymerizable liquid crystal composition 2-15 was 0.14% by mass with respect to the total mass of solid contents of the polymerizable liquid crystal composition 2-15.

Polymerizable liquid crystal composition 2-15

| | | |
|---|---|---|
| Liquid crystal compound R9 shown above | 100.00 | parts by mass |
| Compound B1 (alignment auxiliary agent) | 4.50 | parts by mass |
| shown above | | |
| NK Ester A-600 (manufactured by Shin- | 12.00 | parts by mass |
| Nakamura Chemical Co., Ltd.) | | |
| Polymerization initiator S1 shown above | 1.50 | parts by mass |
| Surfactant P2-1 shown above | 0.17 | parts by mass |
| Methyl ethyl ketone | 225.00 | parts by mass |
| Methanol | 25.00 | parts by mass |

### Example 16

### [Formation of Optically Anisotropic Layer 1-16]

An optically anisotropic layer 1-16 as a positive A-plate was formed by the same method as in Example 1, except that a polymerizable liquid crystal composition 1-16 having the following formulation was used instead of the polymerizable liquid crystal composition 1-1.

Polymerizable liquid crystal composition 1-16

| | | |
|---|---|---|
| Liquid crystal compound R10 shown below | 100.00 | parts by mass |
| Polymerization initiator S1 shown above | 0.50 | parts by mass |
| Surfactant P1-1 shown above | 0.20 | parts by mass |
| HISOLVE MTEM (manufactured by TOHO | 2.00 | parts by mass |
| Chemical Industry Co., Ltd.) | | |
| NK Ester A-200 (manufactured by Shin- | 1.00 | part by mass |
| Nakamura Chemical Co., Ltd.) | | |
| Methyl ethyl ketone | 424.80 | parts by mass |

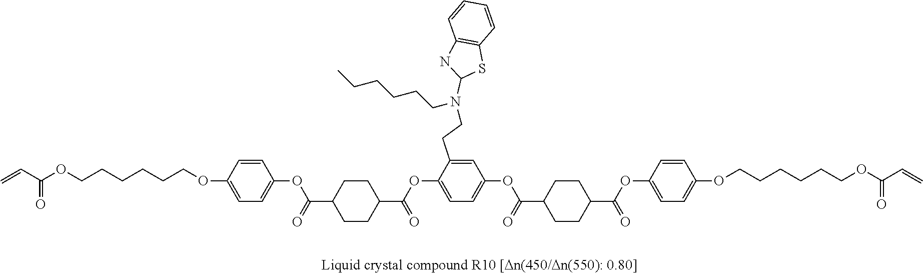 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c(CCN(CCCCCC)C4Nc5ccccc5S4)c3)CC2)cc1]

### [Formation of Optically Anisotropic Layer 2-16]

An elongated optical film L16 was produced by the same method as in Example 1, except that the optically anisotropic layer 1-16 was used instead of the optically anisotropic layer 1-1, and a polymerizable liquid crystal composition 2-16 having the following formulation was used instead of the polymerizable liquid crystal composition 2-1.

The blending amount (0.17 parts by mass) of the surfactant P2-1 in the polymerizable liquid crystal composition 2-16 was 0.14% by mass with respect to the total mass of solid contents of the polymerizable liquid crystal composition 2-16.

Polymerizable liquid crystal composition 2-16

| | | |
|---|---|---|
| Liquid crystal compound R10 shown above | 100.00 | parts by mass |
| Compound B1 (alignment auxiliary agent) | 4.50 | parts by mass |
| shown above | | |
| NK Ester A-600 (manufactured by Shin- | 12.00 | parts by mass |
| Nakamura Chemical Co., Ltd.) | | |
| Polymerization initiator S1 shown above | 1.50 | parts by mass |
| Surfactant P2-1 shown above | 0.17 | parts by mass |
| Methyl ethyl ketone | 225.00 | parts by mass |
| Methanol | 25.00 | parts by mass |

### Example 17

### [Formation of Optically Anisotropic Layer 1-17]

An optically anisotropic layer 1-17 as a positive A-plate was formed by the same method as in Example 1, except that a polymerizable liquid crystal composition 1-17 having the following formulation was used instead of the polymerizable liquid crystal composition 1-1.

Polymerizable liquid crystal composition 1-17

| | | |
|---|---|---|
| Liquid crystal compound R11 shown below | 100.00 | parts by mass |
| Polymerization initiator S1 shown above | 0.50 | parts by mass |
| Surfactant P1-1 shown above | 0.20 | parts by mass |
| HISOLVE MTEM (manufactured by TOHO | 2.00 | parts by mass |
| Chemical Industry Co., Ltd.) | | |
| NK Ester A-200 (manufactured by Shin- | 1.00 | part by mass |
| Nakamura Chemical Co., Ltd.) | | |
| Methyl ethyl ketone | 424.80 | parts by mass |

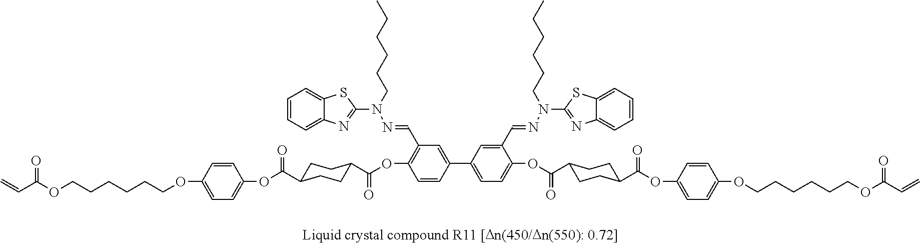 [SMILES: C=CC(=O)OCCCCCCOc1ccc(OC(=O)C2CCC(C(=O)Oc3ccc(-c4ccc(OC(=O)C5CCC(C(=O)Oc6ccc(OCCCCCCOC(=O)C=C)cc6)CC5)c(/C=N/N(CCCCCC)c5nc6ccccc6s5)c4)cc3/C=N/N(CCCCCC)c3nc4ccccc4s3)CC2)cc1]

### [Formation of Optically Anisotropic Layer 2-17]

An elongated optical film L17 was produced by the same method as in Example 1, except that the optically anisotropic layer 1-17 was used instead of the optically anisotropic layer 1-1, and a polymerizable liquid crystal composition 2-17 having the following formulation was used instead of the polymerizable liquid crystal composition 2-1.

The blending amount (0.17 parts by mass) of the surfactant P2-1 in the polymerizable liquid crystal composition 2-17 was 0.14% by mass with respect to the total mass of solid contents of the polymerizable liquid crystal composition 2-17.

Polymerizable liquid crystal composition 2-17

| | | |
|---|---|---|
| Liquid crystal compound R11 shown above | 100.00 | parts by mass |
| Compound B1 (alignment auxiliary agent) | 4.50 | parts by mass |
| shown above | | |
| NK Ester A-600 (manufactured by Shin- | 12.00 | parts by mass |
| Nakamura Chemical Co., Ltd.) | | |
| Polymerization initiator S1 shown above | 1.50 | parts by mass |
| Surfactant P2-1 shown above | 0.17 | parts by mass |
| Methyl ethyl ketone | 225.00 | parts by mass |
| Methanol | 25.00 | parts by mass |

### Example 18

### [Formation of Optically Anisotropic Layer 1-18]

An optically anisotropic layer 1-18 as a positive A-plate was formed by the same method as in Example 1, except that a polymerizable liquid crystal composition 1-18 having the following formulation was used instead of the polymerizable liquid crystal composition 1-1.

Polymerizable liquid crystal composition 1-18

| | | |
|---|---|---|
| Liquid crystal compound R12 shown below | 100.00 | parts by mass |
| Polymerization initiator S1 shown above | 0.50 | parts by mass |
| Surfactant P1-1 shown above | 0.20 | parts by mass |
| HISOLVE MTEM (manufactured by TOHO | 2.00 | parts by mass |
| Chemical Industry Co., Ltd.) | | |
| NK Ester A-200 (manufactured by Shin- | 1.00 | part by mass |
| Nakamura Chemical Co., Ltd.) | | |
| Methyl ethyl ketone | 424.80 | parts by mass |

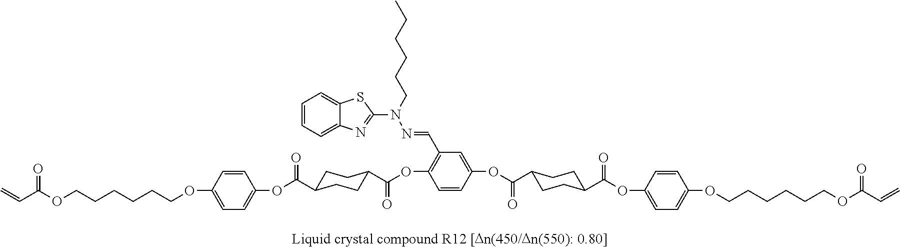 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c(/C=N/N(CCCCCC)c4nc5ccccc5s4)c3)CC2)cc1]

### [Formation of Optically Anisotropic Layer 2-18]

An elongated optical film L18 was produced by the same method as in Example 1, except that the optically anisotropic layer 1-18 was used instead of the optically anisotropic layer 1-1, and a polymerizable liquid crystal composition 2-18 having the following formulation was used instead of the polymerizable liquid crystal composition 2-1.

The blending amount (0.17 parts by mass) of the surfactant P2-1 in the polymerizable liquid crystal composition 2-18 was 0.14% by mass with respect to the total mass of solid contents of the polymerizable liquid crystal composition 2-18.

Polymerizable liquid crystal composition 2-18

| | | |
|---|---|---|
| Liquid crystal compound R12 shown above | 100.00 | parts by mass |
| Compound B1 (alignment auxiliary agent) | 4.50 | parts by mass |
| shown above | | |
| NK Ester A-600 (manufactured by Shin- | 12.00 | parts by mass |
| Nakamura Chemical Co., Ltd.) | | |
| Polymerization initiator S1 shown above | 1.50 | parts by mass |
| Surfactant P2-1 shown above | 0.17 | parts by mass |
| Methyl ethyl ketone | 225.00 | parts by mass |
| Methanol | 25.00 | parts by mass |

### Example 19

### [Formation of Optically Anisotropic Layer 1-19]

An optically anisotropic layer 1-19 as a positive A-plate was formed by the same method as in Example 1, except that a polymerizable liquid crystal composition 1-19 having the following formulation was used instead of the polymerizable liquid crystal composition 1-1.

Polymerizable liquid crystal composition 1-19

| | | |
|---|---|---|
| Liquid crystal compound R13 shown below | 100.00 | parts by mass |
| Polymerization initiator S1 shown above | 0.50 | parts by mass |
| Surfactant P1-1 shown above | 0.20 | parts by mass |
| HISOLVE MTEM (manufactured by TOHO | 2.00 | parts by mass |
| Chemical Industry Co., Ltd.) | | |
| NK Ester A-200 (manufactured by Shin- | 1.00 | part by mass |
| Nakamura Chemical Co., Ltd.) | | |
| Methyl ethyl ketone | 424.80 | parts by mass |

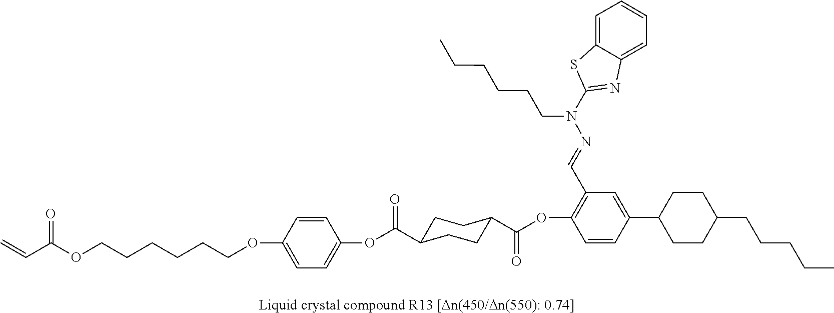 [SMILES: C=CC(=O)OCCCCCCOc1ccc(OC(=O)C2CCC(C(=O)Oc3ccc(C4CCC(CCCCC)CC4)cc3/C=N/N(CCCCCC)c3nc4ccccc4s3)CC2)cc1]

### [Formation of Optically Anisotropic Layer 2-19]

An elongated optical film L19 was produced by the same method as in Example 1, except that the optically anisotropic layer 1-19 was used instead of the optically anisotropic layer 1-1, and a polymerizable liquid crystal composition 2-19 having the following formulation was used instead of the polymerizable liquid crystal composition 2-1.

The blending amount (0.17 parts by mass) of the surfactant P2-1 in the polymerizable liquid crystal composition 2-19 was 0.14% by mass with respect to the total mass of solid contents of the polymerizable liquid crystal composition 2-19.

Polymerizable liquid crystal composition 2-19

| | | |
|---|---|---|
| Liquid crystal compound R13 shown above | 100.00 | parts by mass |
| Compound B1 (alignment auxiliary agent) | 4.50 | parts by mass |
| shown above | | |
| NK Ester A-600 (manufactured by Shin- | 12.00 | parts by mass |
| Nakamura Chemical Co., Ltd.) | | |
| Polymerization initiator S1 shown above | 1.50 | parts by mass |
| Surfactant P2-1 shown below | 0.17 | parts by mass |
| Methyl ethyl ketone | 225.00 | parts by mass |
| Methanol | 25.00 | parts by mass |

### Comparative Example 1

An elongated optical film LH1 was produced by the same method as in Example 1, except that a polymerizable liquid crystal composition 2-20 having the following formulation was used instead of the polymerizable liquid crystal composition 2-1.

Polymerizable liquid crystal composition 2-20

| | | |
|---|---|---|
| Liquid crystal compound R1 shown above | 10.00 | parts by mass |
| Liquid crystal compound R2 shown above | 54.00 | parts by mass |
| Liquid crystal compound R3 shown above | 28.00 | parts by mass |
| Liquid crystal compound T1 shown above | 8.00 | parts by mass |
| Compound B1 shown above | 4.50 | parts by mass |
| NK Ester A-600 (manufactured by Shin- | 12.00 | parts by mass |
| Nakamura Chemical Co., Ltd.) | | |
| Polymerization initiator S1 shown above | 1.50 | parts by mass |
| Surfactant P2-1 shown above | 0.17 | parts by mass |
| Surfactant P2-10 shown below | 0.17 | parts by mass |
| Methyl ethyl ketone | 225.00 | parts by mass |
| Methanol | 25.00 | parts by mass |

Surfactant P2-10 [weight-average molecular weight: 15,000; a numerical value in the following formula indicates a content (mol %) of each repeating unit with respect to all repeating units; regarding the numerical values (mol %) in the formula, in a case of being expressed as the content (% by mass) of each repeating unit with respect to the all repeating units, the leftmost repeating unit constitutes 90% by mass and the subsequent repeating unit constitutes 10% by mass; each repeating unit in the formula corresponds, from left to right, to D9 and D4 in Table 2]

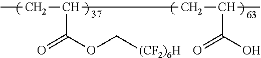

### Comparative Example 2

An elongated optical film LH2 was produced by the same method as in Example 1, except that the surfactant P2-1 was changed to the following surfactant P2-11.

Surfactant P2-11 [weight-average molecular weight: 11,200; a numerical value in the following formula indicates a content (mol %) of each repeating unit with respect to all repeating units; each repeating unit in the formula corresponds, from left to right, to D1, D3, and D4 in Table 2]

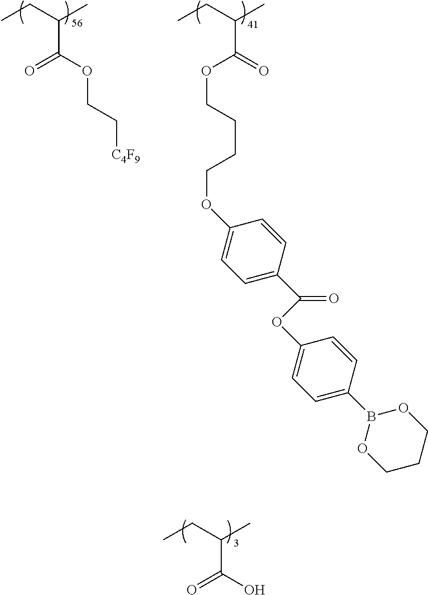

### Comparative Example 3

An elongated optical film LH3 was produced by the same method as in Example 1, except that the surfactant P2-1 was changed to the following surfactant P2-12.

Surfactant P2-12 [weight-average molecular weight: 11,200; a numerical value in the following formula indicates a content (mol %) of each repeating unit with respect to all repeating units; each repeating unit in the formula corresponds, from left to right, to D1, D2, D3, and D4 in Table 2]

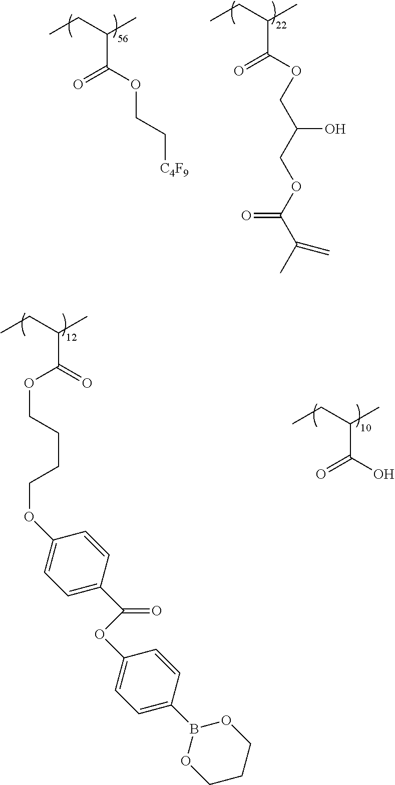

### Comparative Example 4

An elongated optical film LH4 was produced by the same method as in Example 1, except that the surfactant P2-1 was changed to the following surfactant P2-13.

Surfactant P2-13 [weight-average molecular weight. 11,200; a numerical value in the following formula indicates a content (mol %) of each repeating unit with respect to all repeating units; each repeating unit in the formula corresponds, from left to right, to D1, D2, D3 and D5 in Tahle 2]

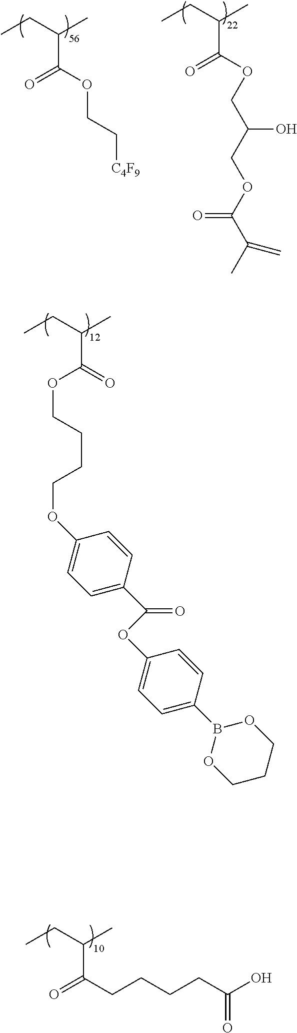

### Comparative Example 5

An elongated optical film LH5 was produced by the same method as in Example 1, except that the surfactant P2-1 was changed to the following surfactant P2-14.

Surfactant P2-14 [weight-average molecular weight: 11,200; a numerical value in the following formula indicates a content (mol %) of each repeating unit with respect to all repeating units; each repeating unit in the formula corresponds, from left to right, to D1, D2, D3, and D6 in Table 2]

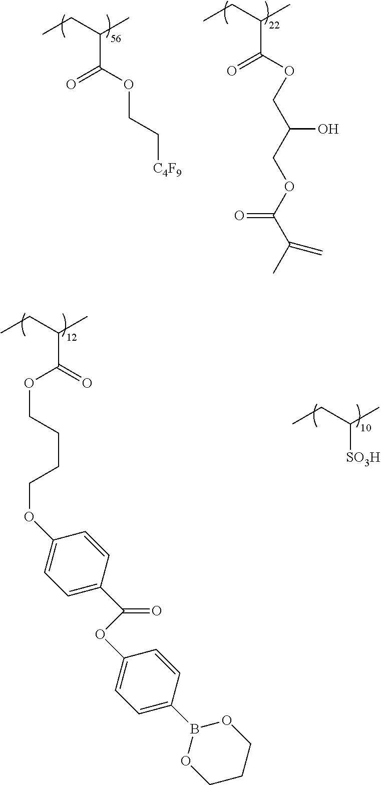

The structures, blending amounts, and the like of the liquid crystal compound (limited to one having the maximum content), the surfactant, and the alignment auxiliary agent, contained in the liquid crystal compositions used for forming the optically anisotropic layer as a positive C-plate in the elongated optical films produced in Examples and Comparative Examples described above, are shown in Table 2.

### [Suppression of Occurrence of Precipitates (Streak Occurrence Length)]

The elongated optical film was cut to a length of 1000 mm×a width of 1340 mm at the 3000 m application end part. The film was set in the cross nicol with a film longitudinal direction aligned with one of polarizer absorption axes, and the azimuth of 1 cycle (360°) was observed from the polar angle 60° direction with the axis perpendicular to the film surface as a reference. In a case where streaky unevenness was visually recognized in the film longitudinal direction, the number of streaks was evaluated according to the following standard.

### <Evaluation Standard>

A: 0
B: 1
C: 2 or more and 6 or less
D: 7 or more

### [Unevenness]

The elongated optical film was cut to a length of 1000 mm×a width of 1340 mm at the 3000 m application end part. The film was set in the cross nicol with a film longitudinal direction aligned with one of polarizer absorption axes, and the azimuth of 1 cycle (360°) was observed from the polar angle 60° direction with the axis perpendicular to the film surface as a reference. For unevenness other than the streaky unevenness in the film longitudinal direction, the unevenness was evaluated according to the following standard.

### <Evaluation Standard>

A: unevenness was visually recognized in an area of less than 10% of the entire area.
B: unevenness was visually recognized in an area of 10% or more and less than 30% of the entire area.
C: unevenness was visually recognized in an area of 30% or more of the entire area.

### [Alignment]

The elongated optical film was cut to a length of 1000 mm×a width of 1340 mm at the 3000 m application end part. The film was set in the cross nicol with a film longitudinal direction aligned with one of polarizer absorption axes, and the observation was carried out from the polar angle 0° direction with the axis perpendicular to the film surface as a reference. An alignment failure rate (light leakage portion) visually recognized in this case was evaluated according to the following standard.

### <Evaluation Standard>

A: number of bright points (ink laydown) visually recognized in the observation part was less than 10.
B: the number of bright points (ink laydown) visually recognized in the observation part was 10 or more and less than 100.
C: the number of bright points (ink laydown) visually recognized in the observation part was 100 or more.

### [Display Performance]

### [Production of Protective Film 1]

### <Preparation of Core Layer Cellulose Acylate Dope 1>

The following composition was put into a mixing tank and stirred to dissolve the respective components, thereby preparing a core layer cellulose acylate dope 1.

Core layer cellulose acylate dope 1

| | | |
|---|---|---|
| Cellulose acetate having acetyl | 100 | parts by mass |
| substitution degree of 2.88 | | |
| Ester oligomer (the following compound 1-1) | 10 | parts by mass |
| Durability improver (the following | 4 | parts by mass |
| compound 1-2) | | |
| Ultraviolet absorber (the following | 3 | parts by mass |
| compound 1-3) | | |
| Methylene chloride (first solvent) | 438 | parts by mass |
| Methanol (second solvent) | 65 | parts by mass |

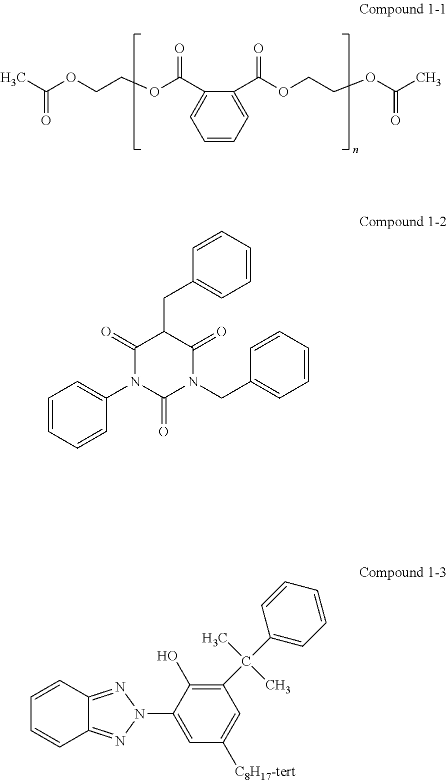

### <Preparation of Outer Layer Cellulose Acylate Dope 1>

10 parts by mass of the following matting agent dispersion liquid 1 was added to 90 parts by mass of the above-described core layer cellulose acylate dope 1, thereby preparing an outer layer cellulose acylate dope 1.

Matting agent solution

| | | |
|---|---|---|
| Silica particles having an average | 2 | parts by mass |
| particle diameter of 20 nm | | |
| (AEROSIL R972, manufactured | | |
| by Nippon Aerosil Co., Ltd.) | | |
| Methylene chloride (first solvent) | 76 | parts by mass |
| Methanol (second solvent) | 11 | parts by mass |
| Core layer cellulose acylate dope 1 | 1 | part by mass |

### <Production of Protective Film 1>

Three layers of the above-described core layer cellulose acylate dope 1 and the outer layer cellulose acylate dopes 1 on both sides thereof were simultaneously cast from a casting port onto a drum at 20° C. In a state in which the content of the solvent in the film on the drum was approximately 20% by mass, the film was peeled off from the drum, and both ends of the obtained film in a width direction were fixed with tenter clips, and in a state in which the content of the residual solvent in the film was 3% to 15% by mass, the film was stretched 1.2 times in the transverse direction and dried. Thereafter, the obtained film was transported between rolls of a heat treatment device to produce a cellulose acylate film 1 having a thickness of 25 μm, which was used as a protective film 1.

[Production of Protective Film 1 with Hard Coat Layer]

As a coating liquid for forming a hard coat layer, a curable composition (hard coat 1) for a hard coat, shown in the following table, was prepared.

TABLE 1

| | Monomer | | | | | | |
|---|---|---|---|---|---|---|---|
| | | | | Total | UV initiator | | |
| | | | | addition | | Addition | |
| | | | | amount | | amount | |
| | | | Monomer1/ | [part by | | [part by | |
| | Monomer 1 | Monomer 2 | monomer 2 | mass] | Type | mass] | Solvent |
| Hard | Pentaerythritol | Pentaerythritol | 3/2 | 53.5 | UV | 1.5 | Ethyl |
| coat 1 | triacrylate | tetraacrylate | | | initiator 1 | | acetate |

A structure of the UV initiator 1 in Table 1 above is shown below.

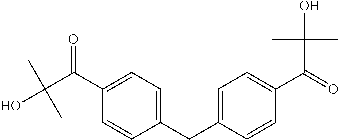 [SMILES: CC(C)(O)C(=O)c1ccc(Cc2ccc(C(=O)C(C)(C)O)cc2)cc1]

The above-described curable composition for a hard coat was applied onto a surface of the protective film 1 produced as described above, dried at 100° C. for 60 seconds, and cured by being irradiated with UV at 1.5 kW and 300 mJ under the conditions of 0.1% or less of nitrogen to produce a protective film 1 with a hard coat layer, having a hard coat layer with a film thickness of 5 μm. The film thickness of the hard coat layer was adjusted by adjusting a coating amount by a die coating method using a slot die.

[Production of Polarizing Plate 1 with Protective Film on One Side]

### (1) Saponification of Film

The produced protective film 1 with a hard coat layer was immersed for 1 minute in a 4.5 mol/L sodium hydroxide aqueous solution (saponified solution) in which a temperature was adjusted to 37° C., washed with water, immersed in a 0.05 mol/L sulfuric acid aqueous solution for 30 seconds, and further passed through a water washing bath. The obtained film was repeatedly dehydrated three times with an air knife to drop water, and then dried by leaving it in a drying zone at 70° C. for 15 seconds to produce a saponified protective film 1 with a hard coat layer.

### (2) Production of Polarizer

According to Examples of JP2016-148724A, a polarizer with a film thickness of 15 m was prepared by imparting a difference in circumferential speed between two pairs of nip rolls and stretching in the longitudinal direction. The polarizer thus produced was used as a polarizer 1.

### (3) Bonding

The polarizer 1 thus obtained and the saponified protective film 1 with a hard coat layer were bonded to each other in a roll-to-roll manner so that the polarizing axis and the longitudinal direction of the film were orthogonal to each other, using a 3% PVA (manufactured by Kuraray Co., Ltd., PVA-117H) aqueous solution as an adhesive, thereby producing a polarizing plate 1 with a protective film on one side (hereinafter also simply referred to as “polarizing plate 1”). In this case, the bonding was carried out such that the cellulose acylate film side of the protective film was on the polarizer side.

### [Production of First Polarizing Plate]

The optically anisotropic layer of the produced optical laminate and the polarizer surface of the polarizing plate 1 were bonded to each other in a roll-to-roll manner so that the polarizing axis and the longitudinal direction of the film were orthogonal to each other, using a 3% PVA (manufactured by Kuraray Co., Ltd., PVA-117H) aqueous solution as an adhesive, thereby producing a first polarizing plate.

### [Production of Protective Film 2]

### <Production of Polymethyl Methacrylate (PMMA) Dope>

The following dope composition was put into a mixing tank and stirred to dissolve each component, thereby preparing a PMMA dope.

PMMA dope

| | | |
|---|---|---|
| PMMA resin | 100 | parts by mass |
| SUMILIZER GS (manufactured by | 0.1 | parts by mass |
| Sumitomo Chemical Co., Ltd.) | | |
| Dichloromethane | 426 | parts by mass |
| Methanol | 64 | parts by mass |

### <Production of Protective Film 2>

The above-described PMMA dope was uniformly cast on a stainless steel band (casting support) from a casting die (band casting machine). The film was peeled off in a state in which the content of the solvent in the cast film was approximately 20% by mass, and both ends of the film in a width direction were fixed with tenter clips and dried while the film was stretched at a stretching ratio of 1.1 times in the transverse direction. Thereafter, the obtained film was transported between rolls of a heat treatment device and further dried to produce a PMMA film with a film thickness of 20 μm, which was used as a protective film 2.

### [Production of Second Polarizing Plate]

### <Preparation of Adhesive Composition 1>

The following compounds were mixed at described ratios to produce an adhesive composition 1.

Polymerizable compound (ARONIX M-220, manufactured by Toagosei Co., Ltd.): 20 parts by mass

Polymerizable compound (4-Hydroxybutyl acrylate, manufactured by Nihon Kasei CO., LTD.): 40 parts by mass

Polymerizable compound (2-Ethylhexyl acrylate, manufactured by Mitsubishi Chemical Corporation): 40 parts by mass

Polymerization initiator (Irgacure 907, manufactured by BASF SE): 1.5 parts by mass Sensitizer (KAYACURE DETX-S, manufactured by Nippon Kayaku Co., Ltd.): 0.5 parts by mass

### <Production of Second Polarizing Plate>

A polarizer-bonded surface of the protective film 2 was subjected to a corona treatment with a discharge amount of 150 W·min/m², and then the adhesive composition 1 was coated so as to have a film thickness of 0.5 m.

Thereafter, the adhesive-coated surface was bonded to the polarizer surface of the polarizing plate 1 with a protective film on one side, and irradiated with ultraviolet rays from the support side of the protective film 2 at 300 mJ/cm² at 40° C. in an air atmosphere. Subsequently, the resultant was dried at 60° C. for 3 minutes to produce a second polarizing plate.

### [Production of Liquid Crystal Display Device]

Polarizing plates on front and back surfaces of a commercially available liquid crystal display device (iPad (registered trademark), manufactured by Apple Inc.) (liquid crystal display device including a liquid crystal cell in an FFS mode) were peeled off; the first polarizing plate including the optical laminate produced as described above was bonded on the viewing side and the second polarizing plate was bonded on a backlight side with a 20 m acrylic pressure sensitive adhesive so that the alignment direction of the liquid crystal in the liquid crystal cell was orthogonal to the absorption axis of the polarizer in the first polarizing plate, thereby producing a liquid crystal display device of Example 1.

The liquid crystal cell in the liquid crystal display device included a color filter layer on the substrate on the first polarizing plate side and a TFT layer on the substrate on the second polarizing plate side, and Rth(550) of both the layers were 10 nm and 2 nm, respectively. In addition, Δn·d of the liquid crystal compound in the liquid crystal cell was 340, and a tilt angle of the liquid crystal compound with respect to the substrate surface was 0.1°.

### [Evaluation of Display Performance]

A black brightness was measured using a measuring device (EZ-Contrast XL88, manufactured by ELDIM) during black display of the liquid crystal display device in a dark room. With an average value of the brightness at azimuth angles of 45°, 135°, 225°, and 315° at a polar angle of 60° defined as a light leak Y, evaluation was performed according to the following standard. The results are shown in Table 2. With regard to the azimuth angle, the azimuthal angle was defined such that an absorption axis direction of the polarizer on the viewing side (first polarizer) is 0° (and 180°) and an absorption axis direction of the polarizer on the backlight side (second polarizer) is 90° (and 270°).

$$Y < 0.6 ( cd / {m}^{2} ) \qquad A$$

$$0.6 ( cd / {m}^{2} ) \leq Y < 0.8 ( cd / {m}^{2} ) \qquad B$$

$$0.8 ( cd / {m}^{2} ) \leq Y \qquad C$$

### [Suppression of Cohesive Failure]

The elongated optical film was cut to 150 mm×25 mm in the slow axis direction of the elongated optical film in the longitudinal direction, and only an 80 mm×25 mm portion was bonded to glass such that a SK1478 (manufactured by Soken Chemical & Engineering Co., Ltd.) surface was in contact with the optically anisotropic layer. A film having a photo-alignment film was prepared by removing a support and a photo-alignment film in advance.

Next, the sample was peeled off in 90° direction, the presence or absence of materials remaining on the SK1478 side was confirmed by FT-IR measurement (ATR method) on the optical film side and the SK1478 side, and interfacial peeling (evaluation A) or cohesive failure in the layer (evaluation B) was confirmed. The results are shown in Table 2.

TABLE 2

| | Liquid crystal composition forming optically anisotropic layer | | | | | | | | | | | | | | | |
|---|---|---|---|---|---|---|---|---|---|---|---|---|---|---|---|---|
| | | | Surfactant | | | | | | | | | | | | | |
| | | | | | | | | | | | | | | | | Content |
| | | | | | | | | | | | | | | | | (% by |
| | | | | | | | | | | | | | | | | mass) |
| | | | | | | | | | | | | | | | | with |
| | Main | | | | | | | | | | | | | | | respect |
| | liquid | | | Repeating | | | Repeating | | | Repeating | | | Repeating | | | to total |
| | crystal | | | unit H | | | unit K | | | unit M | | | unit X | | | mass of |
| | | I/O | Struc- | | ΔI/O | mol | | ΔI/O | mol | | ΔI/O | mol | | ΔI/O | mol | solid |
| | Type | value | ture | Type | value | % | Type | value | % | Type | value | % | Type | value | % | contents |
| Example 1 | R2 | 0.60 | P2-1 | D1 | 0.13 | 56% | D2 | 0.51 | 32% | D3 | 0.21 | 12% | — | — | — | 0.14% |
| Example 2 | R2 | 0.60 | P2-2 | D1 | 0.13 | 56% | D2 | 0.51 | 29% | D3 | 0.21 | 12% | D4 | 1.90 | 3% | 0.14% |
| Example 3 | R2 | 0.60 | P2-3 | D1 | 0.13 | 56% | D2 | 0.51 | 27% | D3 | 0.21 | 12% | D4 | 1.90 | 5% | 0.14% |
| Example 4 | R2 | 0.60 | P2-3 | D1 | 0.13 | 56% | D2 | 0.51 | 27% | D3 | 0.21 | 12% | D4 | 1.90 | 5% | 0.07% |
| Example 5 | R4 | 0.60 | P2-4 | D8 | 0.03 | 65% | D2 | 0.51 | 16% | D3 | 0.21 | 16% | D4 | 1.90 | 3% | 0.18% |
| Example 6 | R2 | 0.60 | P2-4 | D8 | 0.03 | 65% | D2 | 0.51 | 16% | D3 | 0.21 | 16% | D4 | 1.90 | 3% | 0.14% |
| Example 7 | R2 | 0.60 | P2-5 | D1 | 0.13 | 56% | D2 | 0.51 | 27% | D3 | 0.21 | 12% | D5 | 1.03 | 5% | 0.14% |
| Example 8 | R2 | 0.60 | P2-6 | D1 | 0.13 | 56% | D2 | 0.51 | 27% | D3 | 0.21 | 12% | D6 | 3.60 | 5% | 0.14% |
| Example 9 | R2 | 0.60 | P2-7 | D1 | 0.13 | 56% | D2 | 0.51 | 24% | D3 | 0.21 | 12% | D4 | 1.90 | 8% | 0.14% |
| Example 10 | R2 | 0.60 | P2-3 | D1 | 0.13 | 56% | D2 | 0.51 | 29% | D3 | 0.21 | 12% | D4 | 1.90 | 3% | 0.04% |
| Example 11 | R2 | 0.60 | P2-8 | D1 | 0.13 | 56% | D2 | 0.51 | 8% | D3 | 0.21 | 33% | D4 | 1.90 | 3% | 0.14% |
| Example 12 | R2 | 0.60 | P2-3 | D1 | 0.13 | 56% | D2 | 0.51 | 27% | D3 | 0.21 | 12% | D4 | 1.90 | 5% | 0.07% |
| Example 13 | R2 | 0.60 | P2-9 | D1 | 0.13 | 56% | D2 | 0.51 | 29% | D7 | 0.15 | 12% | D4 | 1.90 | 3% | 0.14% |
| Example 14 | R8 | 0.55 | P2-1 | D1 | 0.08 | 56% | D2 | 0.55 | 29% | D3 | 0.26 | 12% | — | — | — | 0.14% |
| Example 15 | R9 | 0.47 | P2-1 | D1 | 0.00 | 56% | D2 | 0.64 | 29% | D3 | 0.34 | 12% | — | — | — | 0.14% |
| Example 16 | R10 | 0.46 | P2-1 | D1 | 0.01 | 56% | D2 | 0.65 | 29% | D3 | 0.35 | 12% | — | — | — | 0.14% |
| Example 17 | R11 | 0.43 | P2-1 | D1 | 0.03 | 56% | D2 | 0.68 | 29% | D3 | 0.38 | 12% | — | — | — | 0.14% |
| Example 18 | R12 | 0.46 | P2-1 | D1 | 0.01 | 56% | D2 | 0.65 | 29% | D3 | 0.35 | 12% | — | — | — | 0.14% |
| Example 19 | R13 | 0.37 | P2-1 | D1 | 0.10 | 56% | D2 | 0.74 | 29% | D3 | 0.44 | 12% | — | — | — | 0.14% |
| Comparative | R2 | 0.60 | P2-1 | D1 | 0.13 | 56% | D2 | 0.51 | 32% | D3 | 0.21 | 12% | — | — | — | 0.14% |
| Example 1 | | | P2-10 | D9 | 0.14 | 37% | — | — | — | — | — | — | D4 | 1.90 | 63% | 0.14% |
| Comparative | R2 | 0.60 | P2-11 | D1 | 0.13 | 56% | — | — | — | D3 | 0.21 | 41% | D4 | 1.90 | 3% | 0.14% |
| Example 2 | | | | | | | | | | | | | | | | |
| Comparative | R2 | 0.60 | P2-12 | D1 | 0.13 | 56% | D2 | 0.51 | 22% | D3 | 0.21 | 12% | D4 | 1.90 | 10% | 0.14% |
| Example 3 | | | | | | | | | | | | | | | | |
| Comparative | R2 | 0.60 | P2-13 | D1 | 0.13 | 56% | D2 | 0.51 | 22% | D3 | 0.21 | 12% | D5 | 1.03 | 10% | 0.14% |
| Example 4 | | | | | | | | | | | | | | | | |
| Comparative | R2 | 0.60 | P2-14 | D1 | 0.13 | 56% | D2 | 0.51 | 22% | D3 | 0.21 | 12% | D6 | 3.60 | 10% | 0.14% |
| Example 5 | | | | | | | | | | | | | | | | |

| | Liquid crystal composition forming | | | | | | |
|---|---|---|---|---|---|---|---|
| | optically anisotropic layer | | | | | | |
| | Alignment | | | | | | |
| | auxiliary | | | | | | |
| | agent | | | | | | |
| | | Content | | | | | |
| | | (% by | | | | | |
| | | mass) | Evaluation item (effect) | | | | |
| | | with | Suppres- | | | | |
| | | respect | sion of | | | | |
| | | to total | occur- | | | | Suppres- |
| | | mass of | rence | | | Display | sion of |
| | | solid | of pre- | Uneven- | Align- | perfor- | cohesive |
| | Type | contents | cipitates | ness | ment | mance | failure |
| Example 1 | B-1 | 3.8% | A | A | A | A | A |
| Example 2 | B-1 | 3.8% | A | A | A | A | A |
| Example 3 | B-1 | 3.8% | A | A | A | A | A |
| Example 4 | B-1 | 3.8% | A | A | A | A | A |
| Example 5 | B-1 | 2.6% | A | A | A | A | A |
| Example 6 | B-1 | 3.8% | A | A | A | A | A |
| Example 7 | B-1 | 3.8% | A | A | A | A | A |
| Example 8 | B-1 | 3.8% | B | A | A | A | A |
| Example 9 | B-1 | 3.8% | B | A | A | A | A |
| Example 10 | B-1 | 3.8% | A | B | A | A | A |
| Example 11 | B-1 | 3.8% | A | A | A | A | A |
| Example 12 | — | — | A | A | B | A | A |
| Example 13 | B-1 | 3.8% | A | A | A | A | A |
| Example 14 | B-1 | 3.8% | A | A | A | A | A |
| Example 15 | B-1 | 3.8% | A | A | A | A | A |
| Example 16 | B-1 | 3.8% | A | A | A | A | A |
| Example 17 | B-1 | 3.8% | A | A | A | A | A |
| Example 18 | B-1 | 3.8% | A | A | A | A | A |
| Example 19 | B-1 | 3.8% | A | A | A | A | A |
| Comparative | B-1 | 3.8% | D | A | B | A | A |
| Example 1 | | | | | | | |
| Comparative | B-1 | 3.8% | A | A | A | A | B |
| Example 2 | | | | | | | |
| Comparative | B-1 | 3.8% | D | A | A | A | A |
| Example 3 | | | | | | | |
| Comparative | B-1 | 3.8% | C | A | A | A | A |
| Example 4 | | | | | | | |
| Comparative | B-1 | 3.8% | D | A | A | A | A |
| Example 5 | | | | | | | |

From the results shown in Table 2, it was found that, in a case where the content of the repeating unit X in the surfactant contained in the liquid crystal composition used for forming the optically anisotropic layer, in which the difference in I/O value with the liquid crystal compound (main liquid crystal) was 0.9 or more, was more than 8 mol %, the precipitates (streaky unevenness) occurred in the optically anisotropic layer (Comparative Examples 1 and 3 to 5).

In addition, it was found that, in a case where the surfactant contained in the liquid crystal composition used for forming the optically anisotropic layer did not have the repeating unit K including a functional group capable of being crosslinked with the liquid crystal compound (main liquid crystal), the optically anisotropic layer underwent cohesive failure (Comparative Example 2).

On the other hand, it was found that, in a case where the surfactant contained in the liquid crystal composition used for forming the optically anisotropic layer had the repeating unit H including a fluorinated alkyl group or a silicon-containing group, the repeating unit K including a functional group capable of being crosslinked with the liquid crystal compound, and the repeating unit M including a mesogen group, and the content of the repeating unit X in the surfactant, in which the difference in I/O value with the liquid crystal compound (main liquid crystal) was 0.9 or more, was 8 mol % or less, an optically anisotropic layer in which both the occurrence of precipitates and the cohesive failure were suppressed could be formed.

In particular, from the comparison between Examples 2 to 4 and Example 8, it was found that, in a case where the repeating unit X of the surfactant included a carboxy group, the occurrence of precipitates could be further suppressed.

In addition, from the comparison between Examples 2 to 4 and Example 9, it was found that, in a case where the content of the repeating unit X of the surfactant was 5 mol % or less, the occurrence of precipitates could be further suppressed.

In addition, from the comparison between Examples 2 to 4 and Example 10, it was found that, in a case where the content of the specific surfactant was 0.05% by mass or more with respect to the total mass of solid contents of the liquid crystal composition, the unevenness other than the precipitates (that is, the streaky unevenness) could be suppressed.

In addition, from the comparison between Examples 2 to 4 and Example 12, it was found that, in a case where the liquid crystal composition contained the compound including a mesogen group having the same structure as the mesogen group included in the repeating unit M of the surfactant contained in the liquid crystal composition in an amount of 0.5% by mass or more with respect to the total mass of solid contents of the liquid crystal composition, the alignment properties of the optically anisotropic layer (liquid crystal cured layer) were improved.

What is claimed is:

1. An optical film comprising:
an optically anisotropic layer,
wherein the optically anisotropic layer is a liquid crystal cured layer formed by using a liquid crystal composition which contains a liquid crystal compound and a surfactant, and immobilizing the liquid crystal compound in a vertically aligned state,
the liquid crystal compound is a liquid crystal compound exhibiting reverse wavelength dispersibility,
the surfactant is a surfactant having a repeating unit H including a fluorinated alkyl group or a silicon-containing group,
at least one surfactant has the repeating unit H, a repeating unit K including a functional group capable of being crosslinked with the liquid crystal compound, and a repeating unit M including a mesogen group, and
a content of a repeating unit X in the surfactant, in which a difference in I/O value with the liquid crystal compound is 0.9 or more, is 8 mol % or less,
provided that, in a case where the liquid crystal composition contains two or more kinds of liquid crystal compounds, each of requirements regarding the liquid crystal compound is a requirement regarding a liquid crystal compound having a highest content, and
in a case where the liquid crystal composition contains two or more kinds of surfactants, a requirement regarding the content of the repeating unit X in the surfactant is a requirement which is satisfied independently by all kinds of the surfactants.

2. The optical film according to claim 1,
wherein the repeating unit X includes a carboxy group.

3. The optical film according to claim 1,
wherein the content of the repeating unit X is 5 mol % or less.

4. The optical film according to claim 1,
wherein a content of the surfactant is 0.05% by mass or more with respect to a total mass of solid contents of the liquid crystal composition.

5. The optical film according to claim 1,
wherein a content of the repeating unit K is 10 mol % or more.

6. The optical film according to claim 1,
wherein, in a case where a value of a content (unit: mol %) of the repeating unit M is denoted by m and a value of a content (unit: mol %) of the repeating unit K is denoted by k, the following expressions (1) and (2) are satisfied,
$$m / k \leq 1 , and \qquad ( 1 )$$
$$m \leq 50. \qquad ( 2 )$$

7. The optical film according to claim 1,
wherein the liquid crystal composition further contains a compound including a mesogen group having the same structure as the mesogen group included in the repeating unit M in an amount of 0.5% by mass or more with respect to a total mass of solid contents of the liquid crystal composition.

8. The optical film according to claim 1,
wherein the repeating unit M further includes a boronic acid group in addition to the mesogen group.

9. The optical film according to claim 1, further comprising:
a substrate.

10. The optical film according to claim 9,
wherein the substrate is a positive A-plate.

11. The optical film according to claim 9,
wherein the substrate is a liquid crystal cured layer formed by fixing an alignment state of a liquid crystal compound, the liquid crystal cured layer being different from the optically anisotropic layer.

12. A polarizing plate comprising:
the optical film according to claim 1; and
a polarizer.

13. An image display device comprising:
the optical film according to claim 1.

14. An image display device comprising:
the polarizing plate according to claim 12.

15. The image display device according to claim 13,
wherein the image display device is a liquid crystal display device.

16. The image display device according to claim 13,
wherein the image display device is an organic EL display device.

17. The optical film according to claim 2,
wherein the content of the repeating unit X is 5 mol % or less.

18. The optical film according to claim 2,
wherein a content of the surfactant is 0.05% by mass or more with respect to a total mass of solid contents of the liquid crystal composition.

19. The optical film according to claim 2,
wherein a content of the repeating unit K is 10 mol % or more.

20. The optical film according to claim 2,
wherein, in a case where a value of a content (unit: mol %) of the repeating unit M is denoted by m and a value of a content (unit: mol %) of the repeating unit K is denoted by k, the following expressions (1) and (2) are satisfied,
$$m / k \leq 1 , and \qquad ( 1 )$$
$$m \leq 50. \qquad ( 2 )$$
